(19) United States
(12) Patent Application Publication
(10) Pub. No.: US 2024/0282738 A1
(43) Pub. Date: Aug. 22, 2024

(54) SEMICONDUCTOR DEVICE

(71) Applicant: ROHM CO., LTD., Kyoto-shi (JP)

(72) Inventor: Yuki NAKANO, Kyoto-shi (JP)

(73) Assignee: ROHM CO., LTD., Kyoto-shi (JP)

(21) Appl. No.: 18/650,144

(22) Filed: Apr. 30, 2024

Related U.S. Application Data
(63) Continuation of application No. PCT/JP2022/040493, filed on Oct. 28, 2022.

(30) Foreign Application Priority Data
Nov. 5, 2021 (JP) 2021-181312

(51) Int. Cl. H01L 23/00; H01L 23/31; H01L 23/495; H01L 29/06; H01L 29/16; H01L 29/417; H01L 29/78

(52) U.S. Cl. CPC H01L 24/13; H01L 23/3107; H01L 23/49513; H01L 23/4952; H01L 23/49562; H01L 23/49575; H01L 24/11; H01L 24/14; H01L 29/0623; H01L 29/0696; H01L 29/1608; H01L 29/41741; H01L 29/7811; H01L 29/7813; H01L 2224/11462; H01L 2224/1184; H01L 2224/13018; H01L 2224/13078; H01L 2224/13147; H01L 2224/1403; H01L 2924/10272; H01L 2924/12032; H01L 2924/13091; H01L 2924/351

(57) ABSTRACT

A semiconductor device includes a chip having a main surface, a main surface electrode arranged on the main surface, and a terminal electrode that has a conductor layer covering the main surface electrode and a gap portion penetrating the conductor layer in a thickness direction as viewed in cross section, and that is fixed to a same potential as that of the main surface electrode.

### CROSS-REFERENCE TO RELATED APPLICATIONS

The present application is a bypass continuation of International Patent Application No. PCT/JP2022/040493, filed on Oct. 28, 2022, which claims the benefit of priority to Japanese Patent Application No. 2021-181312 filed on Nov. 5, 2021, and the entire contents of each application are hereby incorporated herein by reference.

### BACKGROUND

### 1. Field of the Disclosure

The present disclosure relates to a semiconductor device.

### Background Art

### 2. Description of the Related Art

US20190080976A1 discloses a semiconductor device that includes a semiconductor substrate, an electrode and a protective film. The electrode is formed on the semiconductor substrate. The protective film has a laminated structure that includes an inorganic protective film and an organic protective film and covers the electrode.

### BRIEF DESCRIPTION OF THE DRAWINGS

FIG. 1 is a plan view of a semiconductor device according to a first embodiment.

FIG. 2 is a cross sectional view taken along II-II line shown in FIG. 1.

FIG. 3 is a cross sectional view taken along III-III line shown in FIG. 1.

FIG. 4 is an enlarged plan view showing a principal part of an inner portion of a chip.

FIG. 5 is a cross sectional view taken along V-V line shown in FIG. 4.

FIG. 6 is an enlarged cross sectional view showing a peripheral edge portion of the chip.

FIG. 7 is a plan view showing layout examples of a gate electrode and a source electrode.

FIG. 8 is a plan view showing a layout example of an upper insulating film.

FIG. 9 is a plan view showing a wafer structure that is to be used at a time of manufacturing.

FIG. 10 is a cross sectional view showing a device region shown in FIG. 9.

FIGS. 11A to 11I are cross sectional views showing a manufacturing method example for the semiconductor device shown in FIG. 1.

FIG. 12 is a plan view showing a semiconductor device according to a second embodiment.

FIG. 13 is a plan view showing a semiconductor device according to a third embodiment.

FIG. 14 is a cross sectional view taken along XIV-XIV line shown in FIG. 13.

FIG. 15 is a circuit diagram showing an electrical configuration of the semiconductor device shown in FIG. 13.

FIG. 16 is a plan view showing a semiconductor device according to a fourth embodiment.

FIG. 17 is a cross sectional view taken along XVII-XVII line shown in FIG. 16.

FIG. 18 is a plan view showing a semiconductor device according to a fifth embodiment.

FIG. 19 is a plan view showing a semiconductor device according to a sixth embodiment.

FIG. 20 is a plan view showing a semiconductor device according to a seventh embodiment.

FIG. 21 is a plan view showing a semiconductor device according to an eighth embodiment.

FIG. 22 is a cross sectional view taken along XXII-XXII line shown in FIG. 21.

FIG. 23 is a cross sectional view showing a modified example of the chip to be applied to each of the embodiments.

FIG. 24 is a plan view showing a modified example of a gap portion to be applied to each of the embodiments.

FIG. 25 is a plan view showing a modified example of a gap portion to be applied to each of the embodiments.

FIG. 26 is a cross sectional view showing a modified example of a sealing insulator to be applied to each of the embodiments.

FIG. 27 is a plan view showing a modified example of a gate terminal electrode to be applied to each of the embodiments.

FIG. 28 is a plan view showing a package to which any one of the semiconductor devices according to the first to seventh embodiments is to be incorporated.

FIG. 29 is a plan view showing a package to which the semiconductor device according to the eighth embodiment is to be incorporated.

FIG. 30 is a perspective view showing a package to which any one of the semiconductor devices according to the first to seventh embodiments and the semiconductor device according to the eighth embodiment are to be incorporated.

FIG. 31 is an exploded perspective view of the package shown in FIG. 30.

FIG. 32 is a cross sectional view taken along XXXII-XXXII line shown in FIG. 30.

### DETAILED DESCRIPTION OF THE PREFERRED EMBODIMENTS

Hereinafter, embodiments shall be described in detail with reference to attached drawings. The attached drawings are schematic views and are not strictly illustrated, and scales and the like thereof do not always match. Also, identical reference symbols are given to corresponding structures among the attached drawings, and duplicate descriptions thereof shall be omitted or simplified. For the structures whose description have been omitted or simplified, the description given before the omission or simplification shall be applies.

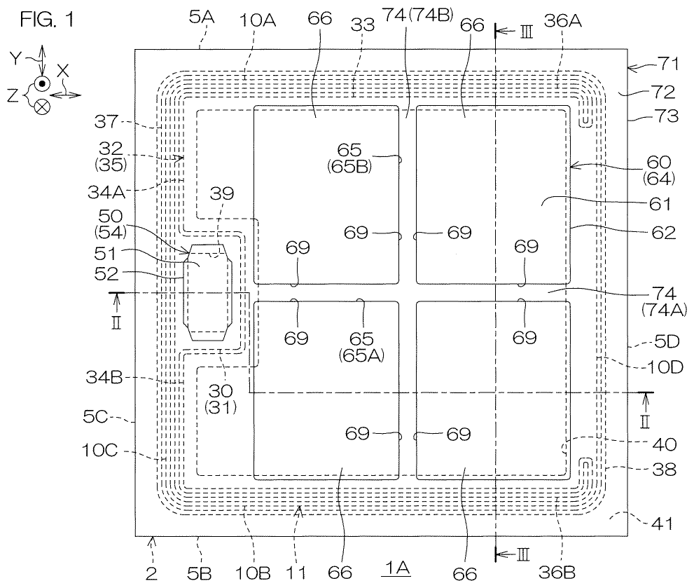

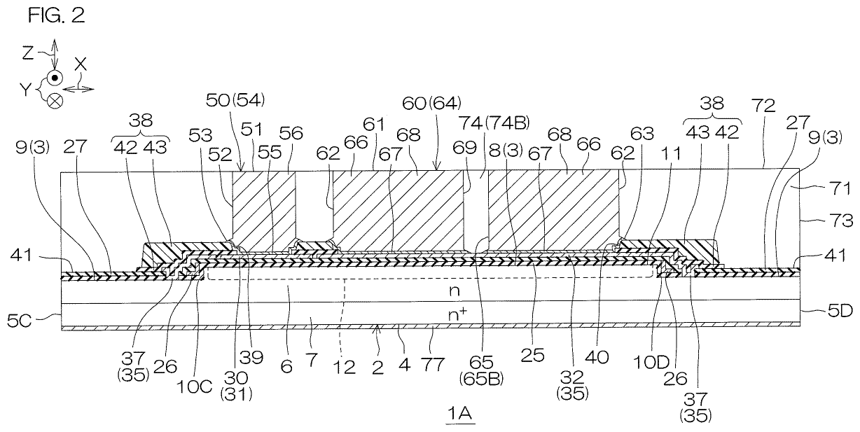

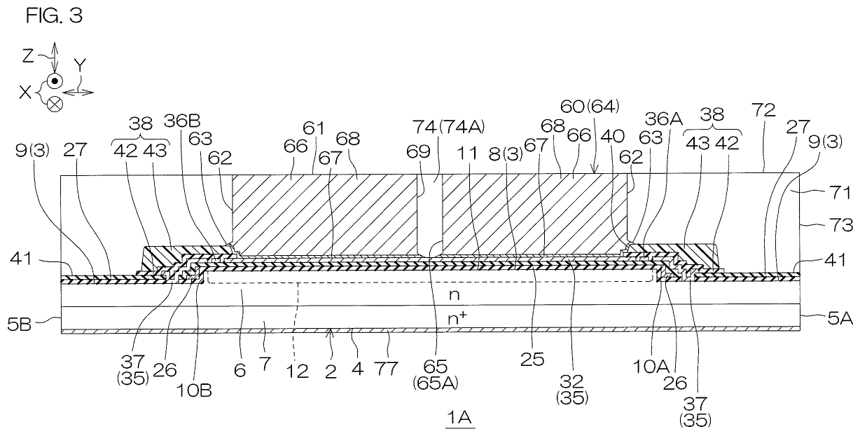

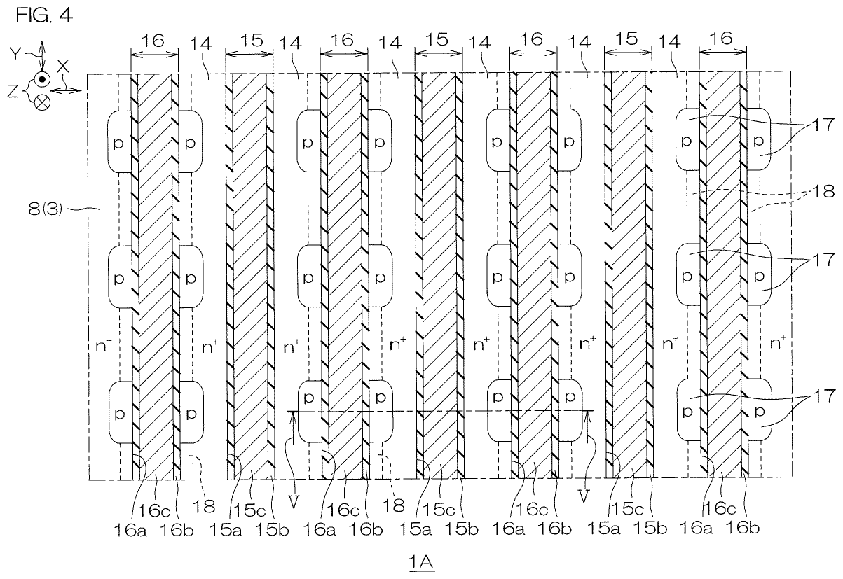

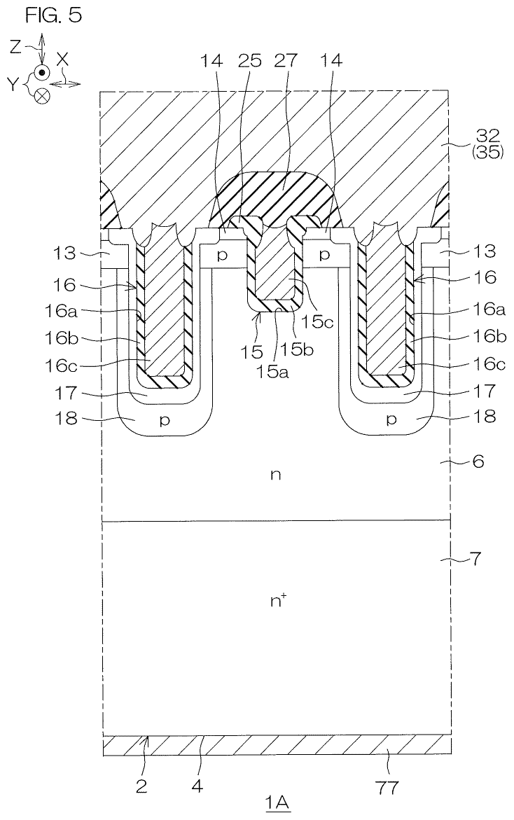

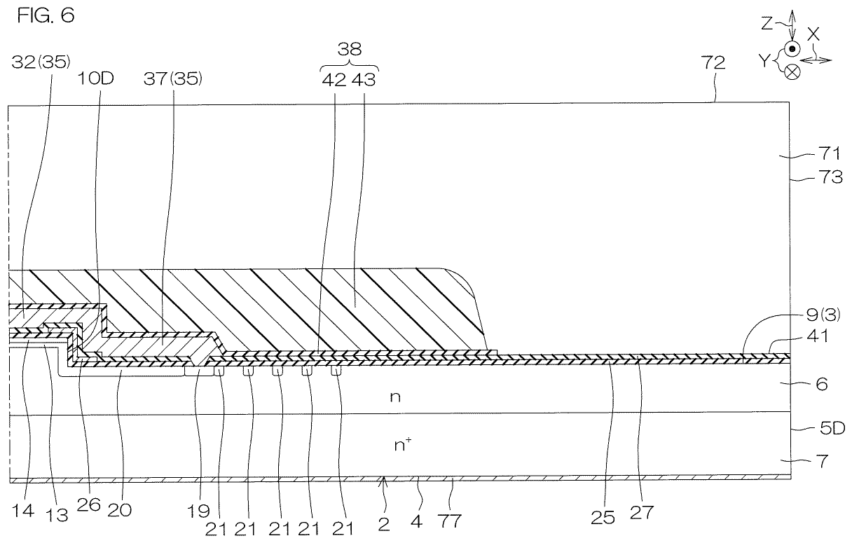

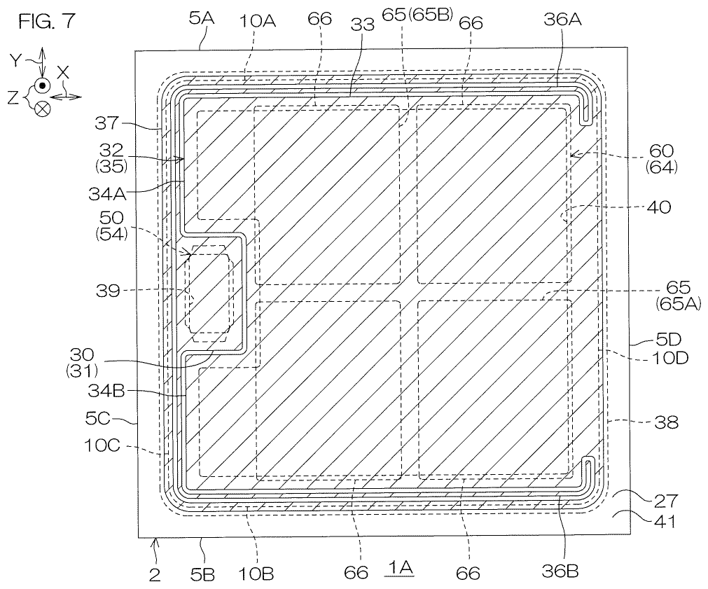

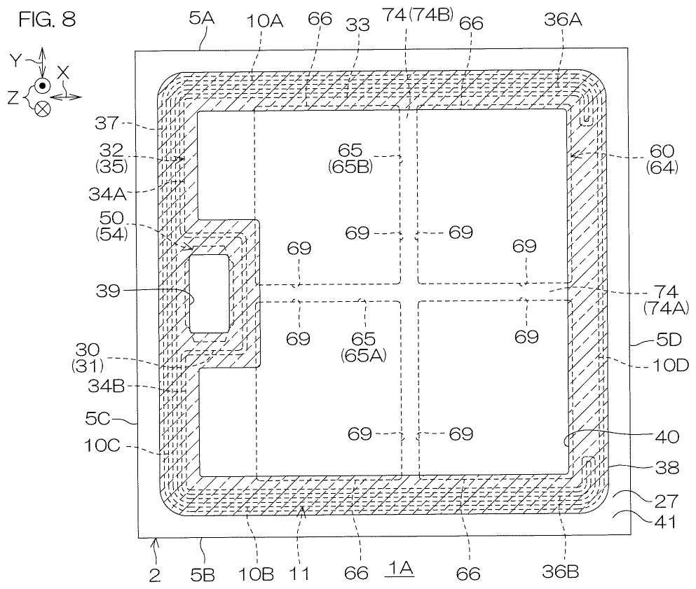

FIG. 1 is a plan view of a semiconductor device 1A according to a first embodiment. FIG. 2 is a cross sectional view taken along II-II line shown in FIG. 1. FIG. 3 is a cross sectional view taken along III-III line shown in FIG. 1. FIG. 4 is an enlarged plan view showing a principal part of an inner portion of a chip 2. FIG. 5 is a cross sectional view taken along V-V line shown in FIG. 4. FIG. 6 is an enlarged cross sectional view showing a peripheral edge portion of the chip 2. FIG. 7 is a plan view showing layout examples of a gate electrode 30 and a source electrode 32. FIG. 8 is a plan view showing a layout example of an upper insulating film 38.

With reference to FIG. 1 to FIG. 8, the semiconductor device 1A includes a chip 2 that includes a monocrystal of a wide bandgap semiconductor and that is formed in a hexahedral shape (specifically, rectangular parallelepiped shape), in this embodiment. That is, the semiconductor device 1A is a “wide bandgap semiconductor device”. The chip 2 may be referred to as a “semiconductor chip” or a “wide bandgap semiconductor chip”. The wide bandgap semiconductor is a semiconductor having a bandgap exceeding a bandgap of an Si (Silicon). GaN (gallium nitride), SiC (silicon carbide) and C (diamond) are exemplified as the wide bandgap semiconductors.

The chip 2 is an “SiC chip” including an SiC monocrystal of a hexagonal crystal as an example of the wide bandgap semiconductor. That is, the semiconductor device 1A is an “SiC semiconductor device”. The SiC monocrystal of the hexagonal crystal has multiple polytypes including 2H (Hexagonal)-SiC monocrystal, 4H-SiC monocrystal, 6H-SiC monocrystal and the like. In this embodiment, an example in which the chip 2 includes the 4H-SiC monocrystal is to be given, but this does not preclude a choice of other polytypes.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are each formed in a quadrangle shape in plan view as viewed from their normal direction Z (hereinafter, simply referred to as “in plan view”). The normal direction Z is also a thickness direction of the chip 2. The first main surface 3 and the second main surface 4 are preferably formed by a c-plane of the SiC monocrystal, respectively.

In this case, the first main surface 3 is preferably formed by a silicon surface of the SiC monocrystal, and the second main surface 4 is preferably formed by a carbon surface of the SiC monocrystal. The first main surface 3 and the second main surface 4 may each have an off angle inclined with a predetermined angle with respect to the c-plane toward a predetermined off direction. The off direction is preferably an a-axis direction ([11-20] direction) of the SiC monocrystal. The off angle may be exceed 0° and not more than 10°. The off angle is preferably not more than 5°. The second main surface 4 may consist of a ground surface with grinding marks, or may consist of a smooth surface without a grinding mark.

The first side surface 5A and the second side surface 5B extend in a first direction X along the first main surface 3 and oppose in a second direction Y intersecting to (specifically, orthogonal to) the first direction X. The third side surface 5C and the fourth side surface 5D extend in the second direction Y and oppose in the first direction X. The first direction X may be an m-axis direction ([1-100] direction) of the SiC monocrystal, and the second direction Y may be the a-axis direction of the SiC monocrystal. As a matter of course, the first direction X may be the a-axis direction of the SiC monocrystal, and the second direction Y may be the m-axis direction of the SiC monocrystal. The first to fourth side surfaces 5A to 5D may each consist of a ground surface with grinding marks, or may each consist of a smooth surface without a grinding mark.

The chip 2 has a thickness of not less than 5 μm and not more than 250 μm in regard to the normal direction Z. The thickness of the chip 2 may be not more than 100 μm. The thickness of the chip 2 is preferably not more than 50 μm. The thickness of the chip 2 is particularly preferably not more than 40 μm. The first to fourth side surfaces 5A to 5D may each have a length of not less than 0.5 mm and not more than 10 mm in plan view.

The lengths of the first to fourth side surfaces 5A to 5D are preferably not less than 1 mm. The lengths of the first to fourth side surfaces 5A to 5D are particularly preferably not less than 2 mm. That is, the chip 2 preferably has a planar area of not less than 1 mm square (preferably, not less than 2 mm square) and preferably has a thickness of not more than 100 μm (preferably, not more than 50 μm). The lengths of the first to fourth side surfaces 5A to 5D are set in a range of not less than 4 mm and not more than 6 mm, in this embodiment.

The semiconductor device 1A includes a first semiconductor region 6 of an n-type (first conductivity type) that is formed in a region (surface layer portion) on the first main surface 3 side inside the chip 2. The first semiconductor region 6 is formed in a layered shape extending along the first main surface 3 and is exposed from the first main surface 3 and the first to fourth side surfaces 5A to 5D. The first semiconductor region 6 consists of an epitaxial layer (specifically, an SiC epitaxial layer), in this embodiment. The first semiconductor region 6 may have a thickness of not less than 1 μm and not more than 50 μm in regard to the normal direction Z. The thickness of the first semiconductor region 6 is preferably not less than 3 μm and not more than 30 μm. The thickness of the first semiconductor region 6 is particularly preferably not less than 5 μm and not more than 25 μm.

The semiconductor device 1A includes a second semiconductor region 7 of the n-type that is formed in a region (surface layer portion) on the second main surface 4 side inside the chip 2. The second semiconductor region 7 is formed in a layered shape extending along the second main surface 4 and exposes from the second main surface 4 and the first to fourth side surfaces 5A to 5D. The second semiconductor region 7 has an n-type impurity concentration higher than that of the first semiconductor region 6 and is electrically connected to the first semiconductor region 6. The second semiconductor region 7 consists of a semiconductor substrate (specifically, an SiC semiconductor substrate), in this embodiment. That is, the chip 2 has a laminated structure including the semiconductor substrate and the epitaxial layer.

The second semiconductor region 7 may have a thickness of not less than 1 μm and not more than 200 μm in regard to the normal direction Z. The thickness of the second semiconductor region 7 is preferably not less than 5 μm and not more than 50 μm. The thickness of the second semiconductor region 7 is particularly preferably not less than 5 μm and not more than 20 μm. Considering an error to be occurred to the first semiconductor region 6, the thickness of the second semiconductor region 7 is preferably not less than 10 μm. The thickness of the second semiconductor region 7 is most preferably less than the thickness of the first semiconductor region 6. According to the second semiconductor region 7 having the relatively small thickness, a resistance value (for example, an on-resistance) due to the second semiconductor region 7 can be reduced. As a matter of course, the thickness of the second semiconductor region 7 may exceed the thickness of first semiconductor region 6.

The semiconductor device 1A includes an active surface 8 (active surface), an outer surface 9 (outer surface) and first to fourth connecting surfaces 10A to 10D (connecting surface) that are formed in the first main surface 3. The active surface 8, the outer surface 9 and the first to fourth connecting surfaces 10A to 10D define a mesa portion 11 (plateau) in the first main surface 3. The active surface 8 may be referred to as a “first surface portion”, the outer surface 9 may be referred to as a “second surface portion”, the first to fourth connecting surfaces 10A to 10D may be referred to as “connecting surface portions”. The active surface 8, the outer surface 9 and the first to fourth connecting surfaces 10A to 10D (that is, the mesa portion 11) may be considered as components of the chip 2 (the first main surface 3).

The active surface 8 is formed at an interval inward from a peripheral edge of the first main surface 3 (the first to fourth side surfaces 5A to 5D). The active surface 8 has a flat surface extending in the first direction X and the second direction Y. The active surface 8 is formed in a quadrangle shape having four sides parallel to the first to fourth side surfaces 5A to 5D in plan view, in this embodiment.

The outer surface 9 is positioned outside the active surface 8 and is recessed toward the thickness direction of the chip 2 (the second main surface 4 side) from the active surface 8. Specifically, the outer surface 9 is recessed with a depth less than the thickness of the first semiconductor region 6 such as to expose the first semiconductor region 6. The outer surface 9 extends along the active surface 8 in a band shape and is formed in an annular shape (specifically, a quadrangle annular shape) surrounding the active surface 8 in plan view. The outer surface 9 has a flat surface extending in the first direction X and the second direction Y and is formed substantially parallel to the active surface 8. The outer surface 9 is continuous to the first to fourth side surfaces 5A to 5D.

The first to fourth connecting surfaces 10A to 10D extend in the normal direction Z and connect the active surface 8 and the outer surface 9. The first connecting surface 10A is positioned on the first side surface 5A side, the second connecting surface 10B is positioned on the second side surface 5B side, the third connecting surface 10C is positioned on the third side surface 5C side, and the fourth connecting surface 10D is positioned on the fourth side surface 5D side. The first connecting surface 10A and the second connecting surface 10B extend in the first direction X and oppose in the second direction Y. The third connecting surface 10C and the fourth connecting surface 10D extend in the second direction Y and oppose in the first direction X.

The first to fourth connecting surfaces 10A to 10D may substantially vertically extend between the active surface 8 and the outer surface 9 such that the mesa portion 11 of a quadrangle columnar is defined. The first to fourth connecting surfaces 10A to 10D may be downwardly inclined from the active surface 8 to the outer surface 9 such that the mesa portion 11 of a quadrangle pyramid shape is defined. Thus, the semiconductor device 1A includes the mesa portion 11 that is formed in the first semiconductor region 6 at the first main surface 3. The mesa portion 11 is formed only in the first semiconductor region 6 and is not formed in the second semiconductor region 7.

The semiconductor device 1A includes a MISFET (Metal Insulator Semiconductor Field Effect Transistor) structure 12 that is formed in the active surface 8 (the first main surface 3). In FIG. 2 and FIG. 3, the MISFET structure 12 is shown simplified by a dashed line. Hereinafter, with reference to FIG. 4 and FIG. 5, a specific structure of the MISFET structure 12 shall be described.

The MISFET structure 12 includes a body region 13 of a p-type (second conductivity type) that is formed in a surface layer portion of the active surface 8. The body region 13 is formed at an interval to the active surface 8 side from a bottom portion of the first semiconductor region 6. The body region 13 is formed in a layered shape extending along the active surface 8. The body region 13 may be exposed from parts of the first to fourth connecting surfaces 10A to 10D.

The MISFET structure 12 includes a source region 14 of the n-type that is formed in a surface layer portion of the body region 13. The source region 14 has an n-type impurity concentration higher than that of the first semiconductor region 6. The source region 14 is formed at an interval to the active surface 8 side from a bottom portion of the body region 13. The source region 14 is formed in a layered shape extending along the active surface 8. The source region 14 may be exposed from a whole region of the active surface 8. The source region 14 may be exposed from parts of the first to fourth connecting surfaces 10A to 10D. The source region 14 forms a channel inside the body region 13 between the first semiconductor region 6 and the source region 14.

The MISFET structure 12 includes a plurality of gate structures 15 that are formed in the active surface 8. The plurality of gate structures 15 arrayed at intervals in the first direction X and each formed in a band shape extending in the second direction Y in plan view. The plurality of gate structures 15 penetrate the body region 13 and the source region 14 such as to reach the first semiconductor region 6. The plurality of gate structures 15 control a reversal and a non-reversal of the channel in the body region 13.

Each of the gate structures 15 includes a gate trench 15a, a gate insulating film 15b and a gate embedded electrode 15c, in this embodiment. The gate trench 15a is formed in the active surface 8 and defines a wall surface of the gate structure 15. The gate insulating film 15b covers the wall surface of the gate trench 15a. The gate embedded electrode 15c is embedded in the gate trench 15a with the gate insulating film 15b interposed therebetween and faces the channel across the gate insulating film 15b.

The MISFET structure 12 includes a plurality of source structures 16 that are formed in the active surface 8. The plurality of source structures 16 are each arranged at a region between a pair of adjacent gate structures 15 in the active surface 8. The plurality of source structures 16 are each formed in a band shape extending in the second direction Y in plan view. The plurality of source structures 16 penetrate the body region 13 and the source region 14 such as to reach the first semiconductor region 6. The plurality of source structures 16 have depths exceeding depths of the gate structures 15. Specifically, the plurality of source structures 16 has the depths substantially equal to the depth of the outer surface 9.

Each of the source structures 16 includes a source trench 16a, a source insulating film 16b and a source embedded electrode 16c. The source trench 16a is formed in the active surface 8 and defines a wall surface of the source structure 16. The source insulating film 16b covers the wall surface of the source trench 16a. The source embedded electrode 16c is embedded in the source trench 16a with the source insulating film 16b interposed therebetween.

The MISFET structure 12 includes a plurality of contact regions 17 of the p-type that are each formed in a region along the source structure 16 inside the chip 2. The plurality of contact regions 17 have a p-type impurity concentration higher than that of the body region 13. Each of the contact regions 17 covers the side wall and the bottom wall of each of the source structures, and is electrically connected to the body region 13.

The MISFET structure 12 includes a plurality of well regions 18 of the p-type that are each formed in a region along the source structure 16 inside the chip 2. Each of the well regions 18 may have a p-type impurity concentration higher than that of the body region 13 and less than that of the contact regions 17. Each of the well regions 18 covers the corresponding source structure 16 with the corresponding contact region 17 interposed therebetween. Each of the well regions 18 covers the side wall and the bottom wall of the corresponding source structure 16, and is electrically connected to the body region 13 and the contact regions 17.

With reference to FIG. 6, the semiconductor device 1A includes an outer contact region 19 of the p-type that is formed in a surface layer portion of the outer surface 9. The outer contact region 19 has a p-type impurity concentration higher than that of the body region 13. The outer contact region 19 is formed at intervals from a peripheral edge of the active surface 8 and a peripheral edge of the outer surface 9, and is formed in a band shape extending along the active surface 8 in plan view.

The outer contact region 19 is formed in an annular shape (specifically, a quadrangle annular shape) surrounding the active surface 8 in plan view, in this embodiment. The outer contact region 19 is formed at an interval to the outer surface 9 side from the bottom portion of the first semiconductor region 6. The outer contact region 19 is positioned on the bottom portion side of the first semiconductor region 6 with respect to the bottom walls of the plurality of gate structures 15 (the plurality of source structures 16).

The semiconductor device 1A includes an outer well region 20 of the p-type that is formed in the surface layer portion of the outer surface 9. The outer well region 20 has a p-type impurity concentration less than that of the outer contact region 19. The p-type impurity concentration of the outer well region 20 is preferably substantially equal to the p-type impurity concentration of the well regions 18. The outer well region 20 is formed in a region between the peripheral edge of the active surface 8 and the outer contact region 19, and is formed in a band shape extending along the active surface 8 in plan view.

The outer well region 20 is formed in an annular shape (specifically, a quadrangle annular shape) surrounding the active surface 8 in plan view, in this embodiment. The outer well region 20 is formed at an interval to the outer surface 9 side from the bottom portion of the first semiconductor region 6. The outer well region 20 may be formed deeper than the outer contact region 19. The outer well region 20 is positioned on the bottom portion side of the first semiconductor region 6 with respect to the plurality of gate structures 15 (the plurality of source structures 16).

The outer well region 20 is electrically connected to the outer contact region 19. The outer well region 20 extends toward the first to fourth connecting surfaces 10A to 10D side from the outer contact region 19 side, and covers the first to fourth connecting surfaces 10A to 10D, in this embodiment. The outer well region 20 is electrically connected to the body region 13 in the surface layer portion of the active surface 8.

The semiconductor device 1A includes at least one (preferably, not less than 2 and not more than 20) field region 21 of the p-type that is formed in a region between the peripheral edge of the outer surface 9 and the outer contact region 19 in the surface layer portion of the outer surface 9. The semiconductor device 1A includes five field regions 21, in this embodiment. The plurality of field regions 21 relaxes an electric field inside the chip 2 at the outer surface 9. A number, a width, a depth, a p-type impurity concentration, etc., of the field region 21 are arbitrary, and various values can be taken depending on the electric field to be relaxed.

The plurality of field regions 21 are arrayed at intervals from the outer contact region 19 side to the peripheral edge side of the outer surface 9. The plurality of field regions 21 are each formed in a band shape extending along the active surface 8 in plan view. The plurality of field regions 21 are each formed in an annular shape (specifically, a quadrangle annular shape) surrounding the active surface 8 in plan view, in this embodiment. Thus, the plurality of field regions 21 are each formed as an FLR (Field Limiting Ring) region.

The plurality of field regions 21 are formed at intervals to the outer surface 9 side from the bottom portion of the first semiconductor region 6. The plurality of field regions 21 are positioned on the bottom portion side of the first semiconductor region 6 with respect to the bottom walls of the plurality of gate structures 15 (the plurality of source structures 16). The plurality of field regions 21 may be formed deeper than the outer contact region 19. The innermost field region 21 may be connected to the outer contact region 19.

The semiconductor device 1A includes a main surface insulating film 25 that covers the first main surface 3. The main surface insulating film 25 may include at least one of a silicon oxide film, a silicon nitride film and a silicon oxynitride film. The main surface insulating film 25 has a single layered structure consisting of the silicon oxide film, in this embodiment. The main surface insulating film 25 particularly preferably includes the silicon oxide film that consists of an oxide of the chip 2.

The main surface insulating film 25 covers the active surface 8, the outer surface 9 and the first to fourth connecting surfaces 10A to 10D. The main surface insulating film 25 covers the active surface 8 such as to be continuous to the gate insulating film 15b and the source insulating film 16b and to expose the gate embedded electrode 15c and the source embedded electrode 16c. The main surface insulating film 25 covers the outer surface 9 and the first to fourth connecting surfaces 10A to 10D such as to cover the outer contact region 19, the outer well region 20 and the plurality of field regions 21.

The main surface insulating film 25 may be continuous to the first to fourth side surfaces 5A to 5D. In this case, an outer wall of the main surface insulating film 25 may consist of a ground surface with grinding marks. The outer wall of the main surface insulating film 25 may form a single ground surface with the first to fourth side surfaces 5A to 5D. As a matter of course, the outer wall of the main surface insulating film 25 may be formed at an interval inward from the peripheral edge portion of the outer surface 9 and may expose the first semiconductor region 6 from a peripheral edge portion of the outer surface 9.

The semiconductor device 1A includes a side wall structure 26 that is formed on the main surface insulating film 25 such as to cover at least one of the first to fourth connecting surfaces 10A to 10D at the outer surface 9. The side wall structure 26 is formed in an annular shape (a quadrangle annular shape) surrounding the active surface 8 in plan view, in this embodiment. The side wall structure 26 may have a portion that overlaps onto the active surface 8. The side wall structure 26 may include an inorganic insulator or a polysilicon. The side wall structure 26 may be a side wall wiring that is electrically connected to the plurality of source structures 16.

The semiconductor device 1A includes an interlayer insulating film 27 that is formed on the main surface insulating film 25. The interlayer insulating film 27 may include at least one of a silicon oxide film, a silicon nitride film and a silicon oxynitride film. The interlayer insulating film 27 has a single layered structure consisting of the silicon oxide film, in this embodiment.

The interlayer insulating film 27 covers the active surface 8, the outer surface 9 and the first to fourth connecting surfaces 10A to 10D with the main surface insulating film 25 interposed therebetween. Specifically, the interlayer insulating film 27 covers the active surface 8, the outer surface 9 and the first to fourth connecting surfaces 10A to 10D across the side wall structure 26. The interlayer insulating film 27 covers the MISFET structure 12 on the active surface 8 side and covers the outer contact region 19, the outer well region 20 and the plurality of field regions 21 on the outer surface 9 side.

The interlayer insulating film 27 is continuous to the first to fourth side surfaces 5A to 5D, in this embodiment. An outer wall of the interlayer insulating film 27 may consist of a ground surface with grinding marks. The outer wall of the interlayer insulating film 27 may form a single ground surface with the first to fourth side surfaces 5A to 5D. As a matter of course, the outer wall of the interlayer insulating film 27 may be formed at an interval inward from the peripheral edge of the outer surface 9 and may expose the first semiconductor region 6 from the peripheral edge portion of the outer surface 9.

The semiconductor device 1A includes a gate electrode 30 that is arranged on the first main surface 3 (the interlayer insulating film 27). The gate electrode 30 may be referred to as a “gate main surface electrode”. The gate electrode 30 is arranged at an inner portion of the first main surface 3 at an interval from the peripheral edge of the first main surface 3. The gate electrode 30 is arranged on the active surface 8, in this embodiment. Specifically, the gate electrode 30 is arranged on a region adjacent a central portion of the third connecting surface 10C (the third side surface 5C) at the peripheral edge portion of the active surface 8. The gate electrode 30 is formed in a quadrangle shape in plan view, in this embodiment. As a matter of course, the gate electrode 30 may be formed in a polygonal shape other than the quadrangle shape, a circular shape, or an elliptical shape in plan view.

The gate electrode 30 preferably has a planar area of not more than 25% of the first main surface 3. The planar area of the gate electrode 30 may be not more than 10% of the first main surface 3. The gate electrode 30 may have a thickness of not less than 0.5 μm and not more than 15 μm. The gate electrode 30 includes a gate lower conductor layer 31. The gate lower conductor layer 31 may include at least one of a Ti film, a TiN film, a W film, an Al film, a Cu film, an Al alloy film, a Cu alloy film and a conductive polysilicon film.

The gate lower conductor layer 31 may include at least one of a pure Cu film (Cu film with a purity of not less than 99%), a pure Al film (Al film with a purity of not less than 99%), an AlCu alloy film, an AlSi alloy film and an AlSiCu alloy film. The gate lower conductor layer 31 has a laminated structure that includes the Ti film and the Al alloy film (in this embodiment, AlSiCu alloy film) laminated in that order from the chip 2 side, in this embodiment.

The semiconductor device 1A includes a source electrode 32 that is arranged on the first main surface 3 (the interlayer insulating film 27) at an interval from the gate electrode 30. The source electrode 32 may be referred to as a “source main surface electrode”. The source electrode 32 is arranged at an inner portion of the first main surface 3 at an interval from the peripheral edge of the first main surface 3. The source electrode 32 is arranged on the active surface 8, in this embodiment. The source electrode 32 has a body electrode portion 33 and at least one (in this embodiment, a plurality of) drawer electrode portions 34A, 34B, in this embodiment.

The body electrode portion 33 is arrange at a region on the fourth side surface 5D (the fourth connecting surface 10D) side at an interval from the gate electrode 30 and faces the gate electrode 30 in the first direction X, in plan view. The body electrode portion 33 is formed in a polygonal shape (specifically, quadrangle shape) that has four sides parallel to the first to fourth side surfaces 5A to 5D in plan view, in this embodiment.

The plurality of drawer electrode portions 34A, 34B include a first drawer electrode portion 34A on one side (the first side surface 5A side) and a second drawer electrode portion 34B on the other side (the second side surface 5B side). The first drawer electrode portion 34A is drawn out from the body electrode portion 33 onto a region located on one side (the first side surface 5A side) of the second direction Y with respect to the gate electrode 30, and faces the gate electrode 30 in the second direction Y, in plan view.

The second drawer electrode portion 34B is drawn out from the body electrode portion 33 onto a region located on the other side (the second side surface 5B side) of the second direction Y with respect to the gate electrode 30, and faces the gate electrode 30 in the second direction Y, in plan view. That is, the plurality of drawer electrode portions 34A, 34B sandwich the gate electrode 30 from both sides of the second direction Y, in plan view.

The source electrode 32 (the body electrode portion 33 and the drawer electrode portions 34A, 34B) penetrates the interlayer insulating film 27 and the main surface insulating film 25, and is electrically connected to the plurality of source structures 16, the source region 14 and the plurality of well regions 18. As a matter of course, the source electrode 32 does not may have the drawer electrode portions 34A, 34B and may consist only of the body electrode portion 33. The source electrode 32 has a planar area exceeding the planar are of the gate electrode 30. The planar area of the source electrode 32 is preferably not less than 50% of the first main surface 3. The planar are of the source electrode 32 is particularly preferably not less than 75% of the first main surface 3.

The source electrode 32 includes a source lower conductor layer 35. The source lower conductor layer 35 may include at least one of a Ti film, a TiN film, a W film, an Al film, a Cu film, an Al alloy film, a Cu alloy film and a conductive polysilicon film. The source lower conductor layer 35 may include at least one of a pure Cu film (Cu film with a purity of not less than 99%), a pure Al film (Al film with a purity of not less than 99%), an AlCu alloy film, an AlSi alloy film and an AlSiCu alloy film.

The source lower conductor layer 35 has a laminated structure that includes the Ti film and the Al alloy film (in this embodiment, AlSiCu alloy film) laminated in that order from the chip 2 side, in this embodiment. The source lower conductor layer 35 preferably has the same conductive material as that of the gate lower conductor layer 31. The source lower conductor layer 35 (the source electrode 32) may have a thickness of not less than 0.5 μm and not more than 15 μm.

The semiconductor device 1A includes at least one (in this embodiment, a plurality of) gate wirings 36A, 36B that are drawn out from the gate electrode 30 onto the first main surface 3 (the interlayer insulating film 27). The plurality of gate wirings 36A, 36B include the gate lower conductor layer 31 as with the gate electrode 30. The plurality of gate wirings 36A, 36B cover the active surface 8 and do not cover the outer surface 9, in this embodiment. The plurality of gate wirings 36A, 36B are drawn out into a region between the peripheral edge of the active surface 8 and the source electrode 32 and each extends in a band shape along the source electrode 32 in plan view.

Specifically, the plurality of gate wirings 36A, 36B include a first gate wiring 36A and a second gate wiring 36B. The first gate wiring 36A is drawn out from the gate electrode 30 into a region on the first side surface 5A side in plan view. The first gate wiring 36A includes a portion extending as a band shape in the second direction Y along the third side surface 5C and a portion extending as a band shape in the first direction X along the first side surface 5A. The second gate wiring 36B is drawn out from the gate electrode 30 into a region on the second side surface 5B side in plan view. The second gate wiring 36B includes a portion extending as a band shape in the second direction Y along the third side surface 5C and a portion extending as a band shape in the first direction X along the second side surface 5B.

The plurality of gate wirings 36A, 36B intersect (specifically, perpendicularly intersect) both end portions of the plurality of gate structures 15 at the peripheral edge portion of the active surface 8 (the first main surface 3). The plurality of gate wirings 36A, 36B penetrate the interlayer insulating film 27 and are electrically connected to the plurality of gate structures 15. The plurality of gate wirings 36A, 36B may be directly connected to the plurality of gate structures 15, or may be electrically connected to the plurality of gate structures 15 via a conductor film.

The semiconductor device 1A includes a source wiring 37 that is drawn out from the source electrode 32 onto the first main surface 3 (the interlayer insulating film 27). The source wiring 37 includes the source lower conductor layer 35 as with the source electrode 32. The source wiring 37 is formed in a band shape extending along the peripheral edge of the active surface 8 at a region located on the outer surface 9 side than the plurality of gate wirings 36A, 36B. The source wiring 37 is formed in an annular shape (specifically, a quadrangle annular shape) surrounding the gate electrode 30, the source electrode 32 and the plurality of gate wirings 36A, 36B in plan view, in this embodiment.

The source wiring 37 covers the side wall structure 26 with the interlayer insulating film 27 interposed therebetween and is drawn out from the active surface 8 side to the outer surface 9 side. The source wiring 37 preferably covers a whole region of the side wall structure 26 over an entire circumference. The source wiring 37 penetrates the interlayer insulating film 27 and the main surface insulating film 25 at the outer surface 9 side, and has a portion connected to the outer surface 9 (specifically, the outer contact region 19). The source wiring 37 may penetrate the interlayer insulating film 27 and may be electrically connected to the side wall structure 26.

The semiconductor device 1A includes an upper insulating film 38 that selectively covers the gate electrode 30, the source electrode 32, the plurality of gate wirings 36A, 36B and the source wiring 37. The upper insulating film 38 has a gate opening 39 exposing an inner portion of the gate electrode 30 and covers a peripheral edge portion of the gate electrode 30 over an entire circumference. The gate opening 39 is formed in a quadrangle shape in plan view, in this embodiment.

The upper insulating film 38 has a source opening 40 exposing an inner portion of the source electrode 32 and covers a peripheral edge portion of the source electrode 32 over an entire circumference. The source opening 40 is formed in a polygonal shape along the source electrode 32 in plan view, in this embodiment. The upper insulating film 38 covers whole regions of the plurality of gate wirings 36A, 36B and a whole region of the source wiring 37.

The upper insulating film 38 covers the side wall structure 26 with the interlayer insulating film 27 interposed therebetween, and is drawn out from the active surface 8 side to the outer surface 9 side. The upper insulating film 38 is formed at an interval inward from the peripheral edge of the outer surface 9 (the first to fourth side surfaces 5A to 5D) and covers the outer contact region 19, the outer well region 20 and the plurality of field regions 21. The upper insulating film 38 defines a dicing street 41 with the peripheral edge of the outer surface 9.

The dicing street 41 is formed in a band shape extending along the peripheral edge of the outer surface 9 (the first to fourth side surfaces 5A to 5D) in plan view. The dicing street 41 is formed in an annular shape (specifically, a quadrangle annular shape) surrounding the inner portion of the first main surface 3 (the active surface 8) in plan view, in this embodiment. The dicing street 41 exposes the interlayer insulating film 27, in this embodiment.

As a matter of course, in a case in which the main surface insulating film 25 and the interlayer insulating film 27 expose the outer surface 9, the dicing street 41 may expose the outer surface 9. The dicing street 41 may have a width of not less than 1 μm and not more than 200 μm. The width of the dicing street 41 is a width in a direction orthogonal to an extending direction of the dicing street 41. The width of the dicing street 41 is preferably not less than 5 μm and not more than 50 μm.

The upper insulating film 38 preferably has a thickness exceeding the thickness of the gate electrode 30 and the thickness of the source electrode 32. The thickness of the upper insulating film 38 is preferably less than the thickness of the chip 2. The thickness of the upper insulating film 38 may be not less than 3 μm and not more than 35 μm. The thickness of the upper insulating film 38 is preferably not more than 25 μm.

The upper insulating film 38 has a laminated structure that includes an inorganic insulating film 42 and an organic insulating film 43 laminated in that order form the chip 2 side, in this embodiment. The upper insulating film 38 may include at least one of the inorganic insulating film 42 and the organic insulating film 43, and does not necessarily have to include the inorganic insulating film 42 and the organic insulating film 43 at the same time. The inorganic insulating film 42 selectively covers the gate electrode 30, the source electrode 32, the plurality of gate wirings 36A, 36B and the source wiring 37, and defines a part of the gate opening 39, a part of the source opening 40 and a part of the dicing street 41.

The inorganic insulating film 42 may include at least one of a silicon oxide film, a silicon nitride film and a silicon oxynitride film. The inorganic insulating film 42 preferably includes an insulating material different from that of the interlayer insulating film 27. The inorganic insulating film 42 preferably includes the silicon nitride film. The inorganic insulating film 42 preferably has a thickness less than the thickness of the interlayer insulating film 27. The thickness of the inorganic insulating film 42 may be not less than 0.1 μm and not more than 5 μm.

The organic insulating film 43 selectively covers the inorganic insulating film 42, and defines a part of the gate opening 39, a part of the source opening 40 and a part of the dicing street 41. Specifically, the organic insulating film 43 partially exposes the inorganic insulating film 42 in a wall surface of the gate opening 39. Also, the organic insulating film 43 partially exposes the inorganic insulating film 42 in a wall surface of the source opening 40. Also, the organic insulating film 43 partially exposes the inorganic insulating film 42 in a wall surface of the dicing street 41.

As a matter of course, the organic insulating film 43 may cover the inorganic insulating film 42 such that the inorganic insulating film 42 does not expose from the wall surface of the gate opening 39. The organic insulating film 43 may cover the inorganic insulating film 42 such that the inorganic insulating film 42 does not expose from the wall surface of the source opening 40. The organic insulating film 43 may cover the inorganic insulating film 42 such that the inorganic insulating film 42 does not expose from the wall surface of the dicing street 41. In those cases, the organic insulating film 43 may cover a whole region of the inorganic insulating film 42.

The organic insulating film 43 preferably consists of a resin film other than a thermosetting resin. The organic insulating film 43 may consist of a translucent resin or a transparent resin. The organic insulating film 43 may consist of a negative type photosensitive resin film or a positive type photosensitive resin film. The organic insulating film 43 preferably consists of a polyimide film, a polyamide film or a polybenzoxazole film. The organic insulating film 43 includes the polybenzoxazole film, in this embodiment.

The organic insulating film 43 preferably has a thickness exceeding the thickness of the inorganic insulating film 42. The thickness of the organic insulating film 43 preferably exceeds the thickness of the interlayer insulating film 27. The thickness of the organic insulating film 43 particularly preferably exceeds the thickness of the gate electrode 30 and the thickness of the source electrode 32. The thickness of the organic insulating film 43 may be not less than 3 μm and not more than 30 μm. The thickness of the organic insulating film 43 is preferably not more than 20 μm.

The semiconductor device 1A includes a gate terminal electrode 50 that is arranged on the gate electrode 30. The gate terminal electrode 50 is erected in a columnar shape on a portion of the gate electrode 30 that is exposed from the gate opening 39. The gate terminal electrode 50 has an area less than the area of the gate electrode 30 in plan view and is arranged on the inner portion of the gate electrode 30 at an interval from the peripheral edge of the gate electrode 30.

The gate terminal electrode 50 has a gate terminal surface 51 and a gate terminal side wall 52. The gate terminal surface 51 flatly extends along the first main surface 3. The gate terminal surface 51 may consist of a ground surface with grinding marks. The gate terminal side wall 52 is located on the upper insulating film 38 (specifically, the organic insulating film 43), in this embodiment.

That is, the gate terminal electrode 50 has a portion in contact with the inorganic insulating film 42 and the organic insulating film 43. The gate terminal side wall 52 extends substantially vertically to the normal direction Z. Here, “substantially vertically” includes a mode that extends in the laminate direction while being curved (meandering). The gate terminal side wall 52 includes a portion that faces the gate electrode 30 with the upper insulating film 38 interposed therebetween. The gate terminal side wall 52 preferably consists of a smooth surface without a grinding mark.

The gate terminal electrode 50 has a first protrusion portion 53 that outwardly protrudes at a lower end portion of the gate terminal side wall 52. The first protrusion portion 53 is formed at a region on the upper insulating film 38 (the organic insulating film 43) side than an intermediate portion of the gate terminal side wall 52. The first protrusion portion 53 extends along an outer surface of the upper insulating film 38, and is formed in a tapered shape in which a thickness gradually decreases toward a tip portion from the gate terminal side wall 52 in cross sectional view. The first protrusion portion 53 therefore has a sharp-shaped tip portion with an acute angle. As a matter of course, the gate terminal electrode 50 without the first protrusion portion 53 may be formed.

The gate terminal electrode 50 preferably has a thickness exceeding the thickness of the gate electrode 30. The thickness of the gate terminal electrode 50 is defined by a distance between the gate electrode 30 and the gate terminal surface 51. The thickness of the gate terminal electrode 50 particularly preferably exceeds the thickness of the upper insulating film 38. The thickness of the gate terminal electrode 50 exceeds the thickness of the chip 2, in this embodiment. As a matter of course, the thickness of the gate terminal electrode 50 may be less than the thickness of the chip 2. The thickness of the gate terminal electrode 50 may be not less than 10 μm and not more than 300 μm. The thickness of the gate terminal electrode 50 is preferably not less than 30 μm. The thickness of the gate terminal electrode 50 is particularly preferably not less than 80 μm and not more than 200 μm.

A planar area of the gate terminal electrode 50 is to be adjusted in accordance with the planar area of the first main surface 3. The planar area of the gate terminal electrode 50 is defined by a planar area of the gate terminal surface 51. The planar area of the gate terminal electrode 50 is preferably not more than 25% of the first main surface 3. The planar area of the gate terminal electrode 50 may be not more than 10% of the first main surface 3.

When the first main surface 3 has the planar area of not less than 1 mm square, the planar area of the gate terminal electrode 50 may be not less than 0.4 mm square. The gate terminal electrode 50 may be formed in a polygonal shape (for example, rectangular shape) having a planar area of not less than 0.4 mm×0.7 mm. The gate terminal electrode 50 is formed in a polygonal shape (quadrangle shape with four corners cut out in a rectangular shape) having four sides parallel to the first to fourth side surfaces 5A to 5D in plan view, in this embodiment. As a matter of course, the gate terminal electrode 50 may be formed in a quadrangle shape, a polygonal shape other than the quadrangle shape, a circular shape, or an elliptical shape in plan view.

The gate terminal electrode 50 includes a gate conductor layer 54 that covers the gate electrode 30. The gate conductor layer 54 covers the gate electrode 30 and the upper insulating film 38 inside the gate opening 39, in this embodiment. The gate conductor layer 54 uniformly covers the gate electrode 30 and the upper insulating film 38. The gate terminal electrode 50 therefore does not include a gap portion that penetrates the gate conductor layer 54 in a thick direction.

The gate conductor layer 54 has a laminated structure that includes a first gate conductor film 55 and a second gate conductor film 56 laminated in that order from the gate electrode 30 side, in this embodiment. The first gate conductor film 55 may include a Ti-based metal film. The first gate conductor film 55 may have a single layered structure consisting of a Ti film or a TiN film. The first gate conductor film 55 may have a laminated structure that includes the Ti film and the TiN film laminated with an arbitrary order.

The first gate conductor film 55 has a thickness less than the thickness of the gate electrode 30. The first gate conductor film 55 covers the gate electrode 30 in a film shape inside the gate opening 39 and is drawn out onto the upper insulating film 38 in a film shape. The first gate conductor film 55 forms a part of the first protrusion portion 53. The first gate conductor film 55 does not necessarily have to be formed and may be omitted.

The second gate conductor film 56 forms a body of the gate terminal electrode 50. The second gate conductor film 56 may include a Cu-based metal film. The Cu-based metal film may be a pure Cu film (Cu film with a purity of not less than 99%) or Cu alloy film. The second gate conductor film 56 includes a pure Cu plating film, in this embodiment. The second gate conductor film 56 preferably has a thickness exceeding the thickness of the gate electrode 30. The thickness of the second gate conductor film 56 particularly preferably exceeds the thickness of the upper insulating film 38. The thickness of the second gate conductor film 56 exceeds the thickness of the chip 2, in this embodiment.

The second gate conductor film 56 covers the gate electrode 30 with the first gate conductor film 55 interposed therebetween inside the gate opening 39, and is drawn out onto the upper insulating film 38 in a film shape with the first gate conductor film 55 interposed therebetween. The second gate conductor film 56 forms a part of the first protrusion portion 53. That is, the first protrusion portion 53 has a laminated structure that includes the first gate conductor film 55 and the second gate conductor film 56. The second gate conductor film 56 has a thickness exceeding the thickness of the first gate conductor film 55 in the first protrusion portion 53.

The semiconductor device 1A includes a source terminal electrode 60 that is arranged on the source electrode 32. The source terminal electrode 60 is erected in a columnar shape on a portion of the source electrode 32 that is exposed from the source opening 40. The source terminal electrode 60 may have an area less than the area of the source electrode 32 in plan view, and may be arranged on an inner portion of the source electrode 32 at an interval from the peripheral edge of the source electrode 32. The source terminal electrode 60 is formed in a polygonal shape (in this embodiment, quadrangle shape) having four sides parallel to the first to fourth side surfaces 5A to 5D in plan view, in this embodiment.

The source terminal electrode 60 has a source terminal surface 61 and a source terminal side wall 62. The source terminal surface 61 flatly extends along the first main surface 3. The source terminal surface 61 may consist of a ground surface with grinding marks. The source terminal side wall 62 is located on the upper insulating film 38 (specifically, the organic insulating film 43), in this embodiment.

That is, the source terminal electrode 60 has a portion in contact with the inorganic insulating film 42 and the organic insulating film 43. The source terminal side wall 62 extends substantially vertically to the normal direction Z. Here, “substantially vertically” includes a mode that extends in the laminate direction while being curved (meandering). The source terminal side wall 62 includes a portion that faces the source electrode 32 with the upper insulating film 38 interposed therebetween. The source terminal side wall 62 preferably consists of a smooth surface without a grinding mark.

The source terminal electrode 60 has a second protrusion portion 63 that outwardly protrudes at a lower end portion of the source terminal side wall 62. The second protrusion portion 63 is formed at a region on the upper insulating film 38 (the organic insulating film 43) side than an intermediate portion of the source terminal side wall 62. The second protrusion portion 63 extends along the outer surface of the upper insulating film 38, and is formed in a tapered shape in which a thickness gradually decreases toward the tip portion from the source terminal side wall 62 in cross sectional view. The second protrusion portion 63 therefore has a sharp-shaped tip portion with an acute angle. As a matter of course, the source terminal electrode 60 without the second protrusion portion 63 may be formed.

The source terminal electrode 60 preferably has a thickness exceeding the thickness of the source electrode 32. The thickness of the source terminal electrode 60 is defined by a distance between the source electrode 32 and the source terminal surface 61. The thickness of the source terminal electrode 60 particularly preferably exceeds the thickness of the upper insulating film 38. The thickness of the source terminal electrode 60 exceeds the thickness of the chip 2, in this embodiment.

As a matter of course, the thickness of the source terminal electrode 60 may be less than the thickness of the chip 2. The thickness of the source terminal electrode 60 may be not less than 10 μm and not more than 300 μm. The thickness of the source terminal electrode 60 is preferably not less than 30 μm. The thickness of the source terminal electrode 60 is particularly preferably not less than 80 μm and not more than 200 μm. The thickness of the source terminal electrode 60 is substantially equal to the thickness of the gate terminal electrode 50.

The source terminal electrode 60 has a source conductor layer 64, at least one (in this embodiment, a plurality of) source gap portions 65 and at least one (in this embodiment, a plurality of) source terminal portions 66. The source conductor layer 64 covers the source electrode 32 and the upper insulating film 38 inside the source opening 40, in this embodiment. The source conductor layer 64 has a laminated structure that includes a first source conductor film 67 and a second source conductor film 68 laminated in that order from the source electrode 32 side, in this embodiment.

The first source conductor film 67 may include a Ti-based metal film. The first source conductor film 67 may have a single layered structure consisting of a Ti film or a TiN film. The first source conductor film 67 may have a laminated structure that includes the Ti film and the TiN film with an arbitrary order. The first source conductor film 67 preferably consists of the same conductive material as that of the first gate conductor film 55.

The first source conductor film 67 has a thickness less than the thickness of the source electrode 32. The first source conductor film 67 covers the source electrode 32 in a film shape inside the source opening 40 and is drawn out onto the upper insulating film 38 in a film shape. The first source conductor film 67 forms a part of the second protrusion portion 63. The thickness of the first source conductor film 67 is substantially equal to the thickness of the first gate conductor film 55. The first source conductor film 67 does not necessarily have to be formed and may be omitted.

The second source conductor film 68 forms a body of the source terminal electrode 60. The second source conductor film 68 may include a Cu-based metal film. The Cu-based metal film may be a pure Cu film (Cu film with a purity of not less than 99%) or Cu alloy film. The second source conductor film 68 includes a pure Cu plating film, in this embodiment. The second source conductor film 68 preferably consists of the same conductive material as that of the second gate conductor film 56.

The second source conductor film 68 preferably has a thickness exceeding the thickness of the source electrode 32. The thickness of the second source conductor film 68 particularly preferably exceeds the thickness of the upper insulating film 38. The thickness of the second source conductor film 68 exceeds the thickness of the chip 2, in this embodiment. The thickness of the second source conductor film 68 is substantially equal to the thickness of the second gate conductor film 56.

The second source conductor film 68 covers the source electrode 32 with the first source conductor film 67 interposed therebetween inside the source opening 40, and is drawn out onto the upper insulating film 38 in a film shape with the first source conductor film 67 interposed therebetween. The second source conductor film 68 forms a part of the second protrusion portion 63. That is, the second protrusion portion 63 has a laminated structure that includes the first source conductor film 67 and the second source conductor film 68. The second source conductor film 68 preferably has a thickness exceeding the thickness of the first source conductor film 67 in the second protrusion portion 63.

The source gap portions 65 penetrate the source conductor layer 64 and define the source conductor layer 64 into a plural portions (regions) in cross sectional view. The source gap portions 65 are formed at positions overlapping the source electrode 32 and expose parts of the source electrode 32. The source gap portions 65 also expose parts of the upper insulating film 38, in this embodiment. The source gap portions 65 include a first source gap portion 65A and a second source gap portion 65B each extending in different directions, in this embodiment.

The first source gap portion 65A is formed in a band shape extending in the first direction X in plan view and divides the source conductor layer 64 into the second direction Y. The first source gap portion 65A crosses a central portion of the source conductor layer 64 in the first direction X in plan view, in this embodiment. The second source gap portion 65B is formed in a band shape extending in the second direction Y such as to intersect the first source gap portion 65A in plan view and divides the source conductor layer 64 into the first direction X.

The second source gap portion 65B crosses the central portion of the source conductor layer 64 in the second direction Y in plan view, in this embodiment. That is, the second source gap portion 65B intersects the first source gap portion 65A at the central portion of the source conductor layer 64. The intersecting portion of the first source gap portion 65A and the second source gap portion 65B faces the gate terminal electrode 50 in the first direction X in plan view.

As a matter of course, the first source gap portion 65A may crosses a central portion of the first main surface 3 (the chip 2) in the first direction X in plan view. Also, the second source gap portion 65B may cross the central portion of the first main surface 3 (the chip 2) in the second direction Y in plan view. Also, the first source gap portion 65A may be formed offset in the second direction Y from the central portion of the source conductor layer 64. Also, the second source gap portion 65B may be formed offset in the first direction X from the central portion of the source conductor layer 64. The source gap portions 65 does not necessarily include both the first source gap portion 65A and the second source gap portion 65B at the same time, and may include only one of the first source gap portion 65A and the second source gap portion 65B.

The plurality of source terminal portions 66 consist of the plurality of portions that are defined by the source gap portions 65 in the source conductor layer 64. That is, four source terminal portions 66 are demarcated by the first source gap portion 65A and the second source gap portion 65B, in this embodiment. The plurality of source terminal portions 66 are each fixed to a same potential as that of the source electrode 32. That is, the source terminal electrode 60 is configured such that a source potential (single potential) is given to the single source electrode 32 via the plurality of source terminal portions 66.

The plurality of source terminal portions 66 are arranged on the body electrode portion 33 of the source electrode 32, and are not arranged on the drawer electrode portions 34A, 34B of the source electrode 32, in this embodiment. A facing area between the gate terminal electrode 50 and the source terminal portions 66 is thereby reduced.

Such a structure is effective in reducing a risk of short-circuit between the gate terminal electrode 50 and the source terminal portions 66, in a case in which conductive adhesives such as solders and metal pastes are to be adhered to the gate terminal electrode 50 and the source terminal portions 66. As a matter of course, conductive bonding members such as conductor plates and conducting wires (for example, bonding wires) may be connected to the gate terminal electrode 50 and the source terminal portions 66. In this case, a risk of short-circuit between the conductive bonding member on the gate terminal electrode 50 side and the conductive bonding member on the source terminal portions 66 side can be reduced.

The plurality of source terminal portions 66 each has a source gap side wall 69 defined by the source gap portion 65. The source gap side wall 69 preferably consists of a smooth surface without a grinding mark. The plurality of source terminal portions 66 each has the second protrusion portion 63 at a lower end portion of the source gap side wall 69, in this embodiment. The second protrusion portion 63 on the source gap side wall 69 side is positioned on the source electrode 32.

A planar area of each of the source terminal portions 66 is adjusted in accordance with the planar area of the first main surface 3. The planar area of each of the source terminal portions 66 is defined by a planar area of a portion demarcated by the source terminal side wall 62 and the source gap side walls 69 in the source terminal surface 61. A total planar area of the source terminal portions 66 preferably exceeds the planar area of the gate terminal electrode 50. The planar area of each of the source terminal portions 66 is preferably not less than the planar area of the gate terminal electrode 50. The planar area of each of the source terminal portions 66 is particularly preferably exceeds the planar area of the gate terminal electrode 50. The total planar area of the source terminal portions 66 is preferably not less than 50% of the first main surface 3. The total planar area of the source terminal portions 66 is particularly preferably not less than 75% of the first main surface 3.

In a case in which the first main surface 3 has a planar area of not less than 1 mm square, the planar area of each of the source terminal portions 66 is preferably not less than 0.8 mm square. In this case, the planar area of each of the source terminal portions 66 is particularly preferably not less than 1 mm square. Each of the source terminal portions 66 may be formed in a polygonal shape having a planar area of not less than 1 mm×1.4 mm. Each of the source terminal portions 66 is formed in a quadrangle shape having four sides parallel to the first to fourth side surfaces 5A to 5D in plan view, in this embodiment. As a matter of course, each of the source terminal portions 66 may be formed in a polygonal shape other than the quadrangle shape, a circular shape, or an elliptical shape in plan view.

The semiconductor device 1A includes a sealing insulator 71 that covers the first main surface 3. The sealing insulator 71 covers a periphery of the gate terminal electrode 50 and a periphery of the source terminal electrode 60 such as to expose a part of the gate terminal electrode 50 and a part of the source terminal electrode 60 on the first main surface 3. Specifically, the sealing insulator 71 covers the active surface 8, the outer surface 9 and the first to fourth connecting surfaces 10A to 10D such as to expose the gate terminal electrode 50 and the source terminal electrode 60.

The sealing insulator 71 exposes the gate terminal surface 51 and the source terminal surface 61 and covers the gate terminal side wall 52 and the source terminal side wall 62. The sealing insulator 71 covers the first protrusion portion 53 of the gate terminal electrode 50 and faces the upper insulating film 38 with the first protrusion portion 53 interposed therebetween, in this embodiment. The sealing insulator 71 suppresses a dropout of the gate terminal electrode 50. Also, the sealing insulator 71 covers the second protrusion portion 63 of the source terminal electrode 60 and faces the upper insulating film 38 with the second protrusion portion 63 interposed therebetween, in this embodiment. The sealing insulator 71 suppresses a dropout of the source terminal electrode 60.

The sealing insulator 71 covers the dicing street 41 at the peripheral edge portion of the outer surface 9. The sealing insulator 71 directly covers the interlayer insulating film 27 at the dicing street 41, in this embodiment. As a matter of course, when the chip 2 (the outer surface 9) or the main surface insulating film 25 is exposed from the dicing street 41, the sealing insulator 71 may directly cover the chip 2 or the main surface insulating film 25 at the dicing street 41.

The sealing insulator 71 has an insulating main surface 72 and an insulating side wall 73. The insulating main surface 72 flatly extends along the first main surface 3. The insulating main surface 72 forms a single flat surface with the gate terminal surface 51 and the source terminal surface 61. The insulating main surface 72 may consist of a ground surface with grinding marks. In this case, the insulating main surface 72 preferably forms a single ground surface with the gate terminal surface 51 and the source terminal surface 61.

The insulating side wall 73 extends toward the chip 2 from a peripheral edge of the insulating main surface 72 and forms a single flat surface with the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The sealing insulator 71 preferably has a thickness exceeding the thickness of the gate electrode 30 and the thickness of the source electrode 32. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm. The thickness of the sealing insulator 71 is substantially equal to the thickness of the gate terminal electrode 50 and the thickness of the source terminal electrode 60.

The sealing insulator 71 includes a matrix resin, a plurality of fillers and a plurality of flexible particles (flexible agent). The sealing insulator 71 is configured such that a mechanical strength is adjusted by the matrix resin, the plurality of fillers and the plurality of flexible particles. The sealing insulator 71 may include at least the matrix resin, and the presence or the absence of the fillers and the flexible particles is optional.

The sealing insulator 71 may include a coloring material such as carbon black that colors the matrix resin. The matrix resin preferably consists of a thermosetting resin. The matrix resin may include at least one of an epoxy resin, a phenol resin and a polyimide resin as an example of the thermosetting resin. The matrix resin includes the epoxy resin, in this embodiment.

The plurality of fillers are added into the matrix resin and are composed of one of or both of spherical objects each consisting of an insulator and indeterminate objects each consisting of an insulator. The indeterminate object has a random shape other than a sphere shape such as a grain shape, a piece shape and a fragment shape. The indeterminate object may have an edge. The plurality of fillers are each composed of the spherical object from a viewpoint of suppressing a damage to be caused by a filler attack, in this embodiment.

The plurality of fillers may include at least one of ceramics, oxides and nitrides. The plurality of fillers each consist of silicon oxide particles (silicon particles), in this embodiment. The plurality of fillers may each have a particle size of not less than 1 nm and not more than 100 μm. The particle sizes of the plurality of fillers are preferably not more than 50 μm.

The sealing insulator 71 preferably include a plurality of fillers differing in the particle sizes. The plurality of fillers may include a plurality of small size fillers, a plurality of medium size fillers and a plurality of large size fillers. The plurality of fillers are preferably added into the matrix resin with a content (density) being in this order of the small size fillers, the medium size fillers and the large size fillers.

The small size fillers may have a thickness less than the thickness of the source electrode 32 (the gate electrode 30). The particle sizes of the small size fillers may be not less than 1 nm and not more than 1 μm. The medium size fillers may have a thickness exceeding the thickness of the source electrode 32 and not more than the thickness of the upper insulating film 38. The particle sizes of the medium size fillers may be not less than 1 μm and not more than 20 μm.

The large size fillers may have a thickness exceeding the thickness of the upper insulating film 38. The plurality of fillers may include at least one large size filler exceeding any one of the thickness of the first semiconductor region 6 (the epitaxial layer), the thickness of the second semiconductor region 7 (the substrate) and the thickness of the chip 2. The particle sizes of the large size fillers may be not less than 20 μm and not more than 100 μm. The particle sizes of the large size fillers are preferably not more than 50 μm.

An average particle size of the plurality of fillers may be not less than 1 μm and not more than 10 μm. The average particle size of the plurality of fillers is preferably not less than 4 μm and not more than 8 μm. As a matter of course, the plurality of fillers does not necessarily have to include all of the small size fillers, the medium size fillers and the large size fillers at the same time, and may be composed of one of or both of the small size fillers and the medium size fillers. For example, in this case, a maximum particle size of the plurality of fillers (the medium size fillers) may be not more than 10 μm.

The sealing insulator 71 may include a plurality of filler fragments each having a broken particle shape in a surface layer portion of the insulating main surface 72 and in a surface layer portion of the insulating side wall 73. The plurality of filler fragments may each be formed by any one of a part of the small size fillers, a part of the medium size fillers and a part of the large size fillers.

The plurality of filler fragments positioned on the insulating main surface 72 side each has a broken portion that is formed along the insulating main surface 72 such as to be oriented to the insulating main surface 72. The plurality of filler fragments positioned on the insulating side wall 73 side each has a broken portion that is formed along the insulating side wall 73 such as to be oriented to the insulating side wall 73. The broken portions of the plurality of filler fragments may be exposed from the insulating main surface 72 and the insulating side wall 73, or may be partially or wholly covered with the matrix resin. The plurality of filler fragments do not affect the structures on the chip 2 side, since the plurality of filler fragments are located in the surface layer portions of the insulating main surface 72 and the insulating side wall 73.

The plurality of flexible particles are added into the matrix resin. The plurality of flexible particles may include at least one of a silicone-based flexible particles, an acrylic-based flexible particles and a butadiene-based flexible particles. The sealing insulator 71 preferably includes the silicone-based flexible particles. The plurality of flexible particles preferably have an average particle size less than the average particle size of the plurality of fillers. The average particle size of the plurality of flexible particles is preferably not less than 1 nm and not more than 1 μm. A maximum particle size of the plurality of flexible particles is preferably not more than 1 μm.

The plurality of flexible particles are added into the matrix resin such that a ratio of a total cross-sectional area with respect to a unit cross-sectional area is to be not less than 0.1% and not more than 10%. In other words, the plurality of flexible particles are added into the matrix resin with a content of a range of not less than 0.1 wt % and not more than 10 wt %. The average particle size and the content of the plurality of flexible particles are to be adjusted in accordance with an elastic modulus to be imparted to the sealing insulator 71 at a time of manufacturing and/or after manufacturing. For example, according to the plurality of flexible particles having the average particle size of a submicron order (=not more than 1 μm), it makes it possible to contribute to a low elastic modulus and a low curing shrinkage of the sealing insulator 71.

The semiconductor device 1A includes a gap insulator 74 that is embedded into the source gap portions 65 such as to expose a part of the source terminal electrode 60 (parts of the plurality of source terminal portions 66). The gap insulator 74 embedded into the first source gap portion 65A and the second source gap portion 65B, in this embodiment. That is, the gap insulator 74 includes a first gap insulator 74A and a second gap insulator 74B, in this embodiment.

The first gap insulator 74A is embedded into the first source gap portion 65A and extends in the first direction X along the first source gap portion 65A. The second gap insulator 74B is embedded into the second source gap portion 65B and extends in the second direction Y along the second source gap portion 65B. The gap insulator 74 therefore covers the source electrode 32 in a lattice pattern (cross pattern) in plan view.

The gap insulator 74 covers the source gap side walls 69 of the plurality of source terminal portions 66 in the first source gap portion 65A and the second source gap portion 65B. That is, the gap insulator 74 partitions the plurality of source terminal portions 66 inside the source gap portions 65. The gap insulator 74 keeps the plurality of source terminal portions 66 fixed at the same potential as that of the source electrode 32, and physically divides the plurality of source terminal portions 66 on the source electrode 32. In other words, the gap insulator 74 is configured such as to allow a vertical current transfer among the plurality of source terminal portions 66 and the source electrode 32, and restrict a lateral current transfer among the plurality of source terminal portions 66.

The gap insulator 74 has a portion that directly covers the source electrode 32 inside the source gap portions 65, in this embodiment. Also, the gap insulator 74 covers the second protrusion portion 63 inside the source gap portions 65, and covers the source electrode 32 with the second protrusion portion 63 interposed therebetween. The gap insulator 74 suppresses a dropout of the source terminal portions 66. Also, the gap insulator 74 has a portion that directly covers the upper insulating film 38 inside the source gap portions 65, in this embodiment. The gap insulator 74 is connected to the sealing insulator 71 outside the source gap portions 65.

The gap insulator 74 consists of a part of the sealing insulator 71, in this embodiment. That is, the gap insulator 74 has the insulating main surface 72 that is continuous to the gate terminal surface 51 and the source terminal surface 61. Also, the gap insulator 74 includes the thermosetting resin, the plurality of fillers and the plurality of flexible particles. As a matter of course, the gap insulator 74 may consist of an insulating material different from that of the sealing insulator 71.

The semiconductor device 1A includes a drain electrode 77 (second main surface electrode) that covers the second main surface 4. The drain electrode 77 is electrically connected to the second main surface 4. The drain electrode 77 forms an ohmic contact with the second semiconductor region 7 that is exposed from the second main surface 4. The drain electrode 77 may cover a whole region of the second main surface 4 such as to be continuous with the peripheral edge of the chip 2 (the first to fourth side surfaces 5A to 5D).

The drain electrode 77 may cover the second main surface 4 at an interval from the peripheral edge of the chip 2. The drain electrode 77 is configured such that a drain source voltage of not less than 500 V and not more than 3000 V is to be applied between the source terminal electrode 60 (the plurality of source terminal portions 66) and the drain electrode 77. That is, the chip 2 is formed such that the voltage of not less than 500 V and not more than 3000 V is to be applied between the first main surface 3 and the second main surface 4.

As described above, the semiconductor device 1A includes the chip 2, the source electrode 32 (main surface electrode) and the source terminal electrode 60. The chip 2 has the first main surface 3. The source electrode 32 is arranged on the first main surface 3. The source terminal electrode 60 is arranged on the source electrode 32 and is fixed to the same potential as the potential of the source electrode 32. The source terminal electrode 60 includes the source conductor layer 64 and the source gap portion 65. The source conductor layer 64 covers the source electrode 32. The source gap portion 65 penetrates the source conductor layer 64 in the thickness direction in cross sectional view.

According to this structure, a volume of the source terminal electrode 60 is reduced by the source gap portion 65, and therefore a stress due to the source terminal electrode 60 is reduced. The source gap portion 65 is also effective in blocking a stress continuously generated in a width direction of the source terminal electrode 60. It is therefore possible to suppress fluctuations in electrical characteristics and shape defects due to the stress of the source terminal electrode 60. As a result, it is possible to provide the semiconductor device 1A capable of improving reliability.

The semiconductor device 1A preferably includes the gap insulator 74 embedded in the source gap portion 65. According to this structure, the source electrode 32 and the source terminal electrode 60 can be protected from an external force and a humidity (moisture) by the gap insulator 74. Therefore, it is possible to improve the reliability. The semiconductor device 1A preferably includes the sealing insulator 71 that covers the periphery of the source terminal electrode 60 on the first main surface 3 such as to expose a part of the source terminal electrode 60.

According to this structure, an object to be sealed can be protected from the external force and the humidity by the sealing insulator 71. That is, the object to be sealed can be protected from a damage (including peeling) due to the external force and deterioration (including corrosion) due to the humidity. It is therefore possible to suppress the shape defects and the fluctuations in electrical characteristics. As a result, it is possible to improve the reliability. In such a structure, the gap insulator 74 preferably consists of a part of the sealing insulator 71.

The semiconductor device 1A preferably includes the upper insulating film 38 that partially covers the source electrode 32. According to this structure, the source electrode 32 can be protected from the external force and the humidity with the upper insulating film 38. That is, according to this structure, the source electrode 32 can be protected by both of the upper insulating film 38 and the sealing insulator 71. The source terminal electrode 60 may have the portion directly covering the source electrode 32 and the portion directly covering the upper insulating film 38. Also, the gap insulator 74 may have the portion directly covering the source electrode 32 and the portion directly covering the upper insulating film 38.

Also, the sealing insulator 71 preferably has the portion directly covering the upper insulating film 38. The sealing insulator 71 preferably has the portion covering the source electrode 32 across the upper insulating film 38 interposed therebetween. The upper insulating film 38 preferably includes any one of or both of the inorganic insulating film 42 and the organic insulating film 43. The organic insulating film 43 preferably consists of the photosensitive resin film.

The upper insulating film 38 is preferably thicker than the source electrode 32. The upper insulating film 38 is preferably thinner than the chip 2. The sealing insulator 71 is preferably thicker than the source electrode 32. The sealing insulator 71 is preferably thicker than the upper insulating film 38. The sealing insulator 71 is particularly preferably thicker than the chip 2.

Those above structures are effective when the source terminal electrode 60 having a relatively large planar area and/or a relatively large thickness is applied to the chip 2 having a relatively large planar area and/or a relatively small thickness. The source terminal electrode 60 having the relatively large planar area and/or the relatively large thickness is also effective in absorbing a heat generated on the chip 2 side and dissipating the heat to the outside.

Also, according to the source gap portion 65, it is possible to appropriately relax the stress caused in the source terminal electrode 60 having the relatively large planar area and/or the relatively large thickness. For example, the source terminal electrode 60 is preferably thicker than the source electrode 32. The source terminal electrode 60 is preferably thicker than the upper insulating film 38. The source terminal electrode 60 is particularly preferably thicker than the chip 2. For example, the source terminal electrode 60 may cover the region of not less than 50% of the first main surface 3 in plan view.

For example, the chip 2 may have the first main surface 3 having the area of not less than 1 mm square in plan view. The chip 2 may have the thickness of not more than 100 μm in cross sectional view. The chip 2 preferably has the thickness of not more than 50 μm in cross sectional view. The chip 2 may have the laminated structure that includes the semiconductor substrate and the epitaxial layer. In this case, the epitaxial layer is preferably thicker than the semiconductor substrate.

In those above structures, the chip 2 preferably includes the monocrystal of the wide bandgap semiconductor. The monocrystal of the wide bandgap semiconductor is effective in improving electrical characteristics. Also, according to the monocrystal of the wide bandgap semiconductor, it is possible to achieve a thinning of the chip 2 and an increasing of the planar area of the chip 2 while suppressing a deformation of the chip 2 with a relatively high hardness. The thinning of the chip 2 and the increasing of the planar area of the chip 2 are also effective in improving the electrical characteristics.

The structure having the sealing insulator 71 is also effective in a structure that includes the drain electrode 77 covering the second main surface 4 of the chip 2. The drain electrode 77 forms a potential difference (for example, not less than 500 V and not more than 3000 V) with the source electrode 32 via the chip 2. In particular, in a case in which the chip 2 is relatively thin, a risk of a discharge phenomenon between the peripheral edge of the first main surface 3 and the source electrode 32 increases, since a distance between the source electrode 32 and the drain electrode 77 is shortened. In this point, according to the structure having the sealing insulator 71, an insulation property between the peripheral edge of the first main surface 3 and the source electrode 32 can be improved, and therefore the discharge phenomenon can be suppressed.

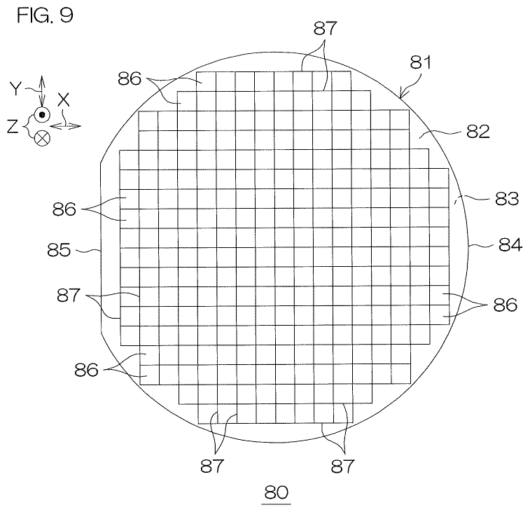

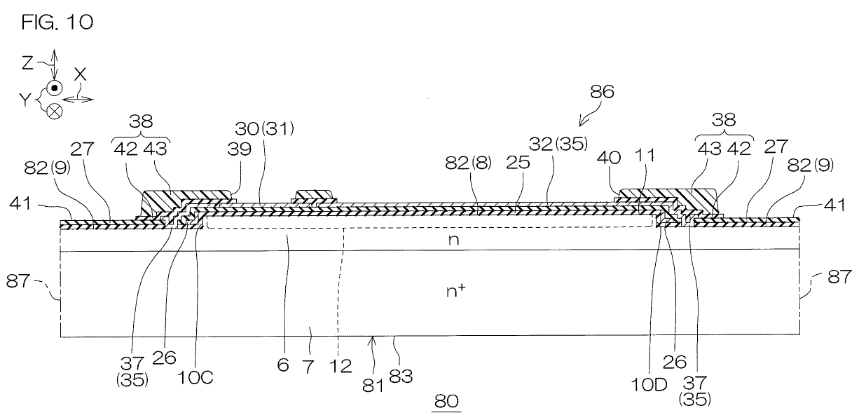

FIG. 9 is a plan view showing a wafer structure 80 that is to be used at a time of manufacturing of the semiconductor device 1A shown in FIG. 1. FIG. 10 is a cross sectional view showing a device region 86 shown in FIG. 9. With reference to FIG. 9 and FIG. 10, the wafer structure 80 includes a wafer 81 formed in a disc shape. The wafer 81 is to be a base of the chip 2. The wafer 81 has a first wafer main surface 82 on one side, a second wafer main surface 83 on the other side, and a wafer side surface 84 connecting the first wafer main surface 82 and the second wafer main surface 83.

The wafer 81 has a mark 85 indicating a crystal orientation of the SiC monocrystal on the wafer side surface 84. The mark 85 includes an orientation flat cut out in a straight line in plan view, in this embodiment. The orientation flat extends in the second direction Y, in this embodiment. The orientation flat does not necessarily have to extend in the second direction Y and may extend in the first direction X.

As a matter of course, the mark 85 may include a first orientation flat extending in the first direction X and a second orientation flat extending in the second direction Y. Also, the mark 85 may have an orientation notch, instead of the orientation flat, cut out toward a central portion of the wafer 81. The orientation notch may be a notched portion cut into a polygonal shape such as a triangle shape and a quadrangle shape in plan view.

The wafer 81 may have a diameter of not less than 50 mm and not more than 300 mm (that is, not less than 2 inch and not more than 12 inch). The diameter of the wafer structure 80 is defined by a length of a chord passing through a center of the wafer structure 80 outside the mark 85. The wafer structure 80 may have a thickness of not less than 100 μm and not more than 1100 μm.

The wafer structure 80 includes the first semiconductor region 6 formed in a region on the first wafer main surface 82 side and the second semiconductor region 7 formed in a region on the second wafer main surface 83 side, inside the wafer 81. The first semiconductor region 6 is formed by an epitaxial layer, and the second semiconductor region 7 formed by a semiconductor substrate. That is, the first semiconductor region 6 is formed by an epitaxial growth of a semiconductor monocrystal from the second semiconductor region 7 by an epitaxial growth method. The second semiconductor region 7 preferably has a thickness exceeding a thickness of the first semiconductor region 6.

The wafer structure 80 includes a plurality of device regions 86 and a plurality of scheduled cutting lines 87 that are provided in the first wafer main surface 82. The plurality of device regions 86 are regions each corresponding to the semiconductor device 1A. The plurality of device regions 86 are each set in a quadrangle shape in plan view. The plurality of device regions 86 are arrayed in a matrix pattern along the first direction X and the second direction Y in plan view, in this embodiment.

The plurality of scheduled cutting lines 87 are lines (regions extending in band shapes) that define positions to be the first to fourth side surfaces 5A to 5D of the chip 2. The plurality of scheduled cutting lines 87 are set in a lattice pattern extending along the first direction X and the second direction Y such as to define the plurality of device regions 86. For example, the plurality of scheduled cutting lines 87 may be demarcated by alignment marks and the like that are provided inside and/or outside the wafer 81.

The wafer structure 80 includes the mesa portion 11, the MISFET structure 12, the outer contact region 19, the outer well region 20, the field regions 21, the main surface insulating film 25, the side wall structure 26, the interlayer insulating film 27, the gate electrode 30, the source electrode 32, the plurality of gate wirings 36A, 36B, the source wiring 37 and the upper insulating film 38 formed in each of the device regions 86, in this embodiment.

The wafer structure 80 includes the dicing street 41 demarcated in regions among the plurality of upper insulating films 38. The dicing street 41 straddles the plurality of device regions 86 across the plurality of scheduled cutting lines 87 such as to expose the plurality of scheduled cutting lines 87. The dicing street 41 is formed in a lattice pattern extending along the plurality of scheduled cutting lines 87. The dicing street 41 exposes the interlayer insulating film 27, in this embodiment. As a matter of course, in a case in which the interlayer insulating film 27 exposing the first wafer main surface 82, the dicing street 41 may expose the first wafer main surface 82.

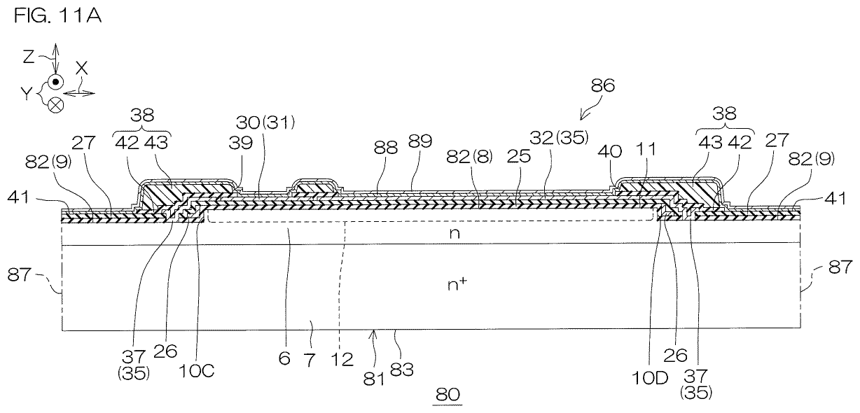

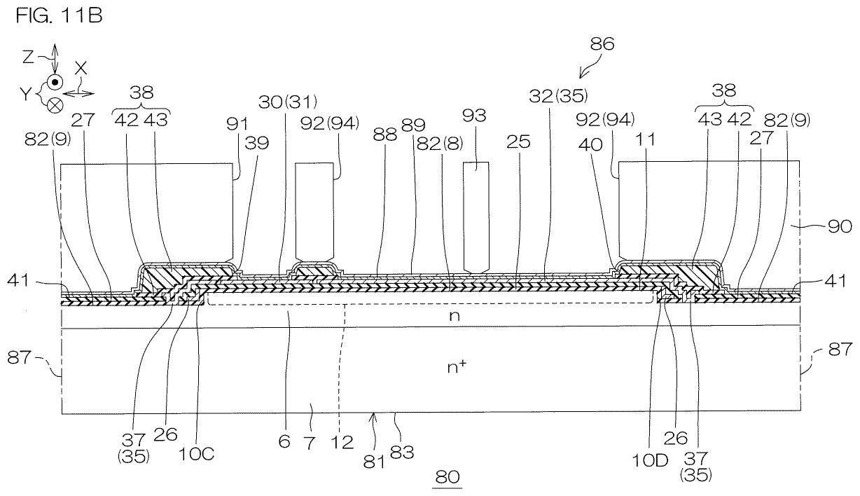

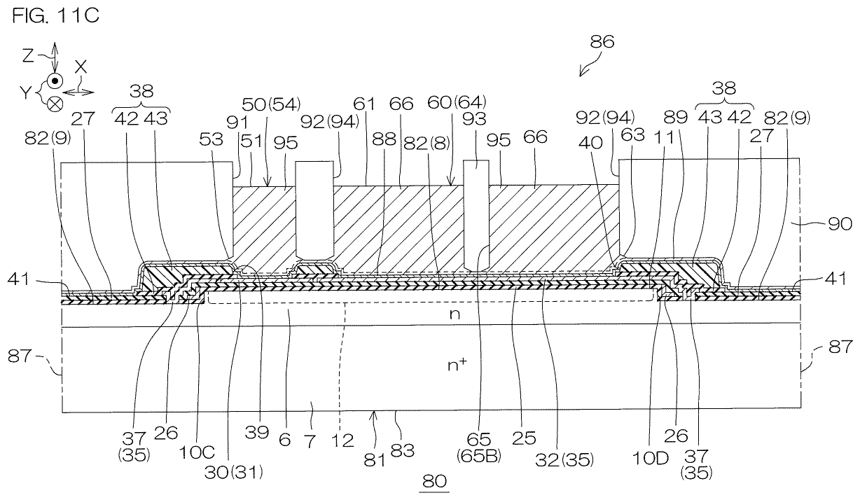

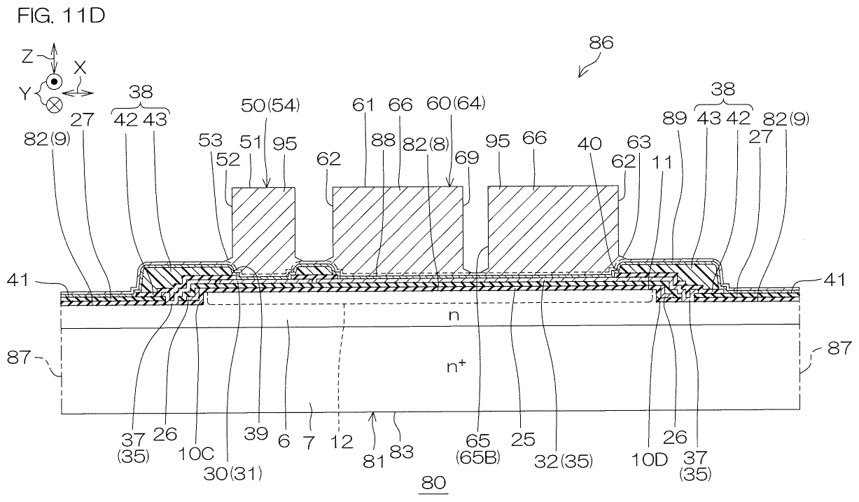

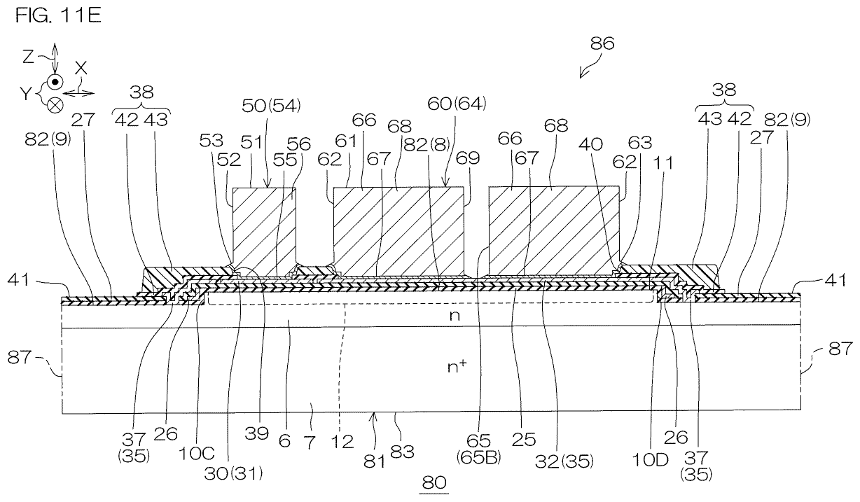

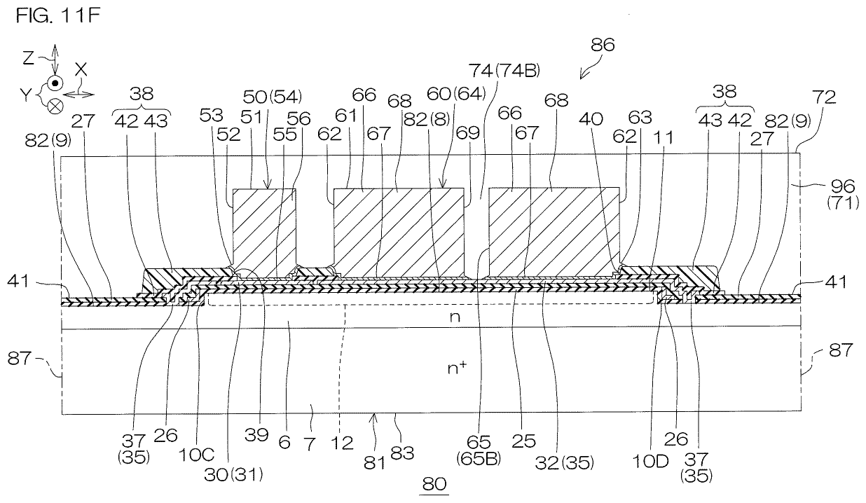

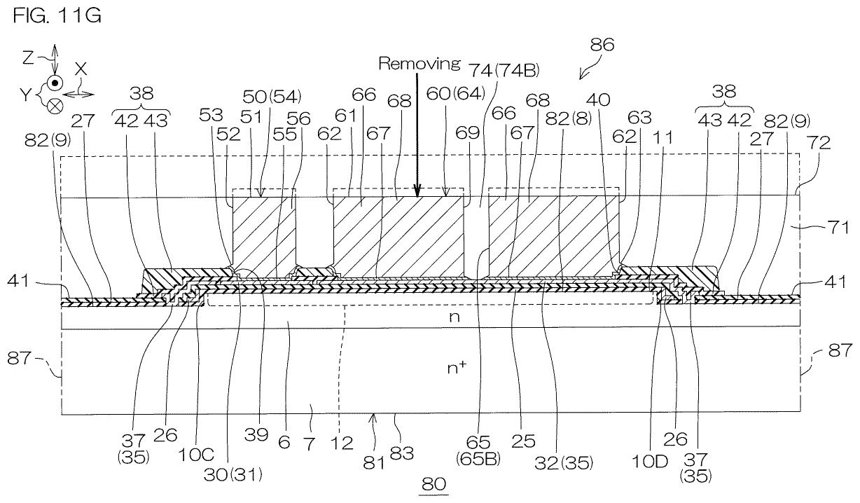

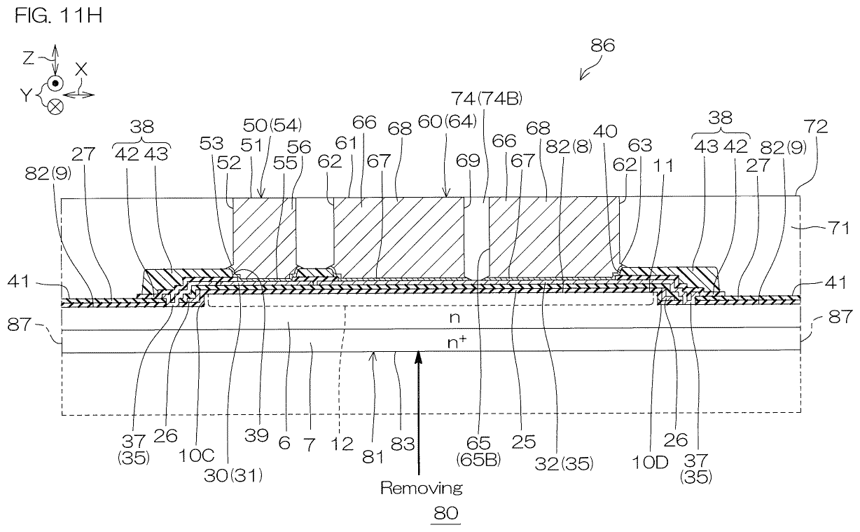

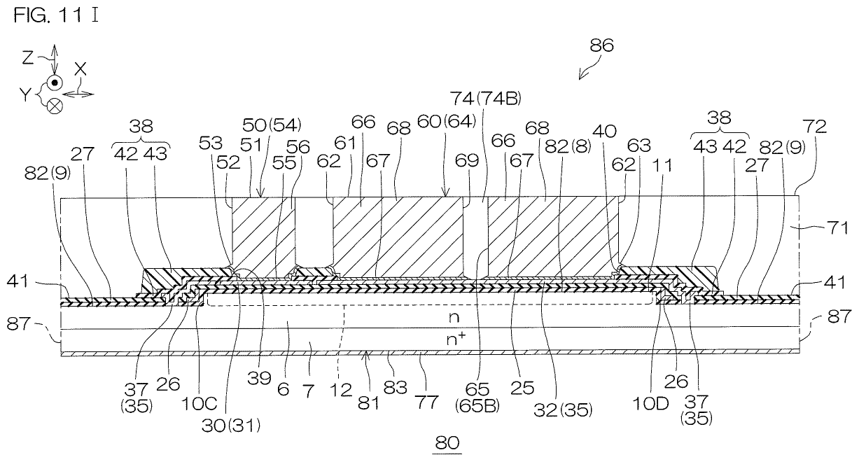

FIG. 11A to FIG. 11I are cross sectional views showing a manufacturing method example for the semiconductor device 1A shown in FIG. 1. Descriptions of the specific features of each structure formed in each process shown in FIG. 11A to FIG. 11I shall be omitted or simplified, since those have been as described above.

With reference to FIG. 11A, the wafer structure 80 is prepared (see FIG. 9 and FIG. 10). Next, a first base conductor film 88 to be a base of the first gate conductor film 55 and the first source conductor film 67 is formed on the wafer structure 80. The first base conductor film 88 is formed in a film shape along the interlayer insulating film 27, the gate electrode 30, the source electrode 32, the plurality of gate wirings 36A, 36B, the source wiring 37 and the upper insulating film 38. The first base conductor film 88 includes a Ti-based metal film. The first base conductor film 88 may be formed by a sputtering method and/or a vapor deposition method.

Next, a second base conductor film 89 to be a base of the second gate conductor film 56 and the second source conductor film 68 is formed on the first base conductor film 88. The second base conductor film 89 covers the interlayer insulating film 27, the gate electrode 30, the source electrode 32, the plurality of gate wirings 36A, 36B, the source wiring 37 and the upper insulating film 38 in a film shape with the first base conductor film 88 interposed therebetween. The second base conductor film 89 includes a Cu-based metal film. The second base conductor film 89 may be formed by a sputtering method and/or a vapor deposition method.

Next, with reference to FIG. 11B, a resist mask 90 having a predetermined pattern is formed on the second base conductor film 89. The resist mask 90 includes a first opening 91 exposing the gate electrode 30 and a second opening 92 exposing the source electrode 32. The first opening 91 exposes a region in which the gate terminal electrode 50 is to be formed at a region on the gate electrode 30. The second opening 92 exposes a region in which the source terminal electrode 60 is to be formed at a region on the source electrode 32.

The resist mask 90 has a wall portion 93 that selectively covers the source electrode 32 inside the second opening 92. The wall portion 93 covers a region in which the source gap portions 65 (in this embodiment, the first and second source gap portions 65A, 65B) are to be formed and exposes a region in which the plurality of source terminal portions 66 are to be formed. The wall portion 93 is drawn out from a wall surface of the second opening 92 onto the source electrode 32, in this embodiment.

Specifically, the wall portion 93 has a portion extending in a band shape in the first direction X and a portion extending in a band shape in the second direction Y in plan view. The portion extending in the second direction Y intersects the portion extending in the first direction X. That is, the wall portion 93 is formed in a lattice shape (cross shape) inside the second opening 92 and partitioned a plurality of opening portions 94 inside the second opening 92, in this embodiment. That is, the wall portion 93 is formed as a partition wall portion, in this embodiment.

This step includes a step of reducing an adhesion of the resist mask 90 with respect to the second base conductor film 89. The adhesion of the resist mask 90 is to be adjusted by adjusting exposure conditions and/or bake conditions (baking temperature, time, etc.,) after exposure for the resist mask 90. Through this step, a growth starting point of the first protrusion portion 53 is formed at a lower end portion of the first opening 91, a growth starting point of the second protrusion portion 63 is formed at a lower end portion of the second opening 92, and a growth starting point of the second protrusion portion 63 is formed at a lower end portion of the wall portion 93.

Next, with reference to FIG. 11C, a third base conductor film 95 to be a base of the second gate conductor film 56 and the second source conductor film 68 is formed on the second base conductor film 89. The third base conductor film 95 is formed by depositing a conductor (in this embodiment, Cu-based metal) in the first opening 91 and the second opening 92 by a plating method (for example, electroplating method), in this embodiment. The third base conductor film 95 integrates with the second base conductor film 89 inside the first opening 91 and the second opening 92.

Through this step, the gate terminal electrode 50 that includes the gate conductor layer 54 covering the gate electrode 30 is formed. Also, the source terminal electrode 60 that includes the source conductor layer 64 covering the source electrode 32 and the source gap portions 65 partitioned by the wall portion 93. A volume of the source terminal electrode 60 is reduced by a volume of the wall portion 93.

This step includes a step of entering a plating solution between the second base conductor film 89 and the resist mask 90 at the lower end portion of the first opening 91. Also, this step includes a step of entering the plating solution between the second base conductor film 89 and the resist mask 90 at the lower end portion of the second opening 92. Also, this step includes a step of entering the plating solution between the second base conductor film 89 and the resist mask 90 at the lower end portion of the wall portion 93.

Through this step, a part of the third base conductor film 95 (the gate terminal electrode 50) is grown into a protrusion shape at the lower end portion of the first opening 91 and the first protrusion portion 53 is thereby formed. Also, a part of the third base conductor film 95 (the source terminal electrode 60) is grown into a protrusion shape at the lower end portion of the second opening 92 and the second protrusion portion 63 is thereby formed. Also, a part of the third base conductor film 95 (the plurality of source terminal portions 66) is grown into a protrusion shape at the lower end portion of the wall portion 93 and the second protrusion portion 63 is thereby formed.

Next, with reference to FIG. 11D, the resist mask 90 is removed. Through this step, the gate terminal electrode 50 is exposed outside. Also, the source terminal electrode 60 including the source gap portions 65 and the source terminal portions 66 is exposed outside.

Next, with reference to FIG. 11E, a portion of the second base conductor film 89 that is exposed from the gate terminal electrode 50 and the source terminal electrode 60 is removed. An unnecessary portion of the second base conductor film 89 may be removed by an etching method. The etching method may be a wet etching method and/or a dry etching method. Next, a portion of the first base conductor film 88 that is exposed from the gate terminal electrode 50 and the source terminal electrode 60 is removed. An unnecessary portion of the first base conductor film 88 may be removed by an etching method. The etching method may be a wet etching method and/or a dry etching method.

Next, with reference to FIG. 11F, a sealant 96 is supplied on the first wafer main surface 82 such as to cover the gate terminal electrode 50 and the source terminal electrode 60. The sealant 96 is to be a base of the sealing insulator 71. The sealant 96 enters into the source gap portions 65 and covers a whole region of the upper insulating film 38, a whole region of the gate terminal electrode 50 and a whole region of the source terminal electrode 60.

The sealant 96 includes the thermosetting resin, the plurality of fillers and the plurality of flexible particles (flexible agent) in this embodiment, and is hardened by heating. Through this step, the sealing insulator 71 is formed. The sealing insulator 71 has the insulating main surface 72 that covers the whole region of the gate terminal electrode 50 and the whole region of the source terminal electrode 60.

Next, with reference to FIG. 11G, the sealing insulator 71 is partially removed. The sealing insulator 71 is ground from the insulating main surface 72 side by a grinding method, in this embodiment. The grinding method may be a mechanical polishing method and/or a chemical mechanical polishing method. The insulating main surface 72 is ground until the gate terminal electrode 50 and the source terminal electrode 60 are exposed. This step includes a grinding step of the gate terminal electrode 50 and the source terminal electrode 60. Through this step, the insulating main surface 72 that forms the single grinding surface with the gate terminal electrode 50 (the gate terminal surface 51) and the source terminal electrode 60 (the source terminal surface 61) is formed.

The sealing insulator 71 may be formed in a semi-cured state (incompletely cured state) by adjusting the heating conditions in the step of FIG. 11F aforementioned. In this case, the sealing insulator 71 is ground in the step of FIG. 11G and then heated again to form a fully cured state (completely cured state). In this case, it is possible to easily remove the sealing insulator 71.

Next, with reference to FIG. 11H, the wafer 81 is partially removed from the second wafer main surface 83 side, and the wafer 81 is thinned until a desired thickness is obtained. The thinning step of the wafer 81 is performed by an etching method and/or a grinding method. The etching method may be a wet etching method and/or a dry etching method. The grinding method may be a mechanical polishing method and/or a chemical mechanical polishing method.

This step includes a step of thinning the wafer 81 by using the sealing insulator 71 as a supporting member that supports the wafer 81. This allows for proper handling of the wafer 81. Also, it is possible to suppress a deformation (warpage due to thinning) of the wafer 81 with the sealing insulator 71, and therefore the wafer 81 can be appropriately thinned.

As one example, in a case in which the thickness of the wafer 81 is less than the thickness of the sealing insulator 71, the wafer 81 is further thinned. As the other example, in a case in which the thickness of the wafer 81 is not less than the thickness of the sealing insulator 71, the wafer 81 is thinned until the thickness of the wafer 81 becomes less than the thickness of the sealing insulator 71. In those cases, the wafer 81 is preferably thinned until a thickness of the second semiconductor region 7 (the semiconductor substrate) becomes less than a thickness of the first semiconductor region 6 (the epitaxial layer).

As a matter of course, the thickness of the second semiconductor region 7 (the semiconductor substrate) may be not less than the thickness of the first semiconductor region 6 (the epitaxial layer). Also, the wafer 81 may be thinned until the first semiconductor region 6 is exposed from the second wafer main surface 83. That is, all of the second semiconductor region 7 may be removed.

Next, with reference to FIG. 11I, the drain electrode 77 covering the second wafer main surface 83 is formed. The drain electrode 77 may be formed by a sputtering method and/or a vapor deposition method. Then, the wafer structure 80 and the sealing insulator 71 are cut along the plurality of scheduled cutting lines 87. The wafer structure 80 and the sealing insulator 71 may be cut by a dicing blade (not shown). Through the steps including the above, the plurality of semiconductor devices 1A are manufactured from the single wafer structure 80.

As described above, the manufacturing method for the semiconductor device 1A includes the preparation step of the wafer structure 80, the formation step of the resist mask 90 (mask) and the formation step of the source terminal electrode 60. In the preparation step of the wafer structure 80, the wafer structure 80 that includes the wafer 81 having the first wafer main surface 82 (main surface) and the source electrode 32 (main surface electrode) formed on the first wafer main surface 82 is prepared. In the formation step of the resist mask 90, the resist mask 90 that has the second opening 92 (opening) exposing the source electrode 32 and has the wall portion 93 partially covering the source electrode 32 inside the second opening 92 is formed.

In the formation step of the source terminal electrode 60, the conductor is deposited on the portion of the source electrode 32 that is exposed from the resist mask 90, and the source terminal electrode 60 to be fixed to the same potential as that of the source electrode 32 is formed. The source terminal electrode 60 has the source conductor layer 64 covering the source electrode 32 and the source gap portion 65 partitioned by the wall portion 93.

According to this manufacturing method, a volume of the source terminal electrode 60 is reduced by a volume of the wall portion 93, and therefore a stress due to the source terminal electrode 60 is reduced. The wall portion 93 of the resist mask 90 is also effective in blocking a stress continuously generated in a width direction of the source terminal electrode 60. It is therefore possible to suppress fluctuations in electrical characteristics and shape defects of the wafer 81 due to the stress of the source terminal electrode 60. As a result, it is possible to manufacture the semiconductor device 1A in which fluctuations in electrical characteristics and shape defects are suppressed. It is therefore possible to provide the semiconductor device 1A capable of improving the reliability.

The above manufacturing method is effective when the source terminal electrode 60 having a relatively large planar area and/or a relatively large thickness is applied to the wafer 81 having a relatively large planar area and/or a relatively small thickness. For example, the source electrode 32 may cover a region of not less than 50% of the device regions 86 in plan view. Also, the source terminal electrode 60 may cover a region of not less than 50% of the device regions 86 in plan view. Also, in the formation step of the source terminal electrode 60, the source terminal electrode 60 thicker than the source electrode 32 may be formed. Also, the thinning step of the wafer 81, the wafer 81 may be thinned until the wafer 81 becomes thinner than the source terminal electrode 60.

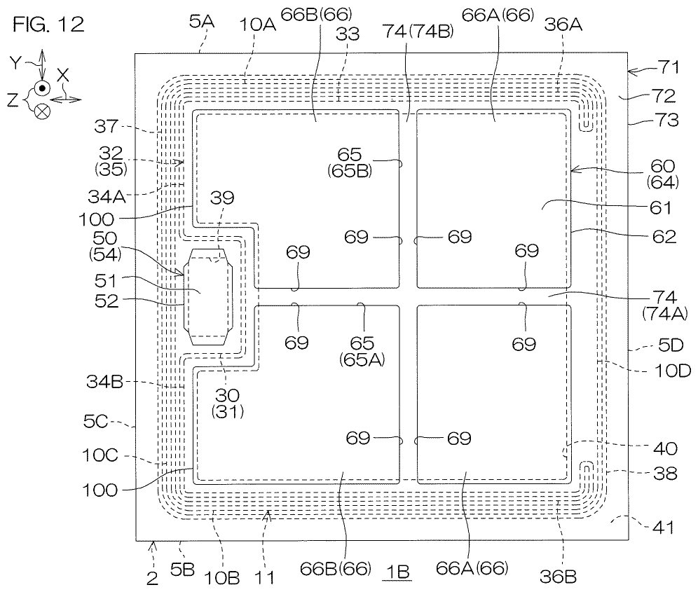

FIG. 12 is a plan view showing a semiconductor device 1B according to a second embodiment. With reference to FIG. 12, the semiconductor device 1B has a modified mode of the semiconductor device 1A. Specifically, the semiconductor device 1B has the source terminal electrode 60 including the plurality of source terminal portions 66 that have planar shapes different from each other. The source terminal electrode 60 includes at least one (in this embodiment, two) first source terminal portions 66A, and at least one (in this embodiment, two) second source terminal portions 66B having different planar shapes from the first source terminal portions 66A, in this embodiment.

The plurality of first source terminal portions 66A are arranged at regions on the fourth side surface 5D side in plan view, respectively. The plurality of first source terminal portions 66A are each formed in a polygonal shape (in this embodiment, quadrangle shape) having four sides parallel to the first to fourth side surfaces 5A to 5D in plan view, in this embodiment. The planar shapes of the plurality of first source terminal portions 66A are arbitrary, and may each be formed in a polygonal shape other than the quadrangle shape, a circular shape, or an elliptical shape.

The plurality of second source terminal portions 66B are arranged at regions on the gate terminal electrode 50 side (the third side surface 5C side) with respect to the plurality of first source terminal portions 66A in plan view, respectively. The plurality of second source terminal portions 66B are each formed in a polygonal shape having four sides parallel to the first to fourth side surfaces 5A to 5D. The plurality of second source terminal portions 66B each has a drawer terminal 100, in this embodiment.

One drawer terminal 100 is drawn out onto the first drawer electrode portion 34A in plan view, and faces the gate terminal electrode 50 in the second direction Y. The other drawer terminal 100 is drawn out onto the second drawer electrode portion 34B in plan view, and faces the gate terminal electrode 50 in the second direction Y. That is, the plurality of drawer terminals 100 sandwich the gate terminal electrode 50 from both sides of the second direction Y in plan view.

The plurality of second source terminal portions 66B each has a planar area different from a planar area of each of the first source terminal portion 66A. The planar area of each second source terminal portion 66B may exceed the planar area of each first source terminal portion 66A. That is, the plurality of source terminal portions 66 may be arrayed with an order in which the planar areas increase as getting closer to the gate terminal electrode 50. As a matter of course, the planar area of each second source terminal portion 66B may be less than the planar area of each first source terminal portion 66A. That is, the plurality of source terminal portions 66 may be arrayed with an order in which the planar areas decrease as getting closer to the gate terminal electrode 50.

As described above, the same effects as those of the semiconductor device 1A are also achieved with the semiconductor device 1B. The semiconductor device 1B is manufactured by modifying the layout of the resist mask 90 in the manufacturing method for the semiconductor device 1A. Therefore, the same effects as those of the manufacturing method for the semiconductor device 1A are also achieved with the manufacturing method for the semiconductor device 1B.

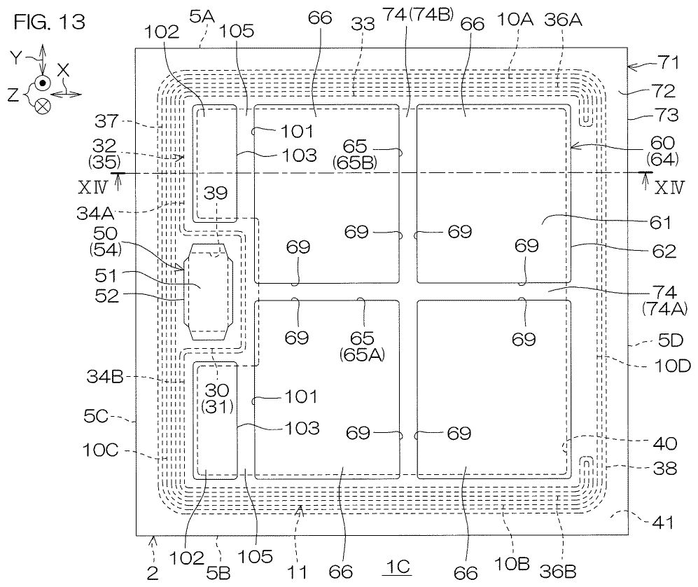

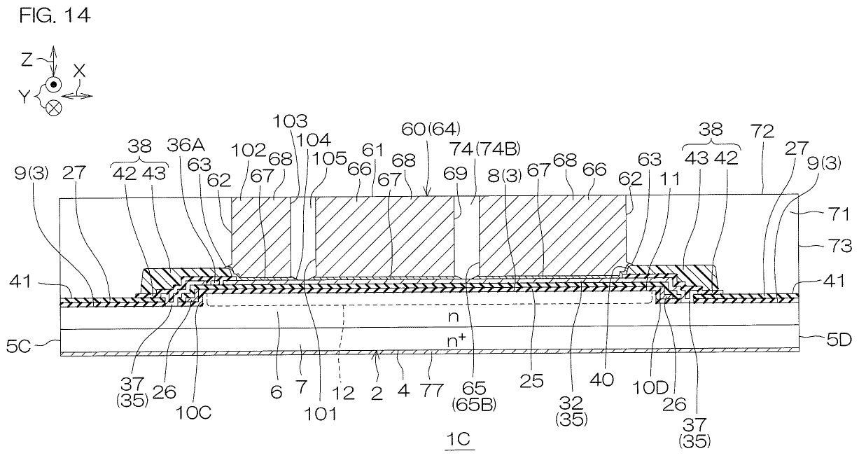

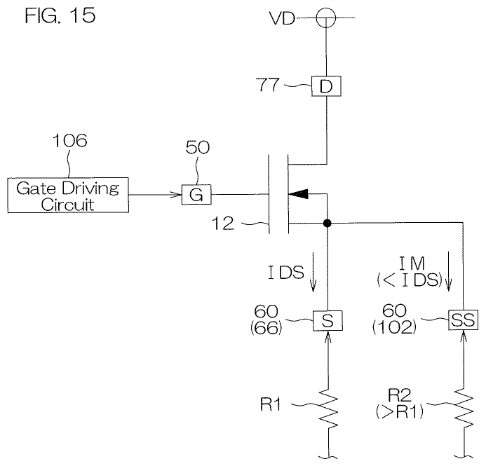

FIG. 13 is a plan view showing a semiconductor device 1C according to a third embodiment. FIG. 14 is a cross sectional view taken along XIV-XIV line shown in FIG. 13. FIG. 15 is a circuit diagram showing an electrical configuration of the semiconductor device 1C shown in FIG. 13. In FIG. 15, external connection example with respect to the semiconductor device 1C is also shown. With reference to FIG. 13 to FIG. 15, the semiconductor device 1C has a modified mode of the semiconductor device 1A.

Specifically, the semiconductor device 1C has the source terminal electrode 60 that includes the source conductor layer 64, at least one (in this embodiment, a plurality of) source gap portions 65, at least one (in this embodiment, a plurality of) source terminal portions 66, at least one (in this embodiment, a plurality of) sense gap portions 101, and at least one (in this embodiment, a plurality of) sense terminal portions 102.

The source gap portions 65 include the first source gap portion 65A and the second source gap portion 65B as with the case of the first embodiment. The plurality of source terminal portions 66 are each partitioned by the source gap portions 65 as with the case of the first embodiment. The plurality of source terminal portions 66 are each formed as a source main terminal that conducts a drain source current IDS, in this embodiment.

The plurality of source terminal portions 66 are arranged at regions on the fourth side surface 5D side in plan view, in this embodiment. The plurality of source terminal portions 66 are each formed in a polygonal shape (in this embodiment, quadrangle shape) having four sides parallel to the first to fourth side surfaces 5A to 5D in plan view, in this embodiment. The planar shapes of the plurality of source terminal portions 66 are arbitrary, and may each be formed in a polygonal shape other than the quadrangle shape, a circular shape, or an elliptical shape.

The plurality of sense gap portions 101 penetrate the source conductor layer 64 outside the plurality of source terminal portions 66 in cross sectional view, and demarcates the source conductor layer 64 to portions (regions) outside the source terminal portions 66. The plurality of sense gap portions 101 are formed at positions overlapping to the source electrode 32 in plan view and expose parts of the source electrode 32. The plurality of sense gap portions 101 are each formed on the source electrode 32 such as to define the drawer electrode portions 34A, 34B from the body electrode portion 33, in this embodiment. The plurality of sense gap portions 101 are each formed in a band shape extending in the second direction Y in plan view, and divide the source conductor layer 64 in the first direction X.

The plurality of sense terminal portions 102 are each demarcated on the corresponding drawer electrode portions 34A, 34B by the corresponding sense gap portions 101. The plurality of sense terminal portions 102 are each formed in a polygonal shape (in this embodiment, quadrangle shape) having four sides parallel to the first to fourth side surfaces 5A to 5D in plan view, in this embodiment. The planar shapes of the plurality of sense terminal portions 102 are arbitrary, and may each be formed in a polygonal shape other than the quadrangle shape, a circular shape, or an elliptical shape. The plurality of sense terminal portions 102 are each formed as a sense terminal that conducts a monitor current IM monitoring the drain source current IDS.

One sense terminal portions 102 faces the gate terminal electrode 50 in the second direction Y in plan view. The other drawer terminal 100 faces the gate terminal electrode 50 in the second direction Y in plan view. That is, the plurality of sense terminal portions 102 sandwich the gate terminal electrode 50 from both sides of the second direction Y in plan view.

The plurality of sense terminal portions 102 each has a sense gap side wall 103 defined by the sense gap portions 101. The sense gap side wall 103 may consist of a smooth surface without a grinding mark. The plurality of sense terminal portions 102 each has a third protrusion portion 104 outwardly protruding at a lower end portion of the sense gap side wall 103, in this embodiment. The third protrusion portion 104 is formed on the source electrode 32 with a similar mode of the second protrusion portion 63. As a matter of course, the sense terminal portions 102 without the third protrusion portion 104 may be formed.

Each of the sense terminal portions 102 has an area less than the area of each source terminal portion 66 in plan view, in this embodiment. The plurality of sense terminal portions 102 may have a total area exceeding the area of the gate terminal electrode 50. Each of the sense terminal portions 102 may have the area exceeding the area of the gate terminal electrode 50. As a matter of course, each of the sense terminal portions 102 may have the area less than the area of the gate terminal electrode 50. The plurality of source terminal portions 66 and the plurality of sense terminal portions 102 may cover a region of not less than 50% of the first main surface 3 in plan view. The plurality of source terminal portions 66 and the plurality of sense terminal portions 102 preferably cover a region of not less than 75% of the first main surface 3.

The semiconductor device 1C includes a sense gap insulator 105 embedded in the plurality of sense gap portions 101. The sense gap insulator 105 covers the source gap side walls 69 of the source terminal portions 66 and the sense gap side walls 103 of the sense terminal portions 102 in each of the sense gap portions 101. That is, the sense gap insulator 105 defines the source terminal portions 66 and the sense terminal portions 102 inside the sense gap portions 101.

The sense gap insulator 105 keeps the source terminal portions 66 and the sense terminal portions 102 fixed at the same potential, and physically divides the source terminal portions 66 and the sense terminal portions 102 on the source electrode 32, in this embodiment. In other words, the sense gap insulator 105 is configured such as to allow a vertical current transfer among the source terminal portions 66, the sense terminal portions 102 and the source electrode 32, and restrict a lateral current transfer among the source terminal portions 66 and the sense terminal portions 102.

The sense gap insulator 105 directly covers the source electrode 32 inside the sense gap portions 101, in this embodiment. Also, the sense gap insulator 105 covers the third protrusion portion 104 inside the sense gap portions 101, and covers the source electrode 32 with the third protrusion portion 104 interposed therebetween. The sense gap insulator 105 suppresses a dropout of the sense terminal portions 102.

The sense gap insulator 105 is connected to the sealing insulator 71 outside the sense gap portions 101. The sense gap insulator 105 consists of a part of the sealing insulator 71, in this embodiment. That is, the sense gap insulator 105 has the insulating main surface 72 (sense insulating main surface) that is continuous to the gate terminal surface 51 and the source terminal surface 61. Also, the sense gap insulator 105 includes the thermosetting resin, the plurality of fillers and the plurality of flexible particles. As a matter of course, the sense gap insulator 105 may consist of an insulating material different from that of the sealing insulator 71.

With reference to FIG. 15, in the semiconductor device 1C, a gate driving circuit 106 is to be electrically connected to the gate terminal electrode 50, at least one first resistance R1 is to be electrically connected to the plurality of source terminal portions 66, and at least one second resistance R2 is to be electrically connected to the plurality of sense terminal portions 102. The first resistance R1 is configured such as to conduct the drain source current IDS that is generated in the semiconductor device 1C. The second resistance R2 is configured such as to conduct the monitor current IM having a value less than that of the drain source current IDS.

The first resistance R1 may be a resistor or a conductive bonding member with a first resistance value. The second resistance R2 may be a resistor or a conductive bonding member with a second resistance value more than the first resistance value. The conductive bonding member may be a conductor plate or a conducting wire (for example, bonding wire). That is, at least one first bonding wire with the first resistance value may be connected to at least one of the source terminal portions 66.

Also, at least one second bonding wire with the second resistance value more than the first resistance value may be connected to at least one of the sense terminal portions 102. The second bonding wire may have a line thickness less than a line thickness of the first bonding wire. In this case, a bonding area of the second bonding wire with respect to the sense terminal portions 102 may be less than a bonding area of the first bonding wire with respect to the source terminal portions 66.

As described above, the same effects as those of the semiconductor device 1A are also achieved with the semiconductor device 1C. In the manufacturing method for the semiconductor device 1C, the resist mask 90 that has the wall portion 93 covering regions in which the sense gap portions 101 are to be formed is formed in the manufacturing method for the semiconductor device 1A, and then the same steps as those of the manufacturing method for the semiconductor device 1A are performed. Therefore, the same effects as those of the manufacturing method for the semiconductor device 1A are also achieved with the manufacturing method for the semiconductor device 1C.

The arrangement locations of the sense terminal portions 102 according to the semiconductor device 1C are one example, and the arrangement locations of the sense terminal portions 102 are arbitrary. For example, at least one of the sense terminal portions 102 may be used as the source terminal portion 66, and at least one of the plurality of source terminal portions 66 may be used as the sense terminal portions 102.

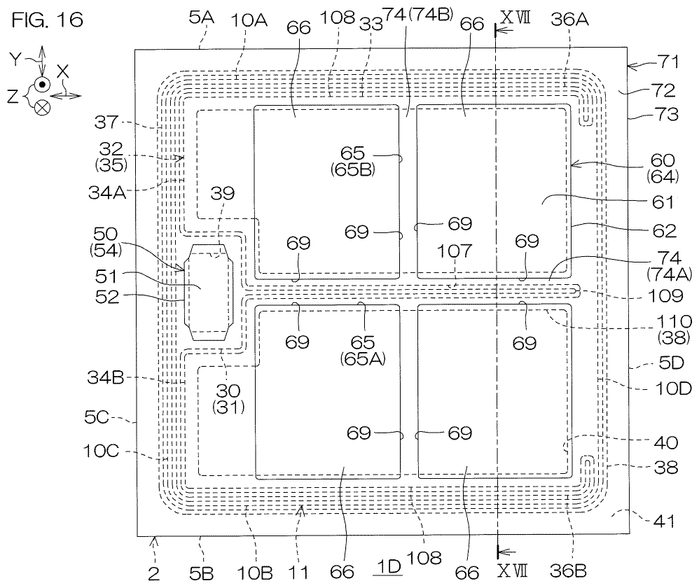

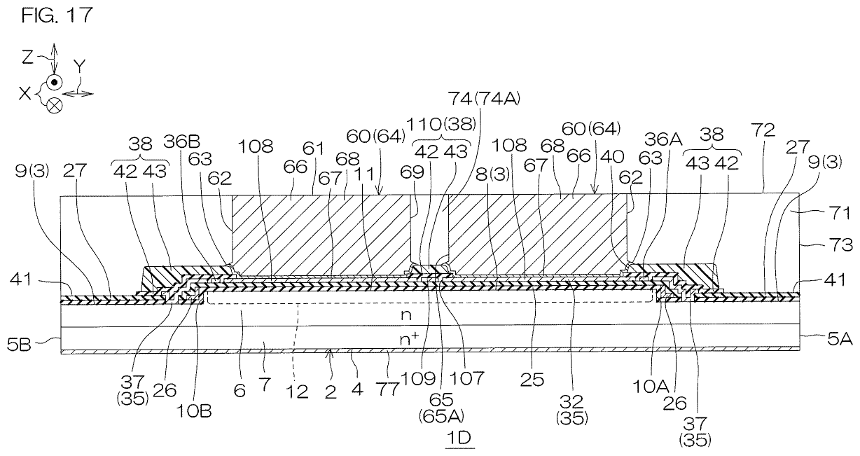

FIG. 16 is a plan view showing a semiconductor device 1D according to a fourth embodiment. FIG. 17 is a cross sectional view taken along XVII-XVII line shown in FIG. 16. With reference to FIG. 16 and FIG. 17, the semiconductor device 1D has a modified mode of the semiconductor device 1A. Specifically, the semiconductor device 1D has the source electrode 32 that includes the source lower conductor layer 35, at least one (in this embodiment, one) lower gap portion 107 and at least one (in this embodiment, a plurality of) lower electrode portions 108.

The lower gap portion 107 is formed in the body electrode portion 33 of the source electrode 32. The lower gap portion 107 penetrates the source lower conductor layer 35 and defines the source lower conductor layer 35 into a plural portions (regions) in cross sectional view. The lower gap portion 107 exposes a part of the interlayer insulating film 27. The lower gap portion 107 extends in a band shape toward an inner portion of the source lower conductor layer 35 from a portion of a wall portion of the source lower conductor layer 35 that opposes the gate electrode 30 in the first direction X, in this embodiment.

The lower gap portion 107 is formed in a band shape extending in the first direction X, in this embodiment. The lower gap portion 107 crosses a central portion of the source lower conductor layer 35 in the first direction X in plan view, in this embodiment. The lower gap portion 107 has an end portion at a position at an interval inward (to the gate electrode 30 side) from a wall portion of the source lower conductor layer 35 on the fourth side surface 5D side in plan view, and does not separate the source lower conductor layer 35 into the second direction Y. As a matter of course, the lower gap portion 107 may separate the source lower conductor layer 35 into the second direction Y. The lower gap portion 107 partitions the source lower conductor layer 35 into a portion (region) on one side and a portion (region) on the other side in plan view, regarding the second direction Y.

The plurality of lower electrode portions 108 consist of a plural portions that are defined by the lower gap portion 107 in the source lower conductor layer 35. That is, two lower electrode portions 108 are defined by the lower gap portion 107, in this embodiment. The plurality of lower electrode portions 108 penetrate the interlayer insulating film 27 and the main surface insulating film 25 and are electrically connected to the plurality of source structures 16, the source region 14 and the plurality of well regions 18. The plurality of lower electrode portions 108 are each demarcated in a polygonal shape having four sides parallel to the first to fourth side surfaces 5A to 5D in plan view, in this embodiment. The planar shape of each of the lower electrode portions 108 is arbitrary, and may be formed in a quadrangle shape, a circular shape and an elliptical shape.

The semiconductor device 1D includes a gate intermediate wiring 109 that is drawn out into the lower gap portion 107 from the gate electrode 30. The gate intermediate wiring 109 includes the gate lower conductor layer 31 as with the gate electrode 30 (the plurality of gate wirings 36A, 36B). The gate intermediate wiring 109 extends in a band shape along the lower gap portion 107 in plan view.

The gate intermediate wiring 109 is formed at intervals from the plurality of lower electrode portions 108 in plan view and face the plurality of lower electrode portions 108 in the second direction Y. The gate intermediate wiring 109 penetrates the interlayer insulating film 27 at an inner portion of the active surface 8 (the first main surface 3) and is electrically connected to the plurality of gate structures 15. The gate intermediate wiring 109 may be directly connected to the plurality of gate structures 15, or may be electrically connected to the plurality of gate structures 15 via a conductor film.

The upper insulating film 38 aforementioned includes a gap covering portion 110 that covers the lower gap portion 107 of the source electrode 32, in this embodiment. The gap covering portion 110 covers a whole region of the gate intermediate wiring 109 inside the lower gap portion 107. The gap covering portion 110 is drawn out onto the plurality of lower electrode portions 108 from inside the lower gap portion 107 such as to cover peripheral edge portions of the plurality of lower electrode portions 108.

The source gap portions 65 of the source terminal electrode 60 aforementioned includes a portion that is formed at a portion overlapping to the lower gap portion 107 in plan view, in this embodiment. Specifically, the source gap portions 65 includes the first source gap portion 65A that is formed at the portion overlapping to the lower gap portion 107 in plan view. The first source gap portion 65A extends in the first direction X along the lower gap portion 107 in this embodiment, and exposes the gap covering portion 110 of the upper insulating film 38. On the other hand, the second source gap portion 65B exposes the gap covering portion 110 of the upper insulating film 38 at the intersecting portion with the first source gap portion 65A.

The plurality of source terminal portions 66 according to the source terminal electrode 60 are each demarcated on the plurality of lower electrode portions 108 by the source gap portions 65, in this embodiment. The plurality of source terminal portions 66 are fixed to the same potential as that of the plurality of lower electrode portions 108. That is, the source terminal electrode 60 is configured such that the source potential (single potential) is given to the plurality of lower electrode portions 108 via the plurality of source terminal portions 66, in this embodiment.

The plurality of source terminal portions 66 each has the second protrusion portion 63 at the source gap side wall 69 as with the case of the first embodiment. The second protrusion portion 63 on the first source gap portion 65A side is formed on the gap covering portion 110 of the upper insulating film 38, in this embodiment. The second protrusion portion 63 on the second source gap portion 65B side is formed on the source electrode 32(the lower electrode portions 108) as with the case of the first embodiment.

The gap insulator 74 aforementioned includes a portion covering the source electrode 32 and a portion covering the upper insulating film 38 inside the source gap portions 65, in this embodiment. Specifically, the gap insulator 74 covers the gap covering portion 110 of the upper insulating film 38 inside the first source gap portion 65A, and covers the source electrode 32 (the plurality of lower electrode portions 108) inside the second source gap portion 65B. The gap insulator 74 covers the gate intermediate wiring 109 inside the first source gap portion 65A with the upper insulating film 38 interposed therebetween. The gap insulator 74 covers the peripheral edge portions of the plurality of lower electrode portions 108 inside the first source gap portion 65A with the upper insulating film 38 interposed therebetween.

An example in which the upper insulating film 38 has the gap covering portion 110 covering the lower gap portion 107 has been shown, in this embodiment. However, the presence or the absence of the gap covering portion 110 is arbitrary, and the upper insulating film 38 without the gap covering portion 110 may be formed. In this case, the first source gap portion 65A is formed in the source conductor layer 64 such as to expose the gate intermediate wiring 109.

In this case, the gap insulator 74 directly covers the gate intermediate wiring 109 in the first source gap portion 65A, and electrically isolates the gate intermediate wiring 109 from the source electrode 32. Also, the gap insulator 74 directly covers a portion of the interlayer insulating film 27 exposed from a region between the source electrode 32 and the gate intermediate wiring 109 in the first source gap portion 65A.

In this embodiment, an example in which the source gap portions 65 having the first and second source gap portions 65A, 65B are formed has been shown. However, the source gap portions 65 that has only the first source gap portion 65A and does not have the second source gap portion 65B may be formed. That is, the source terminal electrode 60 may have two source terminal portions 66 defined by a single source gap portion 65 (the first source gap portion 65A). As a matter of course, the source gap portions 65 that has only the second source gap portion 65B and does not have the first source gap portion 65A may be formed.

As described above, the same effects as those of the semiconductor device 1A are also achieved with the semiconductor device 1D. In the manufacturing method for the semiconductor device 1D, the wafer structure 80 in which structures corresponding to the semiconductor device 1D are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1D.

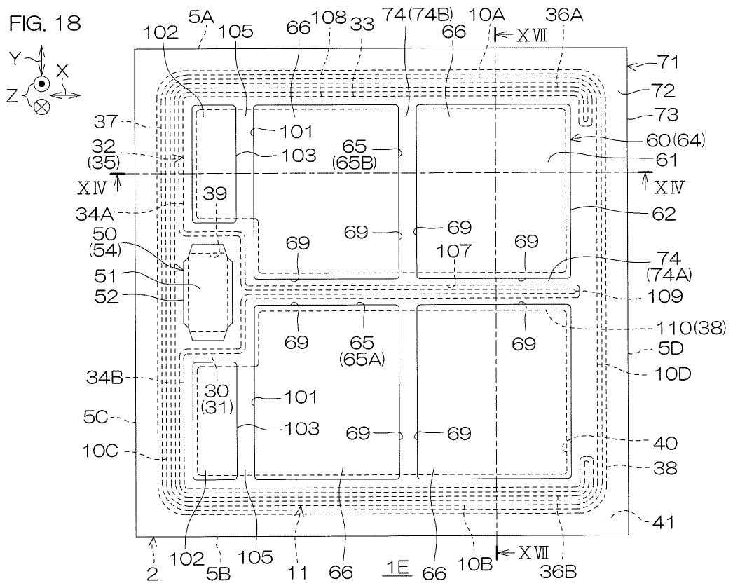

FIG. 18 is a plan view showing a semiconductor device 1E according to a fifth embodiment. The semiconductor device 1E has a mode in which the features (structures having the gate intermediate wiring 109) of the semiconductor device 1D according to the fourth embodiment are combined to the features (structures having the sense terminal portions 102) of the semiconductor device 1C according to the third embodiment. The same effects as those of the semiconductor device 1A are also achieved with the semiconductor device 1E having such a mode.

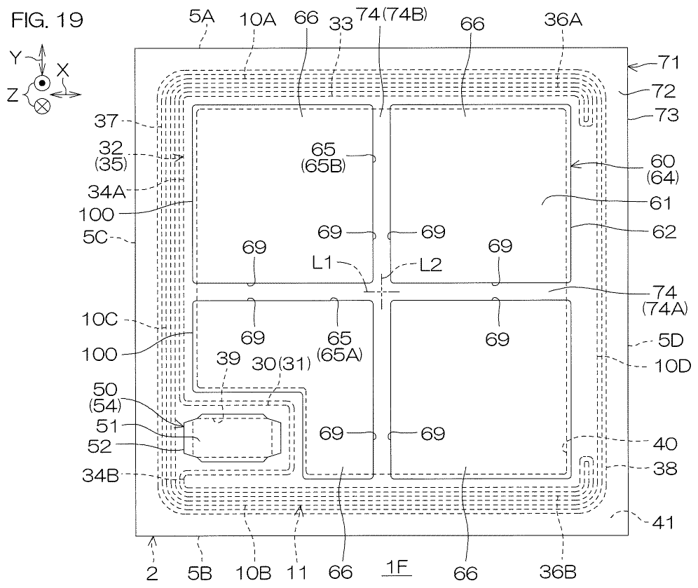

FIG. 19 is a plan view showing a semiconductor device 1F according to a sixth embodiment. With reference to FIG. 19, the semiconductor device 1F has a modified mode of the semiconductor device 1A. Specifically, the semiconductor device 1F has the gate electrode 30 arranged on a region along an arbitrary corner portion of the chip 2.

That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged at a position offset from both of the first straight line L1 and the second straight line L2. The gate electrode 30 is arranged at a region along a corner portion that connects the second side surface 5B and the third side surface 5C in plan view, in this embodiment.

The plurality of drawer electrode portions 34A, 34B of the source electrode 32 aforementioned sandwich the gate electrode 30 from both sides of the second direction Y in plan view as with the case of the first embodiment. The first drawer electrode portion 34A is drawn out from the body electrode portion 33 with a first planar area. The second drawer electrode portion 34B is drawn out from the body electrode portion 33 with a second planar area less than the first planar area. As a matter of course, the source electrode 32 does not may have the second drawer electrode portion 34B and may only include the body electrode portion 33 and the first drawer electrode portion 34A.

The gate terminal electrode 50 aforementioned is arranged on the gate electrode 30 as with the case of the first embodiment. The gate terminal electrode 50 is arranged at a region along an arbitrary corner portion of the chip 2, in this embodiment. That is, the gate terminal electrode 50 is arranged at a position offset from both of the first straight line L1 and the second straight line L2 in plan view. The gate terminal electrode 50 is arranged at the region along the corner portion that connects the second side surface 5B and the third side surface 5C in plan view, in this embodiment.

The source terminal electrode 60 aforementioned includes the plurality of source terminal portions 66 that are defined by the source gap portions 65 (the first and second source gap portions 65A, 65B) as with the case of the first embodiment. The plurality of source terminal portions 66 are each arranged on the body electrode portion 33. At least one (in this embodiment, two) source terminal portions 66 arranged on the third side surface 5C side in the plurality of source terminal portions 66 each has the drawer terminal 100 that is drawn out onto the first drawer electrode portion 34A.

The plurality of source terminal portions 66 does not have the drawer terminal 100 that is drawn out onto the second drawer electrode portion 34B, in this embodiment. The plurality of drawer terminals 100 thereby face the gate terminal electrode 50 from one side of the second direction Y. The source terminal portion 66 adjacent the gate terminal electrode 50 among the plurality of source terminal portions 66 has portions that face the gate terminal electrode 50 from two directions including the first direction X and the second direction Y by having the drawer terminal 100.

As described above, the same effects as those of the semiconductor device 1A are also achieved with the semiconductor device 1F. In the manufacturing method for the semiconductor device 1F, the wafer structure 80 in which structures corresponding to the semiconductor device 1F are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1F. The structure in which the gate electrode 30 and the gate terminal electrode 50 are arranged at the corner portion of the chip 2 may be applied to the second to fifth embodiments.

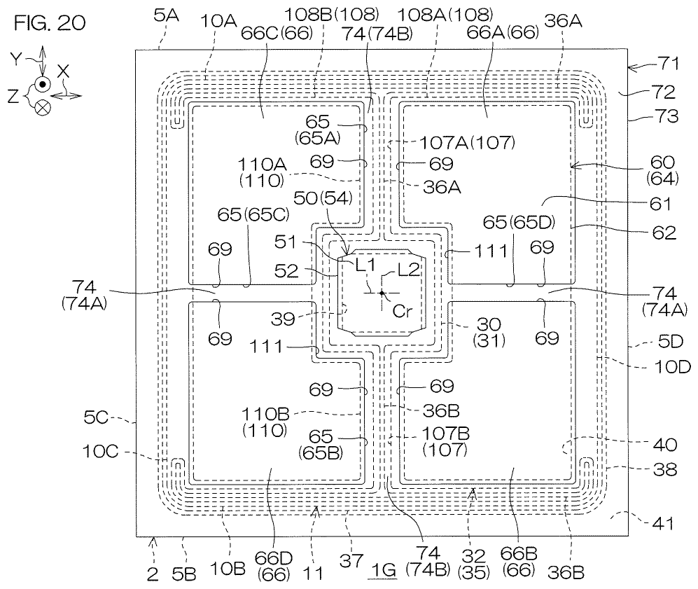

FIG. 20 is a plan view showing a semiconductor device 1G according to a seventh embodiment. With reference to FIG. 20, the semiconductor device 1G has a modified mode of the semiconductor device 1A. Specifically, the semiconductor device 1G has the gate electrode 30 arranged at the central portion of the first main surface 3 (the active surface 8) in plan view. That is, when a first straight line L1 (see two-dot chain line portion) crossing the central portion of the first main surface 3 in the first direction X and a second straight line L2 (see two-dot chain line portion) crossing the central portion of the first main surface 3 in the second direction Y are set, the gate electrode 30 is arranged such as to overlap an intersecting portion Cr of the first straight line L1 and the second straight line L2.

The source electrode 32 aforementioned includes the source lower conductor layer 35, at least one (in this embodiment, a plurality of) lower gap portions 107A, 107B and at least one (in this embodiment, a plurality of) lower electrode portions 108A, 108B, in this embodiment. The source lower conductor layer 35 is formed in an annular shape (specifically, a quadrangle annular shape) surrounding the gate electrode 30 in plan view, in this embodiment.

The plurality of lower gap portions 107A, 107B include a first lower gap portion 107A and a second lower gap portion 107B. The first lower gap portion 107A crosses a portion of the source lower conductor layer 35 that extends in the first direction X in a region on one side (the first side surface 5A side) of the source lower conductor layer 35 in the second direction Y. The first lower gap portion 107A faces the gate electrode 30 in the second direction Y in plan view.

The second lower gap portion 107B crosses a portion of the source lower conductor layer 35 that extends in the first direction X in a region on the other side (the second side surface 5B side) of the source lower conductor layer 35 in the second direction Y. The second lower gap portion 107B faces the gate electrode 30 in the second direction Y in plan view. The second lower gap portion 107B faces the first lower gap portion 107A with the gate electrode 30 interposed therebetween in plan view, in this embodiment.

The plurality of lower electrode portions 108A, 108B are composed of a plurality of portions that are defined by the plurality of lower gap portions 107A, 107B in the source lower conductor layer 35. The plurality of lower electrode portions 108A, 108B penetrate the interlayer insulating film 27 and the main surface insulating film 25 and are electrically connected to the plurality of source structures 16, the source region 14 and the plurality of well regions 18. The plurality of lower electrode portions 108A, 108B are each defined in a C-letter shape curved along the gate electrode 30 such as to face the gate electrode 30 from three directions in plan view, in this embodiment.

The first gate wiring 36A aforementioned is drawn out into the first lower gap portion 107A from the gate electrode 30. Specifically, the first gate wiring 36A has a portion extending as a band shape in the second direction Y inside the first lower gap portion 107A and a portion extending as a band shape in the first direction X along the first side surface 5A (the first connecting surface 10A). The second gate wiring 36B aforementioned is drawn out into the second lower gap portion 107B from the gate electrode 30. Specifically, the second gate wiring 36B has a portion extending as a band shape in the second direction Y inside the second lower gap portion 107B and a portion extending as a band shape in the first direction X along the second side surface 5B (the second connecting surface 10B).

The plurality of gate wirings 36A, 36B intersect (specifically, perpendicularly intersect) the both end portions of the plurality of gate structures 15 as with the case of the first embodiment. The plurality of gate wirings 36A, 36B penetrate the interlayer insulating film 27 and are electrically connected to the plurality of gate structures 15. The plurality of gate wirings 36A, 36B may be directly connected the plurality of gate structures 15, or may be electrically connected to the plurality of gate structures 15 via a conductor film.

The source wiring 37 aforementioned is drawn out from a plural portions of the source electrode 32 and surrounds the gate electrode 30, the source electrode 32 and the gate wirings 36A, 36B. As a matter of course, the source wiring 37 may be drawn out from a single portion of the source electrode 32 as with the case of the first embodiment.

The upper insulating film 38 aforementioned includes a plurality of gap covering portions 110A, 110B each cover the plurality of lower gap portions 107A, 107B, in this embodiment. The plurality of gap covering portions 110A, 110B includes a first gap covering portion 110A and a second gap covering portion 110B. The first gap covering portion 110A covers a whole region of the first gate wiring 36A in the first lower gap portion 107A. The second gap covering portion 110B covers a whole region of the second gate wiring 36B in the second lower gap portion 107B. The plurality of gap covering portions 110A, 110B are each drawn out onto the plurality of lower electrode portions 108A, 108B from inside the plurality of lower gap portions 107A, 107B such as to cover peripheral edge portions of the plurality of lower electrode portions 108A, 108B.

The gate terminal electrode 50 aforementioned is arranged on the gate electrode 30 as with the case of the first embodiment. The gate terminal electrode 50 is arranged on the central portion of the first main surface 3 (the active surface 8), in this embodiment. That is, when the first straight line L1 (see two-dot chain line portion) crossing the central portion of the first main surface 3 in the first direction X and the second straight line L2 (see two-dot chain line portion) crossing the central portion of the first main surface 3 in the second direction Y are set, the gate terminal electrode 50 is arranged such as to overlap the intersecting portion Cr of the first straight line L1 and the second straight line L2.

The source terminal electrode 60 aforementioned is formed in a polygonal annular shape (in this embodiment, a quadrangle annular shape) having four sides parallel to the first to fourth side surfaces 5A to 5D in plan view, in this embodiment. The source terminal electrode 60 includes the source conductor layer 64, at least one (in this embodiment, a plurality of) source gap portions 65A to 65D and at least one (in this embodiment, a plurality of) source terminal portions 66A to 66D, in this embodiment.

The plurality of source gap portions 65 include a portion that overlaps at least one of the plurality of lower gap portions 107A, 107B and a portion that does not overlap any one of the plurality of lower gap portions 107A, 107B, in this embodiment. Specifically, the plurality of source gap portions 65A to 65D includes a first source gap portion 65A, a second source gap portion 65B, a third source gap portion 65C and a fourth source gap portion 65D.

The first source gap portion 65A is formed at a position that overlaps to the first lower gap portion 107A in plan view, and extends as a band shape in the second direction Y along the first lower gap portion 107A at a region between the gate terminal electrode 50 and the first side surface 5A. The first source gap portion 65A exposes the gap covering portion 110 of the upper insulating film 38, in this embodiment. The first source gap portion 65A divides the source conductor layer 64 into the first direction X, in this embodiment.

The second source gap portion 65B is formed at a position that overlaps to the second lower gap portion 107B in plan view, and extends as a band shape in the second direction Y along the second lower gap portion 107 at a region between the gate terminal electrode 50 and the second side surface 5B. The second source gap portion 65B exposes the gap covering portion 110 of the upper insulating film 38, in this embodiment. The second source gap portion 65B divides the source conductor layer 64 into the first direction X, in this embodiment.

The third source gap portion 65C is formed at a position that overlaps to the source lower conductor layer 35 (the first lower electrode portion 108A), and extends as a band shape in the first direction X at a region between the gate terminal electrode 50 and the third side surface 5C. The third source gap portion 65C exposes the source lower conductor layer 35, in this embodiment. The third source gap portion 65C divides the source conductor layer 64 into the second direction Y, in this embodiment.

The fourth source gap portion 65D is formed at a position that overlaps to the source lower conductor layer 35 (the second lower electrode portion 108B) and extends as a band shape in the first direction X at a region between the gate terminal electrode 50 and the fourth side surface 5D. The fourth source gap portion 65D exposes the source lower conductor layer 35, in this embodiment. The fourth source gap portion 65D divides the source conductor layer 64 into the second direction Y, in this embodiment.

The plurality of source terminal portions 66A to 66D are each demarcated on the plurality of lower electrode portions 108A, 108B by the plurality of source gap portions 65A to 65D, in this embodiment. The plurality of source terminal portions 66 includes a first source terminal portion 66A, a second source terminal portion 66B, a third source terminal portion 66C and a fourth source terminal portions 66D. The first source terminal portion 66A is demarcated on the first lower electrode portion 108A at a region on the first side surface 5A side. The second source terminal portion 66B is demarcated on the first lower electrode portion 108A at a region on the second side surface 5B side at an interval from the first source terminal portion 66A.

The third source terminal portion 66C is demarcated on a region the second lower electrode portion 108B at a region on the first side surface 5A side. The fourth source terminal portions 66D is demarcated on the second lower electrode portion 108B at a region on the second side surface 5B side at an interval from the third source terminal portion 66C. That is, the plurality of source terminal portions 66 are defined on the first lower electrode portion 108A, and the plurality of source terminal portions 66 are defined on the second lower electrode portion 108B, in this embodiment.

The plurality of source terminal portions 66 are each formed in a polygonal shape having four sides parallel to the first to fourth side surfaces 5A to 5D in plan view, in this embodiment. Specifically, the plurality of source terminal portions 66 each has a notched portion 111 extending along the gate terminal electrode 50 at a corner portion adjacent to the gate terminal electrode 50. The notched portion 111 is notched into a quadrangle shape having two sides parallel to two sides of the gate terminal electrode 50 in plan view, in this embodiment. The plurality of source terminal portions 66 thereby face the gate terminal electrode 50 from a plural directions (in this embodiment, the first direction X and the second direction Y) in plan view.

The plurality of source terminal portions 66A to 66D each has the second protrusion portion 63 at the source gap side wall 69 as with the case of the first embodiment. The second protrusion portion 63 on the first source gap portion 65A side and the second protrusion portion 63 on the second source gap portion 65B side are each formed on the upper insulating film 38 (the gap covering portion 110). The second protrusion portion 63 on the third source gap portion 65C side and the second protrusion portion 63 on the fourth source gap portion 65D side are formed on the source electrode 32 (the lower electrode portions 108A, 108B).

The gap insulator 74 (the first and second gap insulator 74A, 74B) aforementioned is embedded in the first to fourth source gap portions 65A to 65D, in this embodiment. The gap insulator 74 includes a portion that covers the source electrode 32 and a portion that covers the upper insulating film 38. Specifically, the gap insulator 74 covers the gap covering portion 110A, 110B of the upper insulating film 38 inside the first and second source gap portions 65A, 65B.

The gap insulator 74 covers the gate wirings 36A, 36B inside the first and second source gap portions 65A, 65B with the upper insulating film 38 (the gap covering portion 110A, 110B) interposed therebetween. The gap insulator 74 covers peripheral edge portions of the plurality of lower electrode portions 108A, 108B inside the first and second source gap portions 65A, 65B with the upper insulating film 38 interposed therebetween. The gap insulator 74 covers the source electrode 32 (the plurality of lower electrode portions 108A, 108B) inside the third and fourth source gap portions 65C, 65D.

An example in which the upper insulating film 38 has the gap covering portion 110 has been shown, in this embodiment. However, the presence or the absence of the gap covering portion 110 is arbitrary and the upper insulating film 38 without the gap covering portion 110 may be formed. In this case, the first and second source gap portions 65A, 65B are formed in the source conductor layer 64 such as to expose the gate wirings 36A, 36B.

In this case, the gap insulator 74 directly covers the gate wirings 36A, 36B inside the first and second source gap portions 65A, 65B and electrically isolates the gate wirings 36A, 36B from the source electrode 32. Also, the gap insulator 74 directly covers a part of the interlayer insulating film 27 exposed from a region between the source electrode 32 and the gate wirings 36A, 36B inside the first and second source gap portions 65A, 65B.

Also, an example in which the source gap portions 65 having the first to fourth source gap portions 65A to 65D has been shown, in this embodiment. However, the source gap portions 65 only having at least one, two or three of the first to fourth source gap portions 65A to 65D may be formed. That is, the source terminal electrode 60 may have at least two source terminal portions 66 defined by at least one source gap portions 65.

As described above, the same effects as those of the semiconductor device 1A are also achieved with the semiconductor device 1G. In the manufacturing method for the semiconductor device 1G, the wafer structure 80 in which structures corresponding to the semiconductor device 1G are formed in each device region 86 is prepared, and the similar steps to those of the manufacturing method for the semiconductor device 1A are performed. Therefore, the same effects as those of the manufacturing method for the semiconductor device 1A are also achieved with the manufacturing method for the semiconductor device 1G. The structure in which the gate electrode 30 and the gate terminal electrode 50 are arranged at the central portion of the chip 2 may be applied to the second to sixth embodiments.

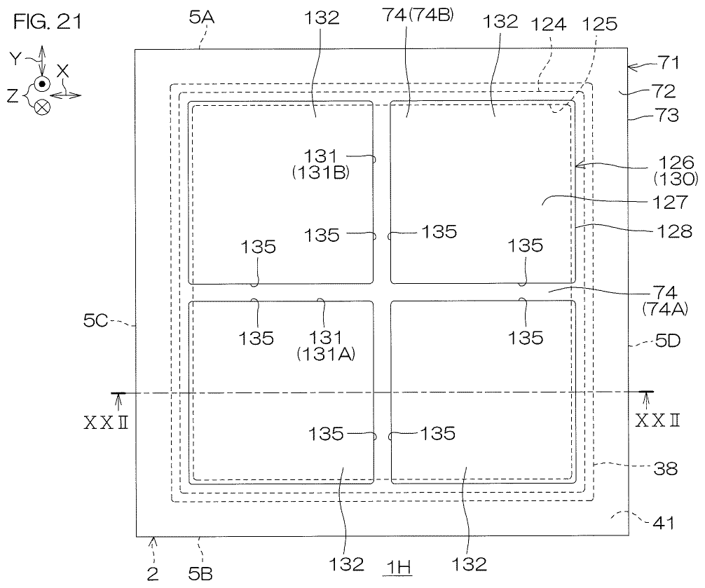

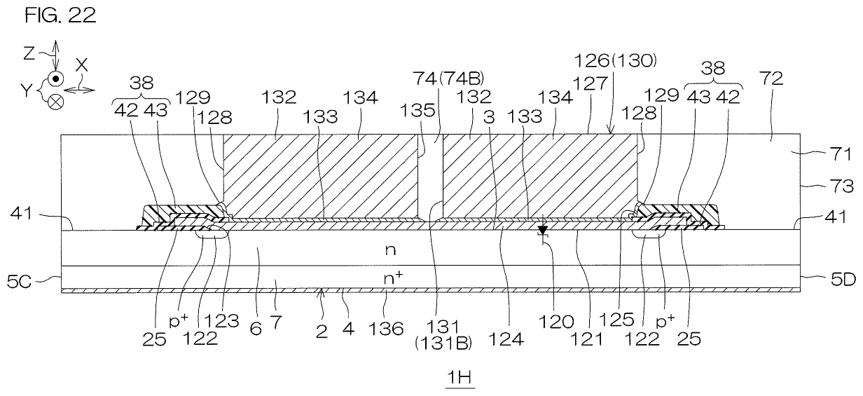

FIG. 21 is a plan view showing a semiconductor device 1H according to an eighth embodiment. FIG. 22 is a cross sectional view taken along XXII-XXII line shown in FIG. 21. The semiconductor device 1H includes the chip 2 aforementioned. The chip 2 is free from the mesa portion 11 in this embodiment and has the flat first main surface 3. The semiconductor device 1H has an SBD (Schottky Barrier Diode) structure 120 that is formed in the chip 2 as an example of a diode.

The semiconductor device 1H includes a diode region 121 of the n-type that is formed in an inner portion of the first main surface 3. The diode region 121 is formed by using a part of the first semiconductor region 6, in this embodiment.

The semiconductor device 1H includes a guard region 122 of the p-type that demarcates the diode region 121 from other region at the first main surface 3. The guard region 122 is formed in a surface layer portion of the first semiconductor region 6 at the interval from a peripheral edge of the first main surface 3. The guard region 122 is formed in an annular shape (in this embodiment, a quadrangle annular shape) surrounding the diode region 121 in plan view, in this embodiment. The guard region 122 has an inner end portion on the diode region 121 side and an outer end portion on the peripheral edge side of the first main surface 3.

The semiconductor device 1H includes the main surface insulating film 25 aforementioned that selectively covers the first main surface 3. The main surface insulating film 25 has a diode opening 123 that exposes the diode region 121 and the inner end portion of the guard region 122. The main surface insulating film 25 is formed at an interval inward from the peripheral edge of the first main surface 3 and exposes the first main surface 3 (the first semiconductor region 6) from the peripheral edge portion of the first main surface 3. As a matter of course, the main surface insulating film 25 may cover the peripheral edge portion of the first main surface 3. In this case, the peripheral edge portion of the main surface insulating film 25 may be continuous to the first to fourth side surfaces 5A to 5D.

The semiconductor device 1H includes a first polar electrode 124 (main surface electrode) that is arranged on the first main surface 3. The first polar electrode 124 is an “anode electrode”, in this embodiment. The first polar electrode 124 is arranged at an interval inward from the peripheral edge of the first main surface 3. The first polar electrode 124 is formed in a quadrangle shape along the peripheral edge of the first main surface 3 in plan view, in this embodiment. The first polar electrode 124 enters into the diode opening 123 from on the main surface insulating film 25, and is electrically connected to the first main surface 3 and the inner end portion of guard region 122.

The first polar electrode 124 forms a Schottky junction with the diode region 121 (the first semiconductor region 6). The SBD structure 120 is thereby formed. A planar area of the first polar electrode 124 is preferably not less than 50% of the first main surface 3. The planar area of the first polar electrode 124 is particularly preferably not less than 75% of the first main surface 3. The first polar electrode 124 may have a thickness of not less than 0.5 μm and not more than 15 μm.

The first polar electrode 124 may have a laminated structure that includes a Ti-based metal film and an Al-based metal film. The Ti-based metal film may have a single layered structure consisting of a Ti film or a TiN film. The Ti-based metal film may have a laminated structure that includes the Ti film and the TiN film laminated with an arbitrary order. The Al-based metal film is preferably thicker than the Ti-based metal film. The Al-based metal film may include at least one of a pure Al film (Al film with a purity of not less than 99%), an AlCu alloy film, an AlSi alloy film and an AlSiCu alloy film.

The semiconductor device 1H includes the upper insulating film 38 aforementioned that selectively covers the main surface insulating film 25 and the first polar electrode 124. The upper insulating film 38 has the laminated structure that includes the inorganic insulating film 42 and the organic insulating film 43 laminated in that order from the chip 2 side as with the case of the first embodiment. The upper insulating film 38 has a contact opening 125 exposing an inner portion of the first polar electrode 124 and covers a peripheral edge portion of the first polar electrode 124 over an entire circumference in plan view, in this embodiment. The contact opening 125 is formed in a quadrangle shape in plan view, in this embodiment.

The upper insulating film 38 is formed at an interval inward from the peripheral edge of the first main surface 3 (the first to fourth side surfaces 5A to 5D) and defines the dicing street 41 with the peripheral edge of the first main surface 3. The dicing street 41 is formed in a band shape extending along the peripheral edge of the first main surface 3 in plan view. The dicing street 41 is formed in an annular shape (specifically, a quadrangle annular shape) surrounding the inner portion of the first main surface 3 in plan view, in this embodiment.

The dicing street 41 exposes the first main surface 3 (the first semiconductor region 6), in this embodiment. As a matter of course, in a case in which the main surface insulating film 25 covers the peripheral edge portion of the first main surface 3, the dicing street 41 may expose the main surface insulating film 25. The upper insulating film 38 preferably has a thickness exceeding the thickness of the first polar electrode 124. The thickness of the upper insulating film 38 may be less than the thickness of the chip 2.

The semiconductor device 1H includes a terminal electrode 126 that is arranged on the first polar electrode 124. The terminal electrode 126 is erected in a columnar shape on a portion of the first polar electrode 124 that is exposed from the contact opening 125. The terminal electrode 126 may have an area less than the area of the first polar electrode 124 in plan view, and may be arranged on an inner portion of the first polar electrode 124 at an interval from the peripheral edge of the first polar electrode 124. The terminal electrode 126 is formed in a polygonal shape (in this embodiment, quadrangle shape) having four sides parallel to the first to fourth side surfaces 5A to 5D in plan view, in this embodiment.

The terminal electrode 126 has a terminal surface 127 and a terminal side wall 128. The terminal surface 127 flatly extends along the first main surface. The terminal surface 127 may consist of a ground surface with grinding marks. The terminal side wall 128 is located on the upper insulating film 38 (specifically, the organic insulating film 43), in this embodiment.

That is, the terminal electrode 126 has a portion in contact with the inorganic insulating film 42 and the organic insulating film 43. The terminal side wall 128 extends substantially vertically to the normal direction Z. Here, “substantially vertically” includes a mode that extends in the laminate direction while being curved (meandering). The terminal side wall 128 includes a portion that faces the first polar electrode 124 with the upper insulating film 38 interposed therebetween. The terminal side wall 128 preferably consists of a smooth surface without a grinding mark.

The terminal electrode 126 has a protrusion portion 129 that outwardly protrudes at a lower end portion of the terminal side wall 128. The protrusion portion 129 is formed at a region on the upper insulating film 38 (the organic insulating film 43) side than an intermediate portion of the terminal side wall 128. The protrusion portion 129 extends along the outer surface of the upper insulating film 38, and is formed in a tapered shape in which a thickness gradually decreases toward the tip portion from the terminal side wall 128 in cross sectional view. The protrusion portion 129 therefore has a sharp-shaped tip portion with an acute angle. As a matter of course, the protrusion portion 129 without the protrusion portion 129 may be formed.

The terminal electrode 126 preferably has a thickness exceeding the thickness of the first polar electrode 124. The thickness of the terminal electrode 126 particularly preferably exceeds the thickness of the upper insulating film 38. The thickness of the terminal electrode 126 exceeds the thickness of the chip 2, in this embodiment. As a matter of course, the thickness of the terminal electrode 126 may be less than the thickness of the chip 2.

The thickness of the terminal electrode 126 may be not less than 10 μm and not more than 300 μm. The thickness of the terminal electrode 126 is preferably not less than 30 μm. The thickness of the terminal electrode 126 is particularly preferably not less than 80 μm and not more than 200 μm. The terminal electrode 126 preferably has a planar area of not less than 50% of the first main surface 3. The terminal electrode 126 particularly preferably has a planar area of not less than 75% of the first main surface 3.

The terminal electrode 126 includes a conductor layer 130, at least one (in this embodiment, a plurality of) gap portions 131 and at least one (in this embodiment, a plurality of) terminal portions 132. The conductor layer 130 covers the upper insulating film 38 and the first polar electrode 124 inside the contact opening 125, in this embodiment. The conductor layer 130 has a laminated structure that includes a first conductor film 133 and a second conductor film 134 laminated in that order from the first polar electrode 124 side, in this embodiment. The first conductor film 133 may include a Ti-based metal film. The first conductor film 133 may have a single layered structure consisting of a Ti film or a TiN film.

The first conductor film 133 may have a laminated structure that includes the Ti film and the TiN film laminated with an arbitrary order. The first conductor film 133 has a thickness less than the thickness of the first polar electrode 124. The first conductor film 133 covers the first polar electrode 124 in a film shape inside the contact opening 125 and is drawn out onto the upper insulating film 38 in a film shape. The first conductor film 133 forms a part of the protrusion portion 129. The first conductor film 133 does not necessarily have to be formed and may be omitted.

The second conductor film 134 forms a body of the terminal electrode 126. The second conductor film 134 may include a Cu-based metal film. The Cu-based metal film may be a pure Cu film (Cu film with a purity of not less than 99%) or Cu alloy film. The second conductor film 134 includes a pure Cu plating film, in this embodiment. The second conductor film 134 preferably has a thickness exceeding the thickness of the first polar electrode 124. The thickness of the second conductor film 134 particularly preferably exceeds the thickness of the upper insulating film 38. The thickness of the second conductor film 134 exceeds the thickness of the chip 2, in this embodiment.

The second conductor film 134 covers the first polar electrode 124 with the first conductor film 133 interposed therebetween inside the contact opening 125, and is drawn out onto the upper insulating film 38 in a film shape with the first conductor film 133 interposed therebetween. The second conductor film 134 forms a part of the protrusion portion 129. That is, the protrusion portion 129 has a laminated structure that includes the first conductor film 133 and the second conductor film 134. The second conductor film 134 has a thickness exceeding a thickness of the first conductor film 133 in the protrusion portion 129.

The gap portions 131 penetrate the conductor layer 130 and define the conductor layer 130 into a plural portions (regions) in cross sectional view. The gap portions 131 are formed at positions overlapping the first polar electrode 124 and expose parts of the first polar electrode 124. The gap portions 131 include a first gap portion 131A and a second gap portion 131B each extending in different directions, in this embodiment.

The first gap portion 131A is formed in a band shape extending in the first direction X and divides the conductor layer 130 into the second direction Y in plan view. The first gap portion 131A crosses a central portion of the conductor layer 130 in the first direction X in plan view, in this embodiment. The second gap portion 131B is formed in a band shape extending in the second direction Y such as to intersect the first gap portion 131A in plan view and divides the conductor layer 130 into the first direction X. The second gap portion 131B crosses the central portion of the conductor layer 130 in the second direction Y in plan view, in this embodiment. That is, the second gap portion 131B intersects the first gap portion 131A at the central portion of the conductor layer 130.

As a matter of course, the first gap portion 131A may be formed offset in the second direction Y from the central portion of the conductor layer 130. Also, the second gap portion 131B may be formed offset in the first direction X from the central portion of the conductor layer 130. The gap portions 131 does not necessarily include both the first gap portion 131A and the second gap portion 131B at the same time, and may include only one of the first gap portion 131A and the second gap portion 131B.

The plurality of terminal portions 132 consist of a plurality of portions of the conductor layer 130 that are defined by the gap portions 131. That is, four terminal portions 132 are demarcated by the first and second gap portions 131A, 131B, in this embodiment. The plurality of terminal portions 132 are fixed to a same potential as that of the first polar electrode 124. That is, the terminal electrode 126 is configured such that a polar potential (single potential) is given to the single first polar electrode 124 via the plurality of terminal portions 132, in this embodiment.

The plurality of terminal portions 132 are each formed in a polygonal shape (in this embodiment, quadrangle shape) having four sides parallel to the first to fourth side surfaces 5A to 5D in plan view, in this embodiment. The planar shapes of the plurality of terminal portions 132 are arbitrary, and may each be formed in a polygonal shape other than the quadrangle shape, a circular shape or an elliptical shape.

The plurality of terminal portions 132 each has a gap side wall 135 defined by the gap portions 131. The gap side wall 135 preferably consists of a smooth surface without a grinding mark. The plurality of terminal portions 132 each has the protrusion portion 129 at a lower end portion of the gap side wall 135, in this embodiment. The protrusion portion 129 at the gap side wall 135 side is positioned on the first polar electrode 124.

The semiconductor device 1H includes the sealing insulator 71 aforementioned that covers the first main surface 3. The sealing insulator 71 covers a periphery of the terminal electrode 126 such as to expose a part of the terminal electrode 126 on the first main surface 3, in this embodiment. Specifically, the sealing insulator 71 exposes the terminal surface 127 and covers the terminal side wall 128. The sealing insulator 71 covers the protrusion portion 129 and faces the upper insulating film 38 with the protrusion portion 129 interposed therebetween, in this embodiment. The sealing insulator 71 suppresses a dropout of the terminal electrode 126.

The sealing insulator 71 covers the dicing street 41 at the peripheral edge portion of the first main surface 3. The sealing insulator 71 directly covers the first main surface 3 (the first semiconductor region 6) at the dicing street 41, in this embodiment. As a matter of course, in a case in which the main surface insulating film 25 is exposed from the dicing street 41, the sealing insulator 71 may directly cover the main surface insulating film 25 at the dicing street 41.

The sealing insulator 71 has the insulating main surface 72 and the insulating side wall 73. The insulating main surface 72 flatly extends along the first main surface 3. The insulating main surface 72 forms a single flat surface with the terminal surface 127. The insulating main surface 72 may consist of a ground surface with grinding marks. In this case, the insulating main surface 72 preferably forms a single ground surface with the terminal surface 127.

The insulating side wall 73 extends toward the chip 2 from the peripheral edge of the insulating main surface 72 and is continuous to the first to fourth side surfaces 5A to 5D. The insulating side wall 73 is formed substantially perpendicular to the insulating main surface 72. The angle formed by the insulating side wall 73 with the insulating main surface 72 may be not less than 88° and not more than 92°. The insulating side wall 73 may consist of a ground surface with grinding marks. The insulating side wall 73 may form a single ground surface with the first to fourth side surfaces 5A to 5D.

The sealing insulator 71 preferably has a thickness exceeding the thickness of the first polar electrode 124. The thickness of the sealing insulator 71 particularly preferably exceeds the thickness of the upper insulating film 38. The thickness of the sealing insulator 71 exceeds the thickness of the chip 2, in this embodiment. As a matter of course, the thickness of the sealing insulator 71 may be less than the thickness of the chip 2. The thickness of the sealing insulator 71 may be not less than 10 μm and not more than 300 μm. The thickness of the sealing insulator 71 is preferably not less than 30 μm. The thickness of the sealing insulator 71 is particularly preferably not less than 80 μm and not more than 200 μm.

The semiconductor device 1H includes the gap insulator 74 aforementioned that is embedded in the gap portions 131 such as to expose a part of the terminal electrode 126 (parts of the plurality of terminal portions 132). The gap insulator 74 includes the first and second gap insulator 74A, 74B as with the case of the first embodiment. The gap insulator 74 covers the gap side walls 135 of the plurality of terminal portions 132 in the first and second gap portions 131A, 131B. That is, the gap insulator 74 partitions the plurality of terminal portions 132 inside the gap portions 131. Also, the gap insulator 74 covers the first polar electrode 124 in a lattice pattern (cross pattern) in plan view.

The gap insulator 74 keeps the plurality of terminal portions 132 fixed at the same potential as the source electrode 32, and physically divides the plurality of terminal portions 132 on the first polar electrode 124. In other words, the gap insulator 74 is configured such as to allow a vertical current transfer among the plurality of terminal portions 132 and the first polar electrode 124, and restrict a lateral current transfer among the plurality of source terminal portions 66.

The gap insulator 74 directly covers the first polar electrode 124 inside the gap portions 131, in this embodiment. Also, the gap insulator 74 covers the protrusion portion 129 inside the gap portions 131 and covers the first polar electrode 124 with the protrusion portion 129 interposed therebetween. The gap insulator 74 suppresses a dropout of the terminal portions 132. The gap insulator 74 is connected to the sealing insulator 71 outside the gap portions 131.

The gap insulator 74 consists of a part of the sealing insulator 71, in this embodiment. That is, the gap insulator 74 has the insulating main surface 72 that is continuous to the terminal surface 127. Also, the gap insulator 74 includes the thermosetting resin, the plurality of fillers and the plurality of flexible particles. As a matter of course, the gap insulator 74 may consist of an insulating material different from that of the sealing insulator 71.

The semiconductor device 1H includes a second polar electrode 136 (second main surface electrode) that covers the second main surface 4. The second polar electrode 136 is a “cathode electrode”, in this embodiment. The second polar electrode 136 is electrically connected to the second main surface 4. The second polar electrode 136 forms an ohmic contact with the second semiconductor region 7 exposed from the second main surface 4. The second polar electrode 136 may cover a whole region of the second main surface 4 such as to be continuous with the peripheral edge of the chip 2 (the first to fourth side surfaces 5A to 5D).

The second polar electrode 136 may cover the second main surface 4 at an interval from the peripheral edge of the chip 2. The second polar electrode 136 is configured such that a voltage of not less than 500 V and not more than 3000 V is to be applied between the terminal electrode 126 (the plurality of terminal portions 132) and second polar electrode 136. That is, the chip 2 is formed such that the voltage of not less than 500 V and not more than 3000 V is to be applied between the first main surface 3 and the second main surface 4.

As described above, the semiconductor device 1H includes the chip 2, the first polar electrode 124 (main surface) and the terminal electrode 126. The chip 2 has the first main surface 3. The first polar electrode 124 is arranged on the first main surface 3. The terminal electrode 126 is arranged on the first polar electrode 124 and is fixed to the same potential as that of the first polar electrode 124. The terminal electrode 126 includes the conductor layer 130 and the gap portion 131. The conductor layer 130 covers the first polar electrode 124. The gap portion 131 penetrates the conductor layer 130 in the thickness direction in cross sectional view.

According to this structure, a volume of the terminal electrode 126 is reduced by the gap portion 131, and therefore a stress due to the terminal electrode 126 is reduced. The gap portion 131 is also effective in blocking a stress continuously generated in a width direction of the terminal electrode 126. As a result, it is possible to suppress fluctuations in electrical characteristics and shape defects due to the stress of the terminal electrode 126. It is therefore possible to provide the semiconductor device 1H capable of achieving the same effects as those of the semiconductor device 1A.

With the manufacturing method for the semiconductor device 1H, the wafer structure 80 in which structures corresponding to the semiconductor device 1H are formed in each device region 86 is prepared, and the terminal electrode 126 is formed on the first polar electrode 124 through the similar steps to those of the manufacturing method for the semiconductor device 1A. Therefore, the same effects as those of the manufacturing method for the semiconductor device 1A are also achieved with the manufacturing method for the semiconductor device 1H.

Hereinafter, modified examples to be applied to each embodiment shall be shown. Hereinafter, examples in which modified examples are applied to the semiconductor device 1A according to the first embodiment, but the following modified examples, or a combination mode of the following modified examples may appropriately applied to any one of the first to eighth embodiments. In a case in which the following modified examples are to be applied to the eighth embodiment, “the source gap portions 65”, “the source terminal electrode 60”, etc., are replaced to “the gap portions 131”, “the terminal electrode 126”, etc.

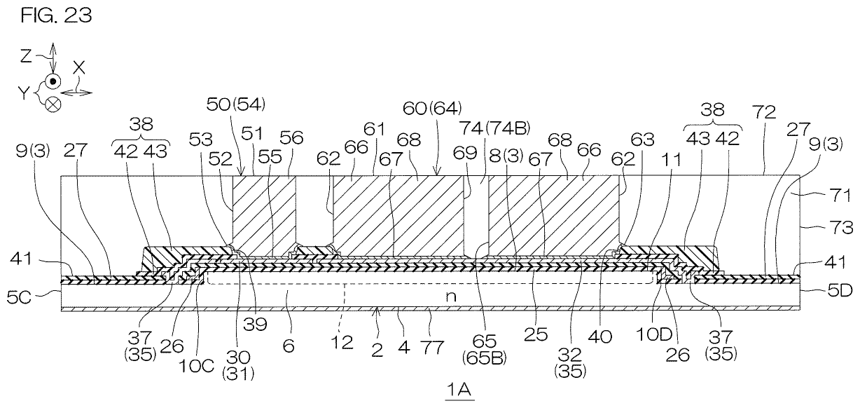

FIG. 23 is a cross sectional view showing a modified example of the chip 2 to be applied to each of the embodiments. With reference to FIG. 23, the semiconductor device 1A does not have the second semiconductor region 7 inside the chip 2 and may only have the first semiconductor region 6 inside the chip 2. In this case, the first semiconductor region 6 is exposed from the first main surface 3, the second main surface 4 and the first to fourth side surfaces 5A to 5D of the chip 2.

That is, the chip 2 has a single layered structure that does not have the semiconductor substrate and that consists of the epitaxial layer, in this embodiment. The chip 2 having such a structure is formed by fully removing the second semiconductor region 7 (the semiconductor substrate) in the step shown in FIG. 11H aforementioned. The structures according to the first to eighth embodiments are effective in suppressing a deformation of the chip 2 in a case in which such an extremely thin chip 2 is adopted.

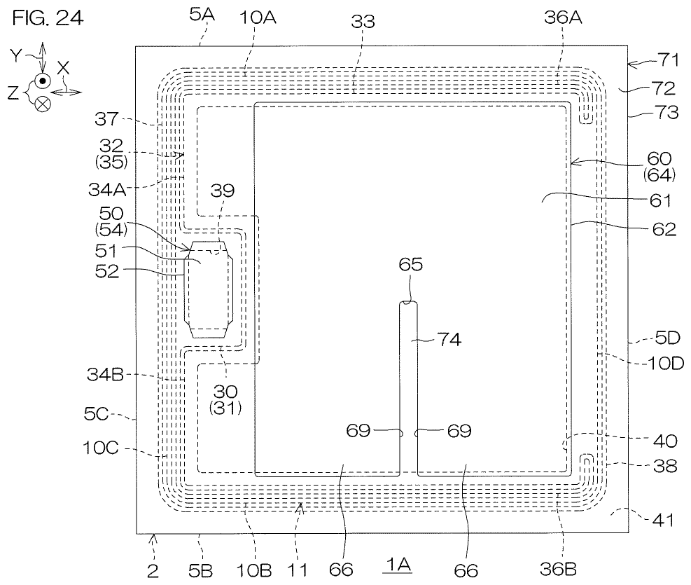

FIG. 24 is a plan view showing a modified example of the source gap portions 65 to be applied to each of the embodiments. With reference to FIG. 24, the source gap portions 65 do not necessarily have to divide the source conductor layer 64 in the first direction X and/or the second direction Y. The source gap portions 65 may extend in the first direction X and/or the second direction Y from the source terminal side wall 62 and may have an end portion that is positioned at an inner portion of the source terminal electrode 60. That is, the source gap portions 65 may be formed in a notched shape. With such a structure, it is also possible to reduce the volume of the source terminal electrode 60 and reduce the stress due to the source terminal electrode 60.

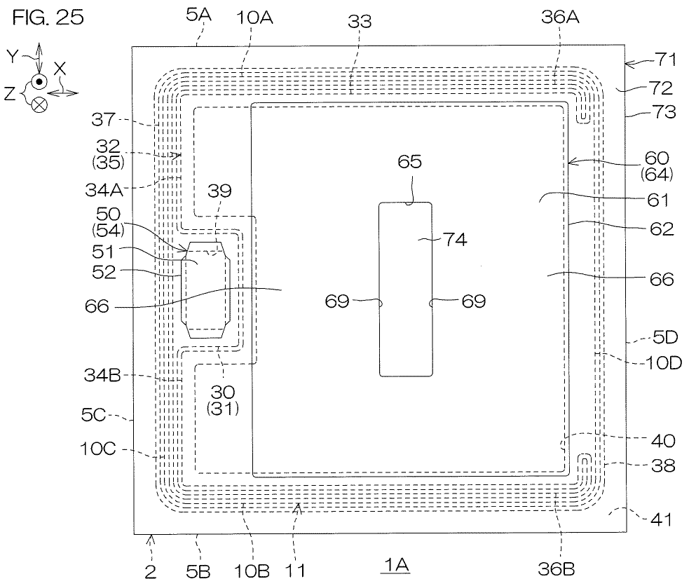

FIG. 25 is a plan view showing a modified example of the source gap portions 65 to be applied to each of the embodiments. With reference to FIG. 25, the source gap portions 65 do not necessarily have to divide the source conductor layer 64 in the first direction X and/or the second direction Y. The source gap portions 65 may be formed in an inner portion of the source terminal electrode 60 at an interval from the source terminal side wall 62. In this case, the source gap portions 65 may extend in the first direction X and/or the second direction Y and may have an end portion positioned at an inner portion of the source terminal electrode 60. That is, the source gap portions 65 may be formed in an opening shape.

The gap insulator 74 is embedded only in the source gap portions 65 that is enclosed by the source conductor layer 64. That is, the gap insulator 74 is formed such as to be physically separated from the sealing insulator 71 by the source conductor layer 64. With such a structure, it is also possible to reduce the volume of the source terminal electrode 60 and reduce the stress due to the source terminal electrode 60.

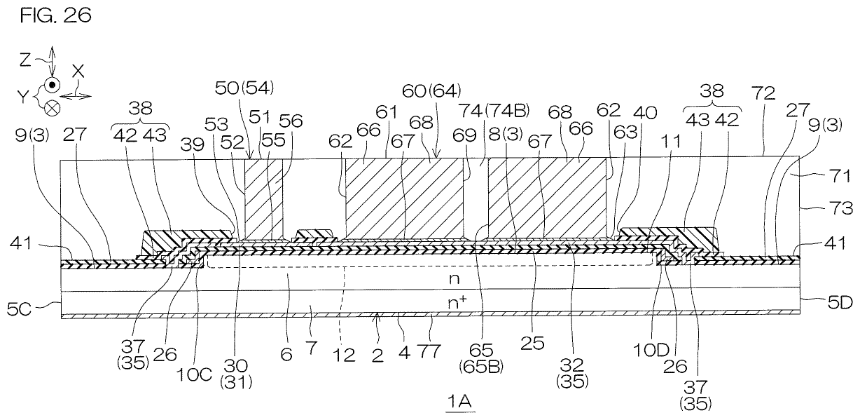

FIG. 26 is a cross sectional view showing a modified example of the sealing insulator 71 to be applied to each of the embodiments. With reference to FIG. 26, the sealing insulator 71 that covers a whole region of the upper insulating film 38 may be formed. In this case, the gate terminal electrode 50 that is not in contact with the upper insulating film 38 and the source terminal electrode 60 that is not in contact with the upper insulating film 38 are formed.

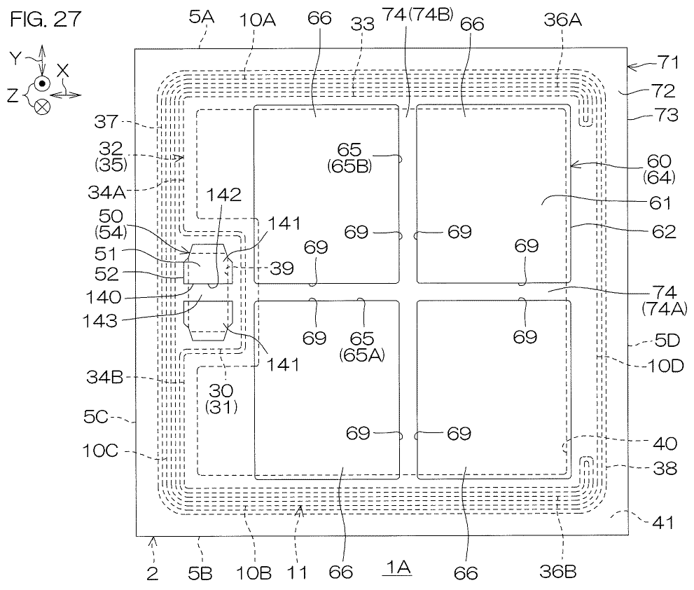

FIG. 27 is a plan view showing a modified example of the gate terminal electrode 50 to be applied to each of the embodiments. With reference to FIG. 27, the gate terminal electrode 50 may include the gate conductor layer 54, at least one (in this embodiment, one) gate gap portion 140 and at least one (in this embodiment, a plurality of) gate terminal portions 141.

The gate gap portion 140 penetrates the gate conductor layer 54 and defines the gate conductor layer 54 into a plural portions (regions) in cross sectional view. The gate gap portion 140 is formed at a position overlapping to the gate electrode 30 in plan view and exposes a part of the gate electrode 30. The gate gap portion 140 may expose a part of the upper insulating film 38.

The gate gap portion 140 may be formed in a band shape extending in one of or both of the first direction X and the second direction Y. The gate gap portion 140 crosses a central portion of the gate conductor layer 54 in the first direction X and divides the gate conductor layer 54 into the second direction Y in plan view, in this embodiment. As a matter of course, the gate gap portion 140 may include a plurality of band portions extending in the first direction X and the second direction Y such as to intersect each other.

The plurality of gate terminal portions 141 consist of a plural portions of the gate conductor layer 54 that are defined by the gate gap portion 140. That is, two gate terminal portions 141 are defined by the gate gap portion 140, in this embodiment. The plurality of gate terminal portions 141 are fixed to a same potential as that of the gate electrode 30. That is, the gate terminal electrode 50 is configured such that a gate potential (single potential) is given to the single gate electrode 30 via the plurality of gate terminal portions 141, in this embodiment.

The plurality of gate terminal portions 141 each has the gate gap side wall 142 defined by the gate gap portion 140. The gate gap side wall 142 preferably consists of a smooth surface without a grinding mark. The plurality of gate terminal portions 141 each has the first protrusion portion 53 at a lower end portion of the gate gap side wall 142, in this embodiment. The first protrusion portion 53 at the gate gap side wall 142 side is positioned on the gate electrode 30.

The semiconductor device 1A includes a gate gap insulator 143 embedded in the gate gap portion 140, in this embodiment. The gate gap insulator 143 covers the gate gap side wall 142 of the plurality of gate terminal portions 141 at the gate gap portion 140 such as to expose a part of the gate terminal electrode 50 (parts of the plurality of gate terminal portions 141).

That is, the gate gap insulator 143 defines the plurality of gate terminal portions 141 inside the gate gap portion 140. The gate gap insulator 143 keeps the gate electrode 30 and the plurality of gate terminal portions 141 fixed at the same potential, and physically divides the plurality of gate terminal portions 141 on the gate electrode 30, in this embodiment.

In other words, the gate gap insulator 143 is configured such as to allow a vertical current transfer among the gate electrode 30 and the plurality of gate terminal portions 141, and restrict a lateral current transfer among the plurality of gate terminal portions 141. The gate gap insulator 143 directly covers the gate electrode 30 inside the gate gap portion 140, in this embodiment.

Also, the gate gap insulator 143 covers the first protrusion portion 53 inside the gate gap portion 140 and covers the gate electrode 30 with the first protrusion portion 53 interposed therebetween. The gate gap insulator 143 suppresses a dropout of the gate terminal portions 141. The gate gap insulator 143 may have a portion that covers the upper insulating film 38 in the gate gap portion 140.

The gate gap insulator 143 is connected to the sealing insulator 71 outside the gate gap portion 140. The gate gap insulator 143 consists of a part of the sealing insulator 71, in this embodiment. That is, the gate gap insulator 143 has the insulating main surface 72 that is continuous to the gate terminal surface 51 and the source terminal surface 61. As a matter of course, the gate gap insulator 143 may consist of an insulating material different from that of the sealing insulator 71.

As described above, the semiconductor device 1A includes the chip 2, the gate electrode 30 (main surface electrode) and the gate terminal electrode 50 (terminal electrode). The chip 2 has the first main surface 3. The gate electrode 30 is arranged on the first main surface 3. The gate terminal electrode 50 is arranged on the gate electrode 30 and is fixed to the same potential as that of the gate electrode 30. The gate terminal electrode 50 includes the gate conductor layer 54 and the gate gap portion 140. The gate conductor layer 54 covers the gate electrode 30. The gate gap portion 140 penetrates the gate conductor layer 54 in the thickness direction in cross sectional view.

According to this structure, a volume of the gate terminal electrode 50 is reduced by the gate gap portion 140, and therefore a stress due to the gate terminal electrode 50 is reduced. The gate gap portion 140 is also effective in blocking a stress continuously generated in a width direction of the gate terminal electrode 50. It is therefore possible to suppress fluctuations in electrical characteristics and shape defects due to the stress of the gate terminal electrode 50. As a result, it is possible to provide the semiconductor device 1A capable of improving reliability.

The semiconductor device 1A having the gate gap portion 140 (the gate gap insulator 143) is manufactured by modifying the layout of the resist mask 90. Therefore, the same effects as those of the manufacturing method for the semiconductor device 1A are also achieved with the manufacturing method for the semiconductor device 1A having the gate gap portion 140. In a case in which the gate terminal electrode 50 with the gate gap portion 140 is formed, the source terminal electrode 60 without the source gap portions 65 may be formed.

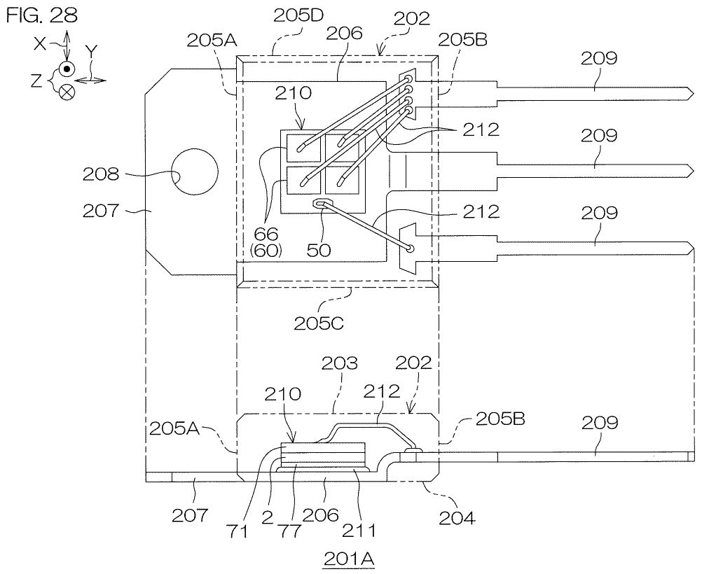

Hereinafter, configuration examples of packages to which any one or plural of the semiconductor devices 1A to 1H according to the first to eighth embodiments are to be incorporated shall be shown. FIG. 28 is a plan view showing a package 201A to which any one of the semiconductor devices 1A to 1G according to the first to seventh embodiments is to be incorporated. The package 201A may be referred to as a “semiconductor package” or a “semiconductor module”.

With reference to FIG. 28, the package 201A includes a package body 202 of a rectangular parallelepiped shape. The package body 202 consists of a mold resin, and includes a matrix resin (for example, epoxy resin), a plurality of fillers and a plurality of flexible particles (flexible agent) as with the sealing insulator 71. The package body 202 has a first surface 203 on one side, a second surface 204 on the other side, and first to fourth side walls 205A to 205D connecting the first surface 203 and the second surface 204.

The first surface 203 and the second surface 204 are each formed in a quadrangle shape in plan view as viewed from their normal direction Z. The first side wall 205A and the second side wall 205B extend in the first direction X and oppose in the second direction Y orthogonal to the first direction X. The third side wall 205C and the fourth side wall 205D extend in the second direction Y and oppose in the first direction X.

The package 201A includes a metal plate 206 (conductor plate) that is arranged inside the package body 202. The metal plate 206 may be referred to as a “die pad”. The metal plate 206 is formed in a quadrangle shape (specifically, rectangular shape) in plan view. The metal plate 206 includes a drawer board part 207 that is drawn out from the first side wall 205A to an outside of the package body 202. The drawer board part 207 has a through hole 208 of a circular shape. The metal plate 206 may be exposed from the second surface 204.

The package 201A includes a plurality of (in this embodiment, three) lead terminals 209 that are pulled out from an inside of the package body 202 to the outside of the package body 202. The plurality of lead terminals 209 are arranged on the second side wall 205B side. The plurality of lead terminals 209 are each formed in a band shape extending in an orthogonal direction to the second side wall 205B (that is, the second direction Y). The lead terminals 209 on both sides of the plurality of lead terminals 209 are arranged at intervals from the metal plate 206, and the lead terminals 209 on a center is integrally formed with the metal plate 206. A position of the lead terminal 209 that is to be connected to the metal plate 206 is arbitrary.

The package 201A includes a semiconductor device 210 that is arranged on the metal plate 206 inside the package body 202. The semiconductor device 210 consists of any one of the semiconductor devices 1A to 1G according to the first to seventh embodiments. The semiconductor device 210 is arranged on the metal plate 206 in a posture with the drain electrode 77 opposing the metal plate 206, and is electrically connected to the metal plate 206.

The package 201A includes a conductive adhesive 211 that is interposed between the drain electrode 77 and the metal plate 206 and that connects the semiconductor device 210 to the metal plate 206. The conductive adhesive 211 may include a solder or a metal paste. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The package 201A includes at least one (in this embodiment, a plurality of) conducting wires 212 (conductive connection member) that are electrically connected to the lead terminals 209 and the semiconductor device 210 inside the package body 202. The conducting wires 212 each consists of a metal wire (that is, bonding wire), in this embodiment. The conducting wires 212 may include at least one of a gold wire, a copper wire and an aluminum wire. As a matter of course, the conducting wires 212 may each consist of a metal plate such as a metal clip, instead of the metal wire.

At least one (in this embodiment, one) conducting wire 212 is electrically connected to the gate terminal electrode 50 and the lead terminal 209. At least one (in this embodiment, four) conducting wires 212 are electrically connected to the source terminal electrode 60 and the lead terminal 209. The four conducting wires 212 connect the four source terminal portions 66 to the single lead terminal 209, in this embodiment. In a case in which the source terminal electrode 60 includes the sense terminal portions 102 (see FIG. 13), the lead terminal 209 corresponding to the sense terminal portions 102, and the conducting wires 212 to be connected to the sense terminal portions 102 and the lead terminal 209 may be provided.

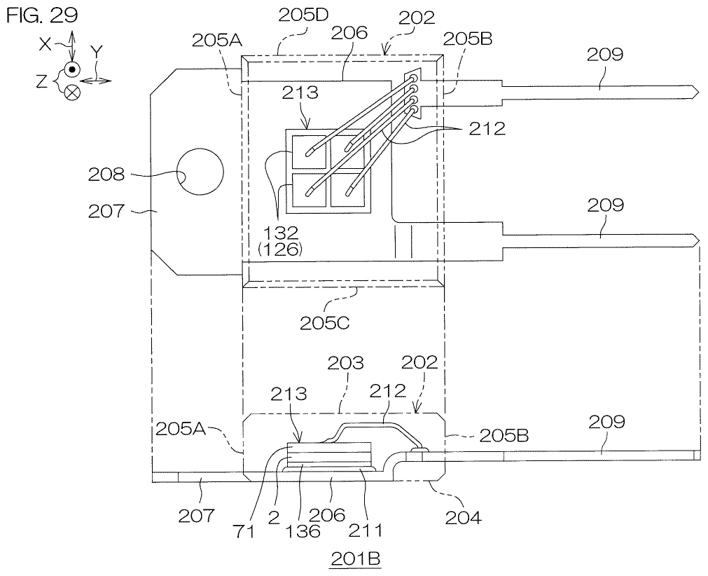

FIG. 29 is a plan view showing a package 201B to which the semiconductor device 1H according to the eighth embodiment is to be incorporated. The package 201B may be referred to as a “semiconductor package” or a “semiconductor module”. With reference to FIG. 29, the package 201B includes the package body 202, the metal plate 206, the plurality (in this embodiment, two) lead terminals 209, a semiconductor device 213, the conductive adhesive 211, and the plurality conducting wires 212. Hereinafter, points different from those of the package 201A shall be described.

One lead terminal 209 of the plurality of lead terminals 209 is arranged at an interval from the metal plate 206, and the other lead terminals 209 is integrally formed with the metal plate 206. The semiconductor device 213 is arranged on the metal plate 206 inside the package body 202. The semiconductor device 213 consists of the semiconductor device 1H according to eighth embodiment. The semiconductor device 213 is arranged on the metal plate 206 in a posture with the second polar electrode 136 opposing to the metal plate 206, and is electrically connected to the metal plate 206.

The conductive adhesive 211 is interposed between the second polar electrode 136 and the metal plate 206 and connects the semiconductor device 213 to the metal plate 206. At least one (in this embodiment, four) conducting wires 212 are electrically connected to the terminal electrode 126 and the lead terminal 209. The four conducting wires 212 connect the four terminal portions 132 to the single lead terminals 209, in this embodiment.

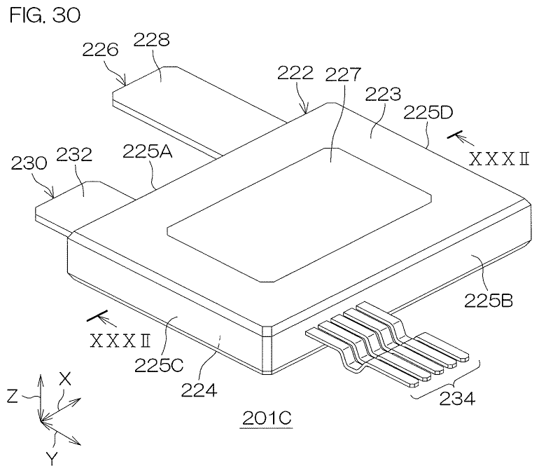

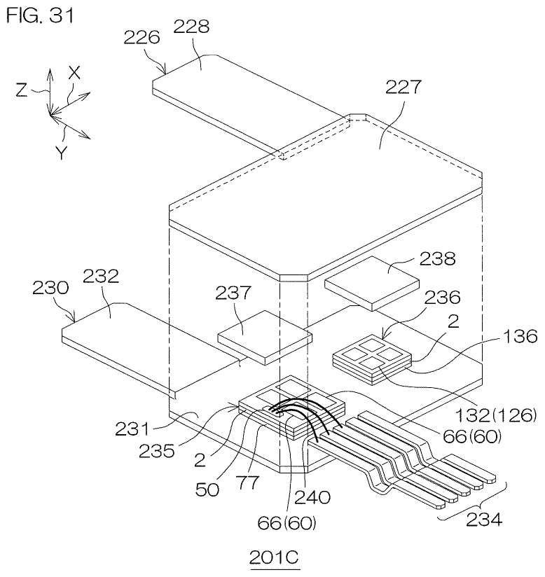

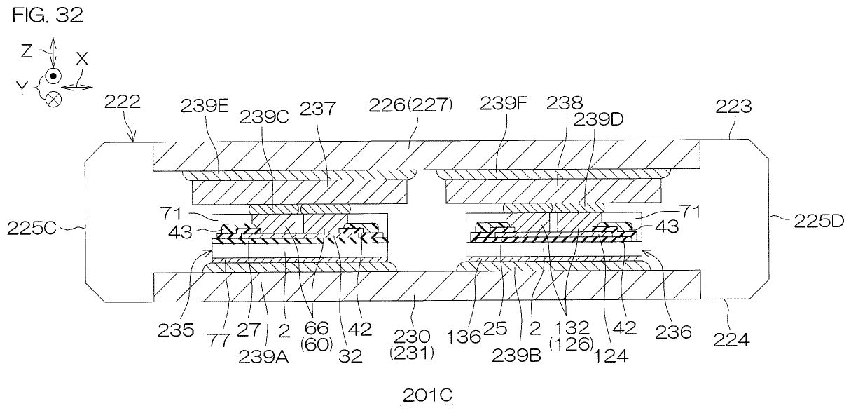

FIG. 30 is a perspective view showing a package 201C to which any one of the semiconductor devices 1A to 1G according to the first to seventh embodiments and the semiconductor device 1H according to the eighth embodiment are to be incorporated. FIG. 31 is an exploded perspective view of the package 201C shown in FIG. 30. FIG. 32 is a cross sectional view taken along XXXII-XXXII line shown in FIG. 30. The package 201C may be referred to as a “semiconductor package” or a “semiconductor module”.

With reference to FIG. 30 to FIG. 32, the package 201C includes a package body 222 of a rectangular parallelepiped shape. The package body 222 consists of a mold resin and includes a matrix resin (for example, epoxy resin), a plurality of fillers and a plurality of flexible particles (flexible agent) as with the sealing insulator 71. The package body 222 has a first surface 223 on one side, a second surface 224 on the other side, and first to fourth side walls 225A to 225D connecting the first surface 223 and the second surface 224.

The first surface 223 and the second surface 224 each formed in a quadrangle shape (in this embodiment, rectangular shape) in plan view as viewed from their normal direction Z. The first side wall 225A and the second side wall 225B extend in the first direction X along the first surface 223 and oppose in the second direction Y. The first side wall 225A and the second side wall 225B each forms a long side of the package body 222. The third side wall 225C and the fourth side wall 225D extend in the second direction Y and oppose in the first direction X. The third side wall 225C and the fourth side wall 225D each forms a short side of the package body 222.

The package 201C includes a first metal plate 226 that is arranged inside and outside the package body 222. The first metal plate 226 is arranged on the first surface 223 side of the first surface 223 and includes a first pad portion 227 and a first lead terminal 228. The first pad portion 227 is formed in a rectangular shape extending in the first direction X inside the package body 222 and exposes the first surface 223.

The first lead terminal 228 is pulled out from the first pad portion 227 toward the first side wall 225A in a band shape extending in the second direction Y, and penetrates the first side wall 225A to be exposed from the package body 222. The first lead terminal 228 is arranged on the fourth side wall 225D side in plan view. The first lead terminal 228 is exposed from the first side wall 225A at a position at intervals from the first surface 223 and the second surface 224.

The package 201C includes a second metal plate 230 that is arranged inside and outside the package body 222. The second metal plate 230 is arranged on the second surface 224 side of the package body 222 at an interval from the first metal plate 226 in the normal direction Z and includes a second pad portion 231 and a second lead terminal 232. The second pad portion 231 is formed in a rectangular shape extending in the first direction X inside the package body 222 and exposes from the second surface 224.

The second lead terminal 232 is pulled out from the second pad portion 231 to the first side wall 225A in a band shape extending in the second direction Y, and penetrates the first side wall 225A to be exposed from the package body 222. The second lead terminal 232 arranged on the third side wall 225C side in plan view. The second lead terminal 232 is exposed from the first side wall 225A at a position at intervals from the first surface 223 and the second surface 224.

The second lead terminal 232 is pulled out at a thickness position different from a thickness position of the first lead terminal 228, in regard to the normal direction Z. The second lead terminal 232 is formed at an interval from the first lead terminal 228 to the second surface 224 side, and does not oppose the first lead terminal 228 in the first direction X, in this embodiment. The second lead terminal 232 has a length different from a length of the first lead terminal 228, in regard to the second direction Y.

The package 201C includes a plurality of (in this embodiment, five) third lead terminals 234 that are pulled out from inside of the package body 222 to outside of the package body 222. The plurality of third lead terminals 234 are arranged in a thickness range between the first pad portion 227 and the second pad portion 231, in this embodiment. The plurality of third lead terminals 234 are each pulled out from inside of the package body 222 toward the second side wall 225B in a band shape extending in the second direction Y, and penetrate the second side wall 225B to be exposed from the package body 222.

An arrangement of the plurality of third lead terminals 234 is arbitrary. The plurality of third lead terminals 234 are arranged on the third side wall 225C side such as to locate on the same straight line with the second lead terminal 232, in plan view, in this embodiment. The plurality of third lead terminals 234 may each have a curved section bent toward the first surface 223 and/or the second surface 224 in a portion located outside the package body 222.

The package 201C includes a first semiconductor device 235 that is arranged inside the package body 222. The first semiconductor device 235 consists of any one of the semiconductor devices 1A to 1G according to the first to seventh embodiments. The first semiconductor device 235 is arranged between the first pad portion 227 and the second pad portion 231. The first semiconductor device 235 is arranged on the third side wall 225C side in plan view. The first semiconductor device 235 is arranged on the second metal plate 230 in a posture with the drain electrode 77 opposing to the second metal plate 230 (the second pad portion 231), and is electrically connected to the second metal plate 230.

The package 201C includes a second semiconductor device 236 that is arranged inside the package body 222 at an interval from the first semiconductor device 235. The second semiconductor device 236 consists of the semiconductor device 1H according to the eighth embodiment. The second semiconductor device 236 is arranged between the first pad portion 227 and the second pad portion 231. The second semiconductor device 236 is arranged on the fourth side wall 225D side in plan view. The second semiconductor device 236 is arranged on the second metal plate 230 in a posture with the second polar electrode 136 opposing to the second metal plate 230 (the second pad portion 231), and is electrically connected to the second metal plate 230.

The package 201C includes a first conductor spacer 237 (first conductive connection member) and a second conductor spacer 238 (second conductive connection member) that are each arranged inside the package body 222. The first conductor spacer 237 is interposed between the first semiconductor device 235 and the first pad portion 227 and is electrically connected to the first semiconductor device 235 and the first pad portion 227. The second conductor spacer 238 is interposed between the second semiconductor device 236 and the first pad portion 227 and is electrically connected to the second semiconductor device 236 and the first pad portion 227.

The first conductor spacer 237 and the second conductor spacer 238 may each include a metal plate (for example, Cu-based metal plate). The second conductor spacer 238 consists of a separated member from the first conductor spacer 237 in this embodiment, but the second conductor spacer 238 may be integrally formed with the first conductor spacer 237.

The package 201C includes first to sixth conductive adhesives 239A to 239F. The first to sixth conductive adhesives 239A to 239F may each include a solder or a metal past. The solder may be a lead-free solder. The metal paste may include at least one of Au, Ag and Cu. The Ag paste may consist of an Ag sintered paste. The Ag sintered paste consists of a paste in which Ag particles of nano size or micro size are added into an organic solvent.

The first conductive adhesive 239A is interposed between the drain electrode 77 and the second pad portion 231, and connects the first semiconductor device 235 to the second pad portion 231. The second conductive adhesive 239B is interposed between the second polar electrode 136 and the second pad portion 231, and connects the second semiconductor device 236 to the second pad portion 231.

The third conductive adhesive 239C is interposed between the source terminal electrode 60 and the first conductor spacer 237, and connects the first conductor spacer 237 to the source terminal electrode 60. The fourth conductive adhesive 239D is interposed between the terminal electrode 126 and the second conductor spacer 238, and connects the second conductor spacer 238 to the terminal electrode 126.

The fifth conductive adhesive 239E is interposed between the first pad portion 227 and the first conductor spacer 237, and connects the first conductor spacer 237 to the first pad portion 227. The sixth conductive adhesive 239F is interposed between the first pad portion 227 and the second conductor spacer 238, and connects the second conductor spacer 238 to the first pad portion 227.

The package 201C includes at least one (in this embodiment, a plurality of) conducting wires 240 (conductive connection member) that are electrically connected to the gate terminal electrode 50 of the first semiconductor device 235 and at least one (in this embodiment, a plurality of) third lead terminals 234 inside the package body 222. The conducting wires 240 each consists of a metal wire (that is, bonding wire), in this embodiment. The conducting wires 240 may include at least one of a gold wire, a copper wire and an aluminum wire. As a matter of course, the conducting wires 240 may each consist of a metal plate such as a metal clip, instead of the metal wire.

An example in which the single first conductor spacer 237 is connected to the plurality of source terminal portions 66 has been shown, in this embodiment. However, a plurality of first conductor spacers 237 may be provided. In this case, the plurality of first conductor spacers 237 may each be connected to the plurality of source terminal portions 66 with a one-to-one correspondence. As a matter of course, at least one of the plurality of first conductor spacers 237 may be connected to the plurality of source terminal portions 66. Also, the plurality of source terminal portions 66 may be connected to the first pad portion 227 by the third conductive adhesive 239C without the first conductor spacer 237.

An example in which the single second conductor spacer 238 is connected to the plurality of terminal portions 132 has been shown, in this embodiment. However, a plurality of second conductor spacers 238 may be provided. In this case, the plurality of second conductor spacers 238 may each be connected to the plurality of terminal portions 132 with a one-to-one correspondence. As a matter of course, at least one of the plurality of second conductor spacers 238 may be connected to the plurality of terminal portions 132. Also, the plurality of terminal portions 132 may be connected to the first pad portion 227 by the fourth conductive adhesive 239D without the second conductor spacer 238. In a case in which the source terminal electrode 60 includes the sense terminal portions 102 (see FIG. 13), a conducting wire 240 to be connected to the sense terminal portion 102 and the third lead terminal 234 may be further provide.

Each of the above embodiments can be implemented in yet other embodiments. For example, features disclosed in the first to eighth embodiments aforementioned can be appropriately combined therebetween. That is, a configuration that includes at least two features among the features disclosed in the first to eighth embodiments aforementioned at the same time may be adopted.

Also, in each of the above embodiments, the source gap portion 65 (the first source gap portion 65A and the second source gap portion 65B) extending in one of or both of the first direction X and the second direction Y has been shown. However, the direction in which the source gap portion 65 (the first source gap portion 65A and the second source gap portion 65B) extends is arbitrary and is not restricted to one of or both of the first direction X and the second direction Y

For example, one or plurality of source gap portions 65 (the first source gap portion 65A and the second source gap portion 65B) extending in a diagonal direction of the source conductor layer 64 may be formed. As a matter of course, one or plurality of gap portions 131 extending in a diagonal direction of the conductor layer 130 may be formed. Also, one or plurality of gate gap portions 140 extending in a diagonal direction of the gate conductor layer 54 may be formed.

In each of the above embodiments, the chip 2 having the mesa portion 11 has been shown. However, the chip 2 that does not have the mesa portion 11 and has the first main surface 3 extending in a flat may be adopted. In this case, the side wall structure 26 may be omitted.

In each of the above embodiments, the configurations that has the source wiring 37 have been shown. However, configurations without the source wiring 37 may be adopted. In each of the above embodiments, the gate structure 15 of the trench gate type that controls the channel inside the chip 2 has been shown. However, the gate structure 15 of a planar gate type that controls the channel from on the first main surface 3 may be adopted.

In each of the above embodiments, the configurations in which the MISFET structure 12 and the SBD structure 120 are formed in the different chips 2 have been shown. However, the MISFET structure 12 and the SBD structure 120 may be formed in different regions of the first main surface 3 in the same chip 2. In this case, the SBD structure 120 may be formed as a reflux diode of the MISFET structure 12.

In each of the embodiments, the configuration in which the “first conductive type” is the “n-type” and the “second conductive type” is the “p-type” has been shown. However, in each of the embodiments, a configuration in which the “first conductive type” is the “p-type” and the “second conductive type” is the “n-type” may be adopted. The specific configuration in this case can be obtained by replacing the “n-type” with the “p-type” and at the same time replacing the “p-type” with the “n-type” in the above descriptions and attached drawings.

In each of the embodiments, the second semiconductor region 7 of the “n-type” has been shown. However, the second semiconductor region 7 may be the “p-type”. In this case, an IGBT (Insulated Gate Bipolar Transistor) structure is formed instead of the MISFET structure 12. In this case, in the above descriptions, the “source” of the MISFET structure 12 is replaced with an “emitter” of the IGBT structure, and the “drain” of the MISFET structure 12 is replaced with a “collector” of the IGBT structure. As a matter of course, in a case in which the chip 2 has a single layered structure that consists of the epitaxial layer, the second semiconductor region 7 of the “p-type” may have p-type impurities introduced into a surface layer portion of the second main surface 4 of the chip 2 (the epitaxial layer) by an ion implantation method.

In each of the embodiments, the first direction X and the second direction Y are defined by the extending directions of the first to fourth side surfaces 5A to 5D. However, the first direction X and the second direction Y may be any directions as long as the first direction X and the second direction Y keep a relationship in which the first direction X and the second direction Y intersect (specifically, perpendicularly intersect) each other. For example, the first direction X may be a direction intersecting the first to fourth side surfaces 5A to 5D, and the second direction Y may be a direction intersecting the first to fourth side surfaces 5A to 5D.

Hereinafter, examples of features extracted from the present descriptions and the attached drawings shall be indicated below. Hereinafter, the alphanumeric characters in parentheses represent the corresponding components in the aforementioned embodiments, but are not intended to limit the scope of each clause to the embodiments. The “semiconductor device” in the following clauses may be replaced with a “wide bandgap semiconductor device”, an “SiC semiconductor device”, a “semiconductor switching device” or a “semiconductor rectifier device” as needed.

[A1] A semiconductor device (1A to 1H) comprising: a chip (2) having the main surface (3); a main surface electrode (30, 32, 124) arranged on the main surface (3); and a terminal electrode (50, 60, 126) that has a conductor layer (54, 64, 130) covering the main surface electrode (30, 32, 124) and a gap section (65, 101, 131, 140) penetrating the conductor layer (54, 64, 130) in a thickness direction as viewed in cross section, and that is fixed to a same potential as that of the main surface electrode (30, 32, 124).

[A2] The semiconductor device (1A to 1H) according to A1, wherein the terminal electrode (50, 60, 126) has terminal portions (66, 102, 132, 141) that are demarcated by the gap section (65, 101, 131, 140) and fixed to the same potential as that of the main surface electrode (30, 32, 124), respectively.

[A3] The semiconductor device (1A to 1H) according to A2, wherein the terminal portions (66, 102, 132, 141) are physically separated by the gap section (65, 101, 131, 140).

[A4] The semiconductor device (1A to 1H) according to any one of A1 to A3, wherein the gap section (65, 101, 131, 140) is formed at a position overlapping the main surface electrode (30, 32, 124) as viewed in plane.

[A5] The semiconductor device (1A to 1H) according to any one of A1 to A4, further comprising: a gap insulator (74, 105, 143) that is embedded in the gap section (65, 101, 131, 140) such as to expose a part of the terminal electrode (50, 60, 126).

[A6] The semiconductor device (1A to 1H) according to A5, wherein the terminal electrode (50, 60, 126) is thicker than the main surface electrode (30, 32, 124), and the gap insulator (74, 105, 143) is thicker than the main surface electrode (30, 32, 124).

[A7] The semiconductor device (1A to 1H) according to A5 or A6, wherein the terminal electrode (50, 60, 126) has an electrode surface (51, 61, 127), and the gap insulator (74, 105, 143) has an insulator surface (72) that forms a single flat surface with the electrode surface (51, 61, 127).

[A8] The semiconductor device (1A to 1H) according to A7, wherein the electrode surface (51, 61, 127) consists of a ground surface having a grinding mark, and the insulator surface (72) consists of a ground surface having a grinding mark.

[A9] The semiconductor device (1A to 1H) according to any one of A1 to A8, wherein the main surface electrode (32) has a lower conductor layer (35) covering the main surface (3) and a lower gap portion (107) penetrating the lower conductor layer (35) in a thickness direction as viewed in cross section, and the gap portion (65) is formed at a position overlapping the lower gap portion (107) as viewed in plane.

[A10] The semiconductor device (1A to 1H) according to A9, wherein the main surface electrode (30, 32, 124) includes electrode portions (108) that are demarcated by the lower gap portion (107).

[A11] The semiconductor device (1A to 1H) according to A9 or A10, further comprising: a wiring (109) arranged in the lower gap portion (107).

[A12] The semiconductor device (1A to 1H) according to any one of A1 to A11, further comprising: an insulating film (38) that is partially covers the main surface electrode (30, 32, 124); wherein the gap portion (65, 101, 131, 140) exposes the insulating film (38).

[A13] The semiconductor device (1A to 1H) according to A12, wherein the insulating film (38) includes any one of or both of an inorganic insulating film (42) and an organic insulating film (43).

[A14] The semiconductor device (1A to 1H) according to any one of A1 to A13, wherein the chip (2) includes a monocrystal of a wide bandgap semiconductor.

[A15] A semiconductor device (1A to 1H) comprising: a chip (2) having a main surface (3); a gate electrode (30) arranged on the main surface (3); a source electrode (32) arranged on the main surface (3) at an interval from the gate electrode (30); a gate terminal electrode (50) arranged on the gate electrode (30); and a source terminal electrode (60) that has a source conductor layer (64) arranged on the source electrode (32) and a gap portion (65, 101) penetrating the source conductor layer (64) in a thickness direction as viewed in cross section.

[A16] The semiconductor device (1A to 1H) according to A15, wherein the source terminal electrode (60) has a planar area larger than that of the gate terminal electrode (50).

[A17] The semiconductor device according to A15 or A16, wherein the gate terminal electrode (50) has a gate conductor layer (54) covering the gate electrode (30) and is free from a gap portion penetrating the gate conductor layer (54).

[A18] The semiconductor device according to any one of A15 to A17, wherein the source terminal electrode (60) includes terminal portions (66, 102) that are demarcated by the gap portion (65, 101).

[A19] The semiconductor device according to any one of A15 to A18, further comprising: the source electrode (32) that has a lower conductor layer (35) covering the main surface (3) and a lower gap portion (107) penetrating the lower conductor layer (35) in the thickness direction as viewed in cross section; a gate wiring (109) drawn out into the lower gap portion (107) from the gate electrode (30); and the source terminal electrode (60) that has the gap portion (65, 101) formed at a position overlapping the gate wiring (109) as viewed in plane.

[A20] The semiconductor device according to any one of A15 to A19, further comprising: a gap insulator (74, 105) embedded in the gap portion (65, 101) such as to expose a part of the source terminal electrode (60).

[B1] A manufacturing method for a semiconductor device (1A to 1H) comprising: a step of preparing a wafer structure (80) that includes a wafer (81) having a main surface (82) and a main surface electrode (30, 32, 124) arranged on the main surface (82); a step of forming a mask (90) that has an opening (92) exposing the main surface electrode (30, 32, 124) and that has a wall portion (93) partially covers the main surface electrode (30, 32, 124) inside the opening (92); and a step of forming a terminal electrode (50, 60, 126) that is fixed to a same potential as that of the main surface electrode (30, 32, 124) and that has a conductor layer (54, 64, 130) covering the main surface electrode (30, 32, 124) and a gap section (65, 101, 131, 140) partitioned by the wall portion (93), by depositing a conductor on a portion of the main surface electrode (30, 32, 124) that is exposed from the mask (90).

[B2] The manufacturing method for the semiconductor device (1A to 1H) according to B1, wherein the wall portion (93) has a portion extending in one direction as viewed in plane.

[B3] The manufacturing method for the semiconductor device (1A to 1H) according to B2, wherein the wall portion (93) has a portion extending in an intersecting direction that intersects the one direction as viewed in plane.

[B4] The manufacturing method for the semiconductor device (1A to 1H) according to any one of B1 to B3, wherein the wall portion (93) partitions opening portions in the opening (92).

[B5] The manufacturing method for the semiconductor device (1A to 1H) according to any one of B1 to B4, the step of forming the terminal electrode (50, 60, 126) includes a step of depositing the conductor by a plating method.

[B6] The manufacturing method for the semiconductor device (1A to 1H) according to any one of B1 to B5, further comprising: a step of removing the mask (90) after the step of forming the terminal electrode (50, 60, 126).

[B7] The manufacturing method for the semiconductor device (1A to 1H) according to any one of B1 to B6, further comprising: a step of thinning the wafer (81) after the step of forming the terminal electrode (50, 60, 126).

[B8] The manufacturing method for the semiconductor device (1A to 1H) according to any one of B1 to B7, further comprising: a step of forming a sealing insulator (71) covering the wafer structure (80) such as to expose the terminal electrode (50, 60, 126) after the step of forming the terminal electrode (50, 60, 126).

[B9] The manufacturing method for the semiconductor device (1A to 1H) according to A8, wherein the step of forming the sealing insulator (71) includes a step of forming the sealing insulator (71) that covers a whole region of the terminal electrode (50, 60, 126) and a step of removing the sealing insulator (71) until the terminal electrode (50, 60, 126) is exposed.

[B10] The manufacturing method for the semiconductor device (1A to 1H) according to A9, wherein the step of removing the sealing insulator (71) includes a step of removing the sealing insulator (71) by a grinding method.

[C1] A semiconductor device (1A to 1H) comprising: a chip (2) that includes a monocrystal of a wide bandgap semiconductor, that has a main surface (3) having an area of not less than 1 mm square as viewed in plane, and that has a thickness of not more than 100 μm as viewed in cross section; a main surface electrode (30, 32, 124) arranged on the main surface (3) such as to cover a region of not less than 50% of the main surface (3) as viewed in plane; and a terminal electrode (50, 60, 126) that has a conductor layer (54, 64, 130) arranged on the main surface electrode (30, 32, 124) and a gap section (65, 101, 131, 140) penetrating the conductor layer (54, 64, 130) in a thickness direction as viewed in cross section and that covers a region of not less than 50% of the main surface (3) as viewed in plane.

[C2] The semiconductor device (1A to 1H) according to C1, wherein the chip (2) has a thickness of not more than 50 μm.

[C3] The semiconductor device (1A to 1H) according to C1 or C2, wherein the main surface (3) has an area of not more than 10 mm square as viewed in plane.

[C4] The semiconductor device (1A to 1H) according to any one of C1 to C3, wherein the terminal electrode (50, 60, 126) includes terminal portions demarcated by the gap section (65, 101, 131, 140).

[C5] The semiconductor device (1A to 1H) according to any one of C1 to C4, further comprising: a gap insulator (74, 105, 143) that is embedded in the gap section (65, 101, 131, 140) such as to expose a part of the terminal electrode (50, 60, 126).

[C6] The semiconductor device (1A to 1H) according to C5, further comprising: a sealing insulator (71) that covers a periphery of the terminal electrode (50, 60, 126) on the main surface (3) such as to expose a part of the terminal electrode (50, 60, 126); wherein the gap insulator (74, 105, 143) consists of a part of the sealing insulator (71).

[C7] The semiconductor device (1A to 1H) according to C6, wherein the terminal electrode (50, 60, 126) is thicker than the main surface electrode (30, 32, 124), and the sealing insulator (71) is thicker than the main surface electrode (30, 32, 124).

[C8] The semiconductor device (1A to 1H) according to C6 or C7, wherein the terminal electrode (50, 60, 126) is thicker than the chip (2), and the sealing insulator (71) is thicker than the chip (2).

[C9] The semiconductor device (1A to 1H) according to any one of C6 to C8, wherein the sealing insulator (71) includes a thermosetting resin.

[C10] The semiconductor device (1A to 1H) according to any one of C1 to C9, the chip (2) has a laminated structure that includes a semiconductor substrate and an epitaxial layer.

[C11] The semiconductor device (1A to 1H) according to C10, wherein the epitaxial layer is thicker than the semiconductor substrate.

[C12] The semiconductor device (1A to 1H) according to any one of C1 to C9, wherein the chip (2) has a single layered structure that consists of an epitaxial layer.

[C13] The semiconductor device (1A to 1H) according to any one of C1 to C12, a potential of not less than 500 V and not more than 3000 V is to be applied to the chip (2).

While embodiments of the present invention have been described in detail above, those are merely specific examples used to clarify the technical contents, and the present invention should not be interpreted as being limited only to those specific examples, and the spirit and scope of the present invention shall be limited only by the appended Claims.

What is claimed is:

1. A semiconductor device comprising:
a chip having a main surface;
a main surface electrode arranged on the main surface; and
a terminal electrode that has a conductor layer covering the main surface electrode and a gap portion penetrating the conductor layer in a thickness direction as viewed in cross section, and that is fixed to a same potential as that of the main surface electrode.

2. The semiconductor device according to claim 1,
wherein the terminal electrode has terminal portions that are demarcated by the gap portion and fixed to the same potential as that of the main surface electrode, respectively.

3. The semiconductor device according to claim 2,
wherein the terminal portions are physically separated by the gap portion.

4. The semiconductor device according to claim 1,
wherein the gap portion is formed at a position overlapping the main surface electrode as viewed in plane.

5. The semiconductor device according to claim 1, further comprising:
a gap insulator that is embedded in the gap portion such as to expose a part of the terminal electrode.

6. The semiconductor device according to claim 5,
wherein the terminal electrode is thicker than the main surface electrode, and
the gap insulator is thicker than the main surface electrode.

7. The semiconductor device according to claim 5,
wherein the terminal electrode has an electrode surface, and
the gap insulator has an insulator surface that forms a single flat surface with the electrode surface.

8. The semiconductor device according to claim 7,
wherein the electrode surface consists of a ground surface having a grinding mark, and
the insulator surface consists of a ground surface having a grinding mark.

9. The semiconductor device according to claim 1,
wherein the main surface electrode has a lower conductor layer covering the main surface and a lower gap portion penetrating the lower conductor layer in the thickness direction as viewed in cross section, and
the gap portion is formed at a position overlapping the lower gap portion as viewed in plane.

10. The semiconductor device according to claim 9,
wherein the main surface electrode includes electrode portions that are demarcated by the lower gap portion.

11. The semiconductor device according to claim 9, further comprising:
a wiring arranged in the lower gap portion.

12. The semiconductor device according to claim 1, further comprising:
an insulating film that is partially covers the main surface electrode;
wherein the gap portion exposes the insulating film.

13. The semiconductor device according to claim 12,
wherein the insulating film includes any one of or both of an inorganic insulating film and an organic insulating film.

14. The semiconductor device according to claim 1,
wherein the chip includes a monocrystal of a wide bandgap semiconductor.

15. A semiconductor device comprising:
a chip having a main surface;
a gate electrode arranged on the main surface;
a source electrode arranged on the main surface at an interval from the gate electrode;
a gate terminal electrode arranged on the gate electrode; and
a source terminal electrode that has a source conductor layer arranged on the source electrode and a gap portion penetrating the source conductor layer in a thickness direction as viewed in cross section.

16. The semiconductor device according to claim 15,
wherein the source terminal electrode has a planar area larger than that of the gate terminal electrode.

17. The semiconductor device according to claim 15,
wherein the gate terminal electrode has a gate conductor layer covering the gate electrode and is free from a gap portion penetrating the gate conductor layer.

18. The semiconductor device according to claim 15,
wherein the source terminal electrode includes terminal portions that are demarcated by the gap portion.

19. The semiconductor device according to claim 15, further comprising:
the source electrode that has a lower conductor layer covering the main surface and a lower gap portion penetrating the lower conductor layer in the thickness direction as viewed in cross section;
a gate wiring drawn out into the lower gap portion from the gate electrode; and
the source terminal electrode that has the gap portion formed at a position overlapping the gate wiring as viewed in plane.

20. The semiconductor device according to claim 15, further comprising:
a gap insulator embedded in the gap portion such as to expose a part of the source terminal electrode.
